(19) United States
(12) Patent Application Publication
(10) Pub. No.: US 2025/0261562 A1
(43) Pub. Date: Aug. 14, 2025

(54) ULTRASONIC TRANSDUCER AND ULTRASOUND IMAGE PROCESSING

(71) Applicant: Liminal Sciences, Inc., Guilford, CT (US)

(72) Inventors: Kamyar Firouzi, Guilford, CT (US); Yichi Zhang, Guilford, CT (US); Guillaume David, Guilford, CT (US); Mohammad Moghadamfalahi, Guilford, CT (US); Tom Reinwald, Guilford, CT (US); Laura Ngan, Guilford, CT (US)

(73) Assignee: Liminal Sciences, Inc., Guilford, CT (US)

(21) Appl. No.: 19/051,084

(22) Filed: Feb. 11, 2025

Related U.S. Application Data
(60) Provisional application No. 63/553,420, filed on Feb. 14, 2024.
(60) Provisional application No. 63/554,019, filed on Feb. 15, 2024.
(60) Provisional application No. 63/554,006, filed on Feb. 15, 2024.
(60) Provisional application No. 63/554,390, filed on Feb. 16, 2024.
(60) Provisional application No. 63/554,382, filed on Feb. 16, 2024.
(60) Provisional application No. 63/554,378, filed on Feb. 16, 2024.

(51) Int. Cl. H10N 30/88; B06B 1/06; H10N 30/85; H10N 30/87

(52) U.S. Cl. CPC H10N 30/88; B06B 1/0629; H10N 30/852; H10N 30/872; H10N 30/875

(57) ABSTRACT

Disclosed are ultrasound transducers with a small form factor, enabling applications for which traditional ultrasound transducers are unsuited. The transducers can be configured to interface with a variety of medical imaging systems. Also disclosed are example methods of manufacturing ultrasound transducers. Example versions of the ultrasound transducer can include an acoustic lens secured to the housing, a piezoelectric array, a backing layer with a phase disruptive component, an interposer board coupled to the piezoelectric array, and a cable assembly coupled to the interposer board. Moreover, disclosed are methods and systems for detecting and classifying anatomical structures using ultrasound systems. A system can generate a clip of brain vessel segmentations in an ultrasound of a patient and determine blood vessel parameters at least by inputting the clip to a machine learning model configured to output the plurality of blood vessel parameters based at least on the clip.

### CROSS-REFERENCE TO RELATED APPLICATIONS

This application claims priority to U.S. Prov. Pat. App. No. 63/553,420 filed Feb. 14, 2024, U.S. Prov. Pat. App. No. 63/554,019 filed Feb. 15, 2024, to U.S. Prov. Pat. App. No. 63/554,006 filed Feb. 15, 2024, U.S. Prov. Pat. App. No. 63/554,382 filed Feb. 16, 2024, U.S. Prov. Pat. App. No. 63/554,390 filed Feb. 16, 2024, and U.S. Prov. Pat. App. No. 63/554,378 filed Feb. 16, 2024, the entirety of each of which is herein incorporated by reference.

### FIELD

The present invention relates, at least in part, to transducers for use in medical imaging. In a non-limiting example, this disclosure provides ultrasound transducers having a small form factor, suitable for use in a variety of applications, and methods for manufacturing ultrasound transducers. The present invention also relates, at least in part, to processing ultrasound for use in medical imaging. In a non-limiting example, this disclosure provides techniques for processing ultrasound images to detect and classify structures in soft tissues, such as the brain.

### BACKGROUND

Medical ultrasound imaging technology uses sound waves to create images of organs, tissues, and other structures inside the human body. It provides health care professionals with a relatively low cost, real-time, and non-invasive medical diagnostic tool. A medical ultrasound imaging system co produces sound waves that bounce off body tissue and result in echoes. The medical ultrasound imaging system receives the echoes and produces images based on the resulting data. Medical ultrasound imaging systems traditionally require trained sonographers limiting the accessibility and applicability of medical ultrasound imaging technology.

### SUMMARY

In one aspect, various embodiments of the disclosure relate to an ultrasound transducer. The ultrasound transducer may comprise a housing, an acoustic lens secured to the housing, a piezoelectric array, a backing layer comprising a phase disruptive component, an interposer board coupled to the piezoelectric array, and/or a cable assembly coupled to the interposer board.

In some embodiments of the disclosure, the piezoelectric array comprises array elements at least partially cut along epoxy resin grooves. In some embodiments of the disclosure, the housing comprises a front casing and a back casing, and the acoustic lens may be secured to the front casing. In some embodiments of the disclosure, the phase disruptive component comprises grooves. In some embodiments of the disclosure, the grooves are V-shaped grooves. In some embodiments of the disclosure, the backing layer further comprises beads. In some embodiments of the disclosure, the beads have a hollow interior. In some embodiments of the disclosure, the backing layer further comprises tungsten powder. In some embodiments of the disclosure, the ultrasound transducer further comprises one or more matching layers, and the one or more matching layers comprises an epoxy resin. In some embodiments of the disclosure, the interposer board comprises one or more receptacles for one or more cable assembly connectors. In some embodiments of the disclosure, the interposer board comprises a cutout sized to fit the piezoelectric array.

In some embodiments of the disclosure, the ultrasound transducer further comprises a copper pad having a cutout smaller than the piezoelectric array. The piezoelectric array may comprise a ground electrode, and the ground electrode may be bonded, via a conductive epoxy, to an exposed part of the copper pad. In some embodiments of the disclosure, the transducer does not comprise an impedance tuner. In some embodiments of the disclosure, the cable assembly comprises a cable extending from a transducer end to a system end. The system end of the cable may comprise one or more electrical components configured for electrical impedance tuning. In some embodiments of the disclosure, the piezoelectric array comprises a 1-3 composite material or a 2-2 composite material.

Various embodiments of the disclosure relate to a method of manufacturing an ultrasound transducer, comprising connecting an element of a composite piezoelectric array to a signal electrode on an interposer board by at least one of: placing conductive epoxy between the element of the piezoelectric array and the signal electrode on the interposer board; soldering an aluminum wire between the element of the composite piezoelectric array and the signal electrode on the interposer board, trimming the aluminum wire, and applying conductive epoxy to the aluminum wire, the element of the composite piezoelectric array, and the signal electrode on the interposer board; or plasma cleaning the element of the composite piezoelectric array, bonding the element of the composite piezoelectric array to the signal electrode on the interposer board with a wire, or covering the element of the composite piezoelectric array, the signal electrode on the interposer board, and the wire with encapsulation material. In some embodiments of the disclosure, electrical connection between the interposer board and array elements is established via wire-bonding and/or direct soldering (which may, e.g., allow for reduction of a number of board-to-board connections and a size of the interposer board).

In some embodiments of the disclosure, the method further comprises at least partially cutting a 1-3 and/or 2-2 composite piezoelectric material along epoxy resin grooves of the 1-3 and/or 2-2 composite piezoelectric material. In some embodiments of the disclosure, the 1-3 and/or 2-2 composite piezoelectric material is at least partially cut to a depth of less than 100%. In some embodiments of the disclosure, the 1-3 and/or 2-2 composite piezoelectric material is at least partially cut to a depth of about 80% to leave a ground electrode intact.

In another aspect, various embodiments of the present disclosure are directed to a method for peduncle detection with B-mode from a single or a sequence of frames. The method may be performed, in a non-limiting example, by an ultrasound system. The method includes generating imaging data corresponding to a single B-mode frame in an ultrasound image of a brain of a patient. The method includes providing the imaging data to a first machine learning model configured to receive B-mode frames and, for each of the B-mode frames, output a prediction comprising a bounding region indicative of a location of a cerebral peduncle in the respective B-mode frame.

In some implementations, the first machine learning model is further configured to output a presence score indicative of a confidence of the first machine learning model in the prediction. In some implementations, the method includes generating, on a display device, the ultrasound image comprising the respective B-mode frame with the bounding region superimposed thereon. In some implementations, the method includes identifying a Circle of Willis in the respective B-mode frame based at least on the location of the cerebral peduncle.

In some implementations, the method includes training the first machine learning model. In some implementations, training the first machine learning model includes generating a first training dataset comprising imaging data for a set of B-mode frames and, for each B-mode frame in the set of B-mode frames, a bounding region containing the cerebral peduncle. In some implementations, the bounding region for each B-mode frame in the set of B-mode frames in the first training dataset is user-defined. In some implementations, the method includes training the first machine learning model using one or more training datasets comprising (i) B-mode frames, (ii) a cerebral peduncle bounding region for each B-mode frame, and (iii) a cerebral peduncle presence label for each B-mode frame.

In some implementations, the method includes generating second imaging data corresponding to a sequence of B-mode frames in the ultrasound image of the patient. In some implementations, the method includes inputting the second imaging data to a second machine learning model that is configured to predict the location of the cerebral peduncle based at least on regions neighboring the cerebral peduncle. In some implementations, the method includes generating second imaging data corresponding to a sequence of B-mode frames in the ultrasound image of the patient. In some implementations, the sequence comprises (i) the single B-mode frame and (ii) data indicative of the bounding region predicted by the first machine learning model. In some implementations, the method includes inputting the second imaging data to a second machine learning model that is configured to predict the location of the cerebral peduncle based at least on regions neighboring the bounding region.

In some implementations, the method includes training the second machine learning model. In some implementations, training the second machine learning model comprises generating a second training dataset comprising imaging data for sequences of B-mode frames and, for each B-mode frame in each of the sequences, (i) a bounding region produced by the first machine learning model and (ii) data corresponding to neighboring regions proximate to the bounding region. In some implementations, the method includes updating the first machine learning model based at least on outputs of the second machine learning model. In some implementations, the method includes receiving, for the single B-mode frame, a user input corresponding to the cerebral peduncle. In some implementations, the method includes updating the first machine learning model based at least on the user input.

One other embodiment is directed to another method for peduncle detection with B-mode from a single or a sequence of frames. The method may be performed, in a non-limiting example, by an ultrasound system. The method includes generating imaging data corresponding to a sequence of B-mode frames in an ultrasound of a patient and, in each of the B-mode frames, an indication of a first location of a cerebral peduncle. The method includes providing the imaging data to a first machine learning model, the first machine learning model configured to output a prediction comprising a bounding region indicative of a second location of a neighboring anatomic feature proximate to the cerebral peduncle.

In some implementations, the method includes training the first machine learning model using a training dataset comprising B-mode frames, peduncle bounding regions, and peduncle presence labels. In some implementations, the method includes using a second machine learning model to locate the second anatomic feature in a single B-mode frame in the sequence of B-mode frames.

One embodiment is directed to a method for brain vessel detection and segmentation for ultrasound imaging. The method may be performed, in a non-limiting example, by an ultrasound system. The method includes providing a single colorflow frame in an ultrasound of a patient to a first machine learning model configured to receive colorflow frames and, for each of the colorflow frames received, output a prediction indicative of a brain blood vessel location in the colorflow frame. The method includes generating, by the ultrasound device, an ultrasound image based at least on the prediction.

In some implementations, the first machine learning model is further configured to output a presence score indicative of a confidence of the first machine learning model in the prediction. In some implementations, the first machine learning model is trained using one or more training datasets comprising colorflow frames, each of the colorflow frames comprising a vessel presence label. In some implementations, the vessel presence label is a binary indicator of whether a blood vessel is present. In some implementations, the method includes the first machine learning model is trained using one or more training datasets consisting of colorflow frames, each of the colorflow frames comprising a vessel presence label.

In some implementations, the vessel presence label is a binary indicator of whether a blood vessel is present. In some implementations, the method includes inputting the single colorflow frame and a single B-mode frame to a second machine learning model configured to output a single-frame blood vessel segmentation. In some implementations, the method includes deriving a metric related to blood flow velocity based at least on the blood vessel segmentation. In some implementations, the method includes smoothing variations of frame-to-frame brain vessel segmentations in real-time using a buffer that stores previous segmentations and uses the previous segmentations to modify current vessel segmentations. In some implementations, the method includes generating, in real-time, an ultrasound image based at least on the brain blood vessel location from the first machine learning model and the blood vessel segmentation of the second machine learning model.

One other embodiment of the present disclosure is directed to another method for brain vessel detection and segmentation for ultrasound imaging. The method may be performed, in a non-limiting example, by an ultrasound system. The method includes generating, in real-time, a single-frame brain vessel segmentation in an ultrasound of a brain of a patient by inputting a single B-mode frame and a single colorflow frame to a machine learning model configured for brain vessel detection based at least on vessel volume.

In some implementations, the method includes deriving a quantity related to blood flow velocity based at least on the brain vessel segmentation. In some implementations, the method includes characterizing blood vessel shape based at least on the brain vessel segmentation. In some implementations, the method includes smoothing variations of frame-to-frame vessel segmentations using a buffer that stores previous segmentations and uses the previous segmentations to modify brain vessel segmentation in the current frame.

Yet another embodiment of the present disclosure is directed to another method for brain vessel detection and segmentation for ultrasound imaging. The method may be performed, in a non-limiting example, by an ultrasound system. The method includes using a first machine learning model to determine a blood vessel location using a single colorflow frame in an ultrasound of a patient. The method includes using a second machine learning model to generate a brain vessel segmentation using the single colorflow frame and a single B-mode frame. The method includes generating, for display, an ultrasound image based at least on the blood vessel location and the brain vessel segmentation.

One embodiment of the present disclosure is directed to a method for brain vessel segmentation with B-mode. The method may be performed, in a non-limiting example, by an ultrasound system. The method includes generating ultrasound images comprising brain vessel segmentations at least by inputting a single B-mode frame in an ultrasound of a patient to a machine learning model. The machine learning model may be configured to output a brain vessel segmentation based at least on the single B-mode frame.

In some implementations, the brain vessel segmentations are generated, by the ultrasound system, in real-time. In some implementations, the machine learning model is trained using brain vessel segmentations derived from colorflow images. In some implementations, the machine learning model does not receive a colorflow image as input once the machine learning model has been optimized using the colorflow images. In some implementations, the machine learning model detects multiple anatomical landmarks visible in B-mode images and uses the anatomical landmarks to estimate a position of a brain vessel corresponding to the brain vessel segmentation.

In some implementations, the machine learning model detects multiple anatomical landmarks visible in B-mode images and uses the anatomical landmarks to estimate a delineation of a brain vessel corresponding to the brain vessel segmentation. In some implementations, the method includes the machine learning model detects multiple anatomical landmarks visible in B-mode images and uses the anatomical landmarks to estimate a position and delineation of a brain vessel corresponding to the brain vessel segmentation. In some implementations, the method includes training the machine learning model using brain vessel segmentations derived from colorflow images.

Another embodiment of the present disclosure is directed to an ultrasound system for brain vessel segmentation with B-mode. The ultrasound system may comprise one or more processors. The ultrasound system can generate ultrasound images comprising brain vessel segmentations at least by inputting a single B-mode frame in an ultrasound of a patient to a machine learning model. The machine learning model may be configured to output a brain vessel segmentation based at least on the single B-mode frame.

In some implementations, the ultrasound system can generate the brain vessel segmentations in real-time. In some implementations, the machine learning model is trained using brain vessel segmentations derived from colorflow images. In some implementations, the ultrasound system does not input colorflow images to the machine learning model once the machine learning model has been trained using the colorflow images. In some implementations, the machine learning model detects multiple anatomical landmarks visible in B-mode images and uses the anatomical landmarks to estimate a position of a brain vessel corresponding to the brain vessel segmentation. In some implementations, the machine learning model detects multiple anatomical landmarks visible in B-mode images and uses the anatomical landmarks to estimate a delineation of a brain vessel corresponding to the brain vessel segmentation. In some implementations, the machine learning model detects multiple anatomical landmarks visible in B-mode images and uses the anatomical landmarks to estimate a position and a delineation of a brain vessel corresponding to the brain vessel segmentation.

One embodiment of the present disclosure is directed to a method for brain vessel parametrization and tracking. The method may be performed, in a non-limiting example, by an ultrasound system. The method includes generating a clip of brain vessel segmentations in an ultrasound of a patient. The method includes determining a plurality of blood vessel parameters at least by inputting the clip of brain vessel segmentations to a machine learning model configured to output the plurality of blood vessel parameters based at least on the clip of the brain vessel segmentations. The method includes outputting the plurality of blood vessel parameters determined using the machine learning model.

In some implementations, the plurality of blood vessel parameters comprises coordinates of a centerline location. In some implementations, the plurality of blood vessel parameters comprises a vessel curvature at each centerline location. In some implementations, the plurality of blood vessel parameters comprises a vessel diameter at each centerline location. In some implementations, the plurality of blood vessel parameters comprises a colorflow signal-to-noise ratio at each centerline location. In some implementations, the plurality of blood vessel parameters comprises at least one of: a plurality of coordinates of a centerline location, a vessel curvature at the centerline location, a vessel diameter at the centerline location, or a colorflow signal-to-noise ratio at the centerline location.

Another embodiment of the present disclosure is directed to another method for brain vessel parametrization and tracking. The method may be performed, in a non-limiting example, by an ultrasound system. The method includes tracking, in a sequence of ultrasound images, by an ultrasound system, a position of brain vessel segments across time using a machine learning model. The machine learning model may be configured to use parametrization of a brain vessel curve and a spatiotemporal matching algorithm to build a spatiotemporal graph.

In some implementations, tracking is implemented as a scan through the spatiotemporal graph. In some implementations, the spatiotemporal matching algorithm comprises a Hungarian matching algorithm. In some implementations, the method includes using the tracking in a beam steering component of an ultrasound system. In some implementations, the method includes locking on a target and extracting one or more parameters to perform an assessment of cerebral blood flow velocity.

Yet another embodiment of the present disclosure is directed to an ultrasound system for brain vessel parametrization and tracking. The ultrasound system may comprise one or more processors. The ultrasound system can generate a plurality of blood vessel parameters at least by inputting a clip of brain vessel segmentations in an ultrasound of a patient, to a first machine learning model configured to output the plurality of blood vessel parameters based at least on the clip of the brain vessel segmentations. The ultrasound system can track a position of brain vessel segments across time using a second machine learning model configured to use parametrization of a brain vessel curve and a spatiotemporal matching algorithm to build a spatiotemporal graph.

In some implementations, the plurality of blood vessel parameters comprises at least one of: a plurality of coordinates of a centerline location, a vessel curvature at the centerline location, a vessel diameter at the centerline location, or a colorflow signal-to-noise ratio at the centerline location. In some implementations, the ultrasound system may track the position in a beam steering component of the ultrasound system. In some implementations, the ultrasound system may lock on a target and extract one or more parameters to perform an assessment of cerebral blood flow velocity.

One embodiment of the present disclosure is directed to a method for implementing model ensembles for brain vessel detection. The method may be performed, in a non-limiting example, by an ultrasound system. The method includes predicting a presence score for a target brain vessel in a Circle of Willis in an ultrasound of a patient, by providing a sequence of B-mode and colorflow frames to an ensemble model. The ensemble model may aggregate predictions of a plurality of machine learning models with different designs. The method includes outputting an indication of the presence score predicted using the ensemble model.

In some implementations, the plurality of machine learning models comprises either: (i) a first machine learning model, or (ii) both the first machine learning model and a second machine learning model, each of the first and second machine learning models configured to detect a cerebral peduncle using a single B-mode frame, the first and second machine learning models having different designs. In some implementations, the plurality of machine learning models comprises a third machine learning model configured to detect a cerebral peduncle using a sequence of B-mode frames. In some implementations, the plurality of machine learning models comprises a fourth machine learning model configured for brain vessel segmentation using B-mode and colorflow frames.

In some implementations, the fourth machine learning model is further configured to perform temporal smoothing. In some implementations, the plurality of machine learning models comprises a fifth machine learning model configured for brain vessel segmentation using only B-mode frames. In some implementations, the fifth machine learning model is further configured to perform temporal smoothing. In some implementations, the plurality of machine learning models comprises a first machine learning model and a second machine learning model, each of the first and second machine learning models configured to detect a cerebral peduncle using a single B-mode frame; a third machine learning model configured to detect a cerebral peduncle using a sequence of B-mode frames; a fourth machine learning model configured for brain vessel segmentation using B-mode and colorflow frames; and a fifth machine learning model configured for brain vessel segmentation using only B-mode frames. In some implementations, the ensemble model comprises at least two of: a B-mode You Only Look Once (YOLO) model, a B-mode CenterNet model, a B-mode segmentation model, and a B-mode and colorflow segmentation model.

Another embodiment of the present disclosure is directed to an ultrasound system for implementing model ensembles for brain vessel detection. The ultrasound system may comprise one or more processors. The ultrasound system can predict a presence score for a target brain vessel in a Circle of Willis in an ultrasound of a patient, by providing a sequence of B-mode and colorflow frames to an ensemble model, the ensemble model configured to aggregate predictions of a plurality of machine learning models with different designs. The ultrasound system can output an indication of the presence score predicted using the ensemble model.

In some implementations, the plurality of machine learning models comprises a first machine learning model and a second machine learning model, each of the first and second machine learning models configured to detect a cerebral peduncle using a single B-mode frame, the first and second machine learning models having different designs. In some implementations, the plurality of machine learning models comprises a third machine learning model configured to detect a cerebral peduncle using a sequence of B-mode frames. In some implementations, the plurality of machine learning models comprises a fourth machine learning model configured for brain vessel segmentation using B-mode and colorflow frames. In some implementations, the plurality of machine learning models comprises a fifth machine learning model configured for brain vessel segmentation using only B-mode frames.

### BRIEF DESCRIPTION OF THE DRAWINGS

The accompanying drawings are not intended to be drawn to scale. Like reference numbers and designations in the various drawings indicate like elements. For purposes of clarity, not every component may be labeled in every drawing. In the drawings:

FIG. 1 illustrates components of an example ultrasound imaging system, in accordance with one or more embodiments of the disclosure;

FIGS. 2A and 2B depict different perspectives of a small form factor ultrasound transducer, in accordance with one or more embodiments of the disclosure;

FIG. 3 depicts a non-limiting example use case of a small form factor ultrasound transducer, in accordance with one or more embodiments of the disclosure;

FIGS. 4A and 4B depict a partial subset of the components comprising a small form factor ultrasound transducer, in accordance with one or more embodiments of the disclosure;

FIG. 5 depicts an example housing of a small form factor ultrasound transducer, in accordance with one or more embodiments of the disclosure;

FIGS. 6A and 6B depict example acoustic lens constructions, in accordance with one or more embodiments of the disclosure;

FIG. 7 depicts an example piezoelectric array for use in a small form factor ultrasound transducer, in accordance with one or more embodiments of the disclosure;

FIGS. 8A and 8B depict different perspectives of an example interposer board for use in a small form factor ultrasound transducer, in accordance with one or more embodiments of the disclosure;

FIGS. 9A and 9B depict different perspectives of an example interposer board having a copper pad affixed to it for use in a small form factor ultrasound transducer, in accordance with one or more embodiments of the disclosure;

FIG. 10 depicts an example assembly of an interposer board and a piezoelectric array for use in a small form factor ultrasound transducer, in accordance with one or more embodiments of the disclosure;

FIG. 11 depicts example connections between elements of a piezoelectric array and electrodes on an interposer board, in accordance with one or more embodiments of the disclosure;

FIG. 12 depicts example wire bonding connections between elements of a piezoelectric array and electrodes on an interposer board, in accordance with one or more embodiments of the disclosure;

FIG. 13 depicts various components comprising a small formfactor ultrasound transducer, in accordance with one or more embodiments of the disclosure;

FIG. 14 depicts an example backing layer comprising a phase disruptive component, in accordance with one or more embodiments of the disclosure;

FIG. 15 depicts an example cable assembly, in accordance with one or more embodiments of the disclosure;

FIG. 16 depicts a transducer end of a cable assembly connected to an interposer board of a small form factor ultrasound transducer, in accordance with one or more embodiments of the disclosure;

FIG. 17 depicts a partial subset of components of a small form factor ultrasound transducer, in accordance with one or more embodiments of the disclosure;

FIG. 18 illustrates components of an example ultrasound imaging system, in accordance with one or more embodiments of the disclosure;

FIG. 19 depicts a non-limiting example dataflow diagram showing a process for training and executing a machine-learning model for detecting cerebral peduncles with single, or a sequence, of B-mode image frames, in accordance with one or more embodiments of the disclosure;

FIG. 20 depicts a flowchart of an example method of training and executing a machine-learning model for detecting cerebral peduncles with single, or a sequence, of B-mode image frames, in accordance with one or more embodiments of the disclosure;

FIGS. 21A, 21B, and 21C depict non-limiting example dataflow diagrams showing processes for training and executing machine-learning models for brain vessel detection and segmentation, in accordance with one or more embodiments of the disclosure;

FIG. 22 depicts a flowchart of an example method of brain vessel detection and segmentation for ultrasound imaging, in accordance with one or more embodiments of the disclosure;

FIG. 23 depicts a non-limiting example dataflow diagram showing a process for training and executing machine-learning models for brain vessel segmentation with B-mode frames, in accordance with one or more embodiments of the disclosure;

FIG. 24 depicts a flowchart of an example method of brain vessel segmentation with B-mode frames, in accordance with one or more embodiments of the disclosure;

FIGS. 25A and 25B depict non-limiting example dataflow diagrams showing processes for training and executing machine-learning models for brain vessel parameterization and tracking, in accordance with one or more embodiments of the disclosure;

FIG. 26 depicts a flowchart of an example method of brain vessel parameterization and tracking, in accordance with one or more embodiments of the disclosure;

FIG. 27 depicts a non-limiting example dataflow diagram showing a process for training and executing a machine-learning model ensemble for brain vessel detection, in accordance with one or more embodiments of the disclosure;

FIG. 28 depicts a flowchart of an example method of brain vessel detection using a machine-learning model ensemble, in accordance with one or more embodiments of the disclosure;

FIG. 29 depicts a non-limiting example dataflow diagram showing a process for labeling cerebral peduncles or other anatomical structures in ultrasound clips for training machine learning models, in accordance with one or more embodiments of the disclosure;

FIG. 30 depicts a non-limiting example dataflow diagram showing a process for creating pixel annotations for brain vessels that may be used for training machine learning models, in accordance with one or more embodiments of the disclosure;

FIG. 31 depicts a non-limiting example dataflow diagram showing a process for executing a machine-learning model to estimate cerebral blood flow using colorflow images, in accordance with one or more embodiments of the disclosure; and

FIG. 32 is a block diagram of an example computing system suitable for use in the various arrangements described herein, in accordance with one or more example implementations.

### DETAILED DESCRIPTION

### Example Embodiments of Ultrasonic Imaging Transducer

Below are detailed descriptions of various concepts related to and embodiments of techniques, approaches, methods, apparatuses, and systems for manufacturing and using a small form factor ultrasound transducer. The various concepts introduced above and discussed in detail below may be embodied in any of numerous ways, as the described concepts are not limited to any particular manner of embodiment. Examples of specific embodiments and applications are provided primarily for illustrative purposes.

Medical ultrasound imaging systems may generate images for health evaluation. Ultrasound images are generated by bouncing sound waves off body tissue. The echoes produced are received and processed into images that may then be analyzed or reviewed to better evaluate a patient's health.

Ultrasound transducers are typically large devices that require specially trained sonographers to operate. This means there are many situations where medical ultrasound imaging would be useful, but not practical. Embodiments of the disclosure are directed to an ultrasound transducer with a small form factor and a method of manufacturing such transducers. A small form factor ultrasound transducer is useful in situations where traditional ultrasound transducers are inapplicable.

Typical ultrasound transducers owe their size, at least in part, to two main limitations. First, a typical ultrasound transducer employs a large interposer board, and second, a typical ultrasound transducer requires a large and heavy backing layer to maintain signal integrity. The interposer board of an ultrasound transducer provides an electrical interface between the ultrasound transducer's piezoelectric array and a cable assembly connecting the ultrasound transducer to an imaging system. In some embodiments of the disclosure, the size of the ultrasound transducer's interposer board is minimized in one or more of several ways. In a non-limiting example, electrical connection between the interposer board and a piezoelectric array may be established by a series of direct connections between the two components. Receptacles for connecting the interposer board to a cable assembly may be integrated into the interposer board to reduce the number and size of interconnections. An impedance tuner, and/or one or more passive electrical components for electrical impedance tuning of the circuit or circuits formed between the ultrasound transducer and the imaging system, may be located in either the cable assembly or an imaging system associated with the ultrasound transducer, rather than on the interposer board, or otherwise incorporated into the ultrasound transducer.

Next, in some embodiments of the disclosure, the size of an ultrasound transducer's backing layer may be minimized in one of several ways. A backing layer is a component that attenuates backward emitted sound waves, and/or their echoes. The size of the backing layer may be reduced by increasing its weight per unit volume. This may be achieved by adding materials such as tungsten powder to the backing layer's composition. The sound attenuation qualities of the backing layer may be improved by, in a non-limiting example, adding micro balloons to the backing layer. Alternatively or additionally, the performance of an ultrasound transducer's backing layer may be improved by incorporating a phase disruptive component, such as a series of V-shaped grooves cut into a surface of the backing layer, so that backward emitted waves are not reflected, in phase, back to the ultrasound transducer's piezoelectric array elements.

The size of an ultrasound transducer's backing layer may further be reduced by minimizing unwanted sound waves produced by the ultrasound transducer's piezoelectric array elements in the first place. This may be achieved by producing the piezoelectric array from a piezoelectric composite material, such as a 1-3 or 2-2 piezoelectric composite, and minimizing the compositional variation among elements of the piezoelectric array. Independently, or in combination, these novel features enable the construction of ultrasound transducers with a small form factor, suitable for use in various situations where traditional ultrasound technology is unsuitable.

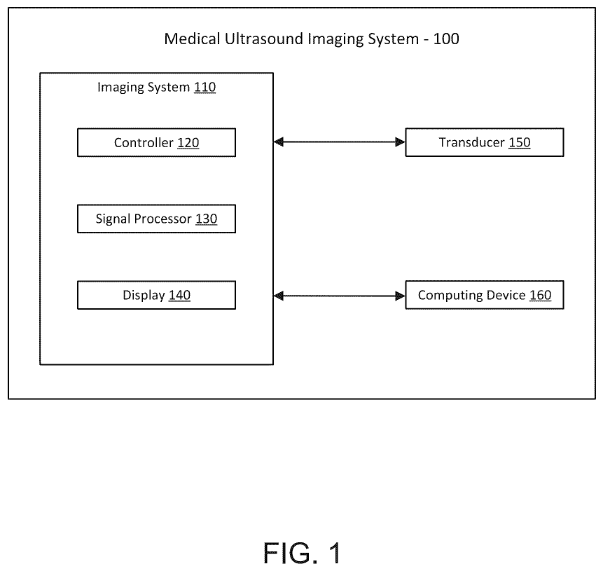

FIG. 1 depicts an example medical ultrasound imaging system 100. The medical ultrasound imaging system 100 may include an imaging system 110, one or more ultrasound transducers 150, and a computing device 160 external to the imaging system 110. The ultrasound transducer 150 produces sound waves that are transmitted to and bounce off body tissue being imaged. The echoes produced by this process can also be received by the ultrasound transducer 150 and transmitted to the imaging system 110. As used herein, an “echo” is distinguished from direct sound, and includes sound resulting from reflection and/or refraction once the direct sound has interfaced with (“hit” or “bounced off”) a surface. There is a delay between emission of the direct sound and detection of an echo. The delay is proportional to a first distance between the source of the direct sound and the surface with which the direct sound interfaces, and a second distance between the surface and a sensor used to detect the echo.

The imaging system 110 may include a controller 120, a signal processor 130, and a display 140. The controller 120 may control the amplitude, sequence, or direction of the sound waves that are produced by the ultrasound transducer 150. The echoes received by the ultrasound transducer and transmitted to the imaging system 110 may be processed by the signal processor 130 to produce images. These images may be displayed to a patient or a medical professional for viewing and diagnostic purposes on the display 140. The controller 120, signal processor 130, and display 140 may be implemented by a single device. In some embodiments, the functions performed by each of these components are performed by multiple devices in communication with one another.

In some embodiments, the medical ultrasound imaging system 100 may include a computing device 160 external to the imaging system 110. The computing device may implement one or more functions of one or more components of the imaging system, such as the controller 120, the signal processor 130, or the display 140. In a non-limiting example, the external computing device 160 may be used to view, preview, and/or store produced images. The computing device 160 may allow a user to make selections regarding operation of the imaging system 110, such as initiating or terminating functions of the medical ultrasound imaging system 110, selecting imaging modalities, adjusting what is displayed, etc. In some embodiments, the computing device 160 may be a general-purpose computer in communication with the imaging system 110. The computing device 160 may be, in a non-limiting example, a workstation, a desktop computer, a laptop, or any mobile device such as a tablet, a smartphone, or another smart device capable of running an application that provides interactivity.

Typical ultrasound transducers are relatively large devices that require specially trained sonographers to operate. This requirement limits medical ultrasound imaging to situations in which a sonographer can be present. Accordingly, there are many situations in which medical ultrasound imaging would be advantageous but due to the technology's limitations, is not practical. Embodiments of the disclosure are directed to an ultrasound transducer 150 with a small form factor and a method of manufacturing such transducers. An ultrasound transducer 150 with a small form factor is suitable for use in many situations where traditional medical ultrasound imaging technology is not feasible or cost effective.

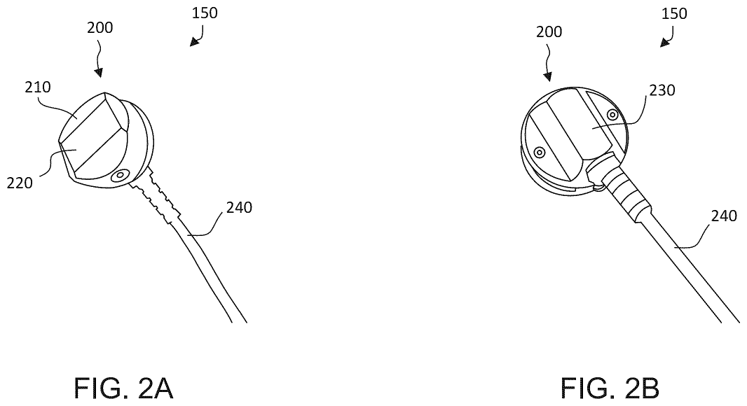

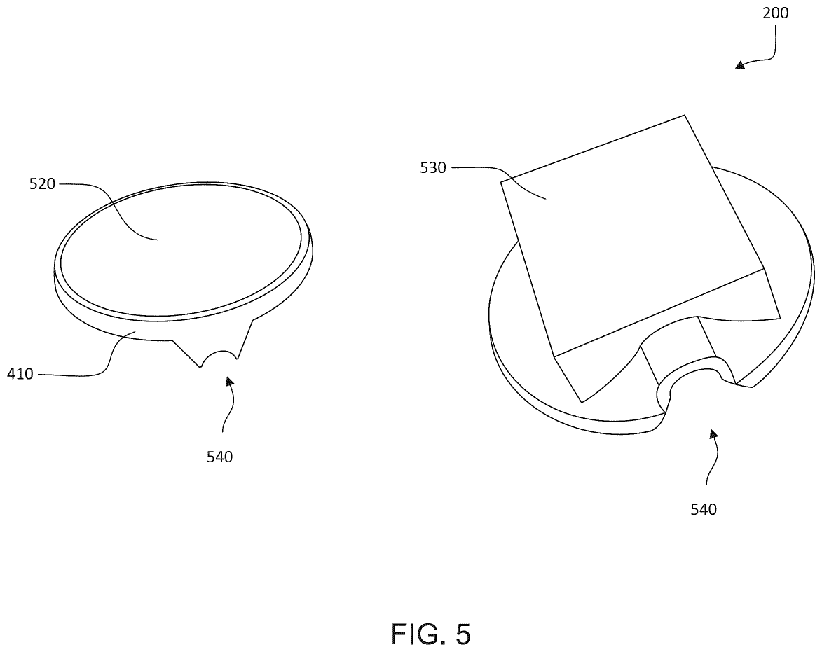

FIGS. 2A and 2B depict an ultrasound transducer 150 with a small form factor, in accordance with one or more embodiments of the disclosure. The ultrasound transducer 150 has a housing 200. The housing 200 has a front 210 and a back 230. An acoustic lens 220 is on the front 210 of the housing 200. The front 210 of the housing 200 is placed in contact with a patient during operation of a medical ultrasound imaging system 100. The back 230 of the housing 200 may provide a location to handle or physically manipulate the ultrasound transducer 150 during use. The back 230 may also provide a location to mount or attach the ultrasound transducer 150 to some other medical device. The housing 200 is described in greater detail in connection with FIG. 5, below.

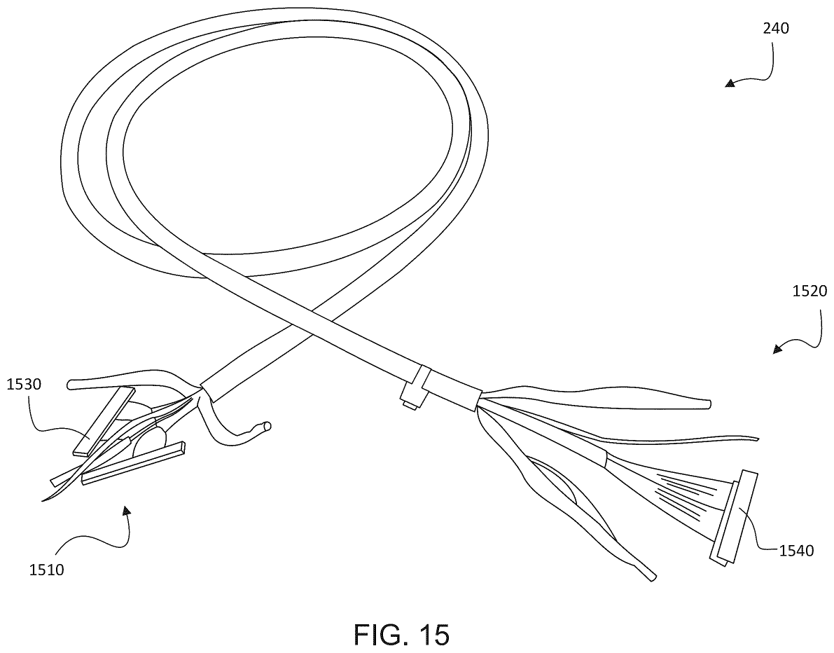

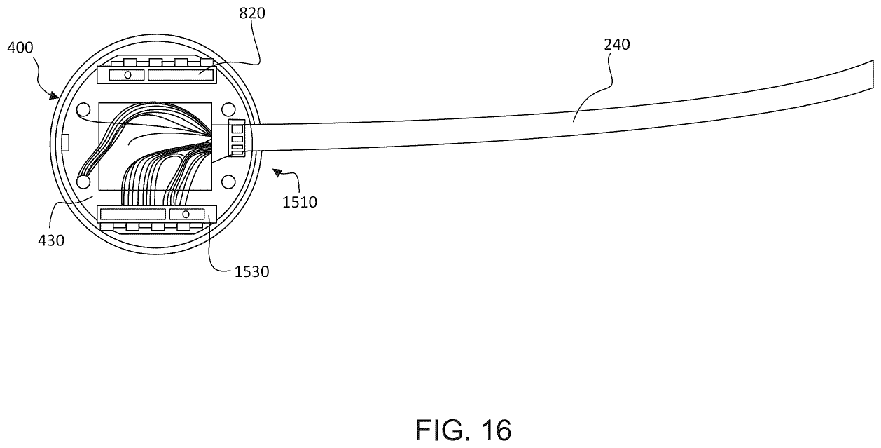

In some embodiments of the disclosure, the ultrasound transducer 150 has a cable assembly 240 extending between the housing 200 and an imaging system 110. In some embodiments, the ultrasound transducer 150 is in wireless communication with the imaging system 110, and therefore no cable assembly 240 is required. The cable assembly 240 is discussed in greater detail below, in connection with FIGS. 15 and 16.

In the embodiments depicted in FIGS. 2A and 2B, the ultrasound transducer 150 has an essentially/substantially cylindrical shape, with the front 210 and back 230 of the housing 200 providing essentially/substantially parallel, circular surfaces, each having a diameter, connected by a curvilinear surface having a height. In some embodiments of the disclosure, the ultrasound transducer 150 may have a height between approximately 10 millimeters (mm) and approximately 30 mm (e.g., about 13 mm) and a diameter between approximately 25 mm and approximately 100 mm (e.g., about 36 mm).

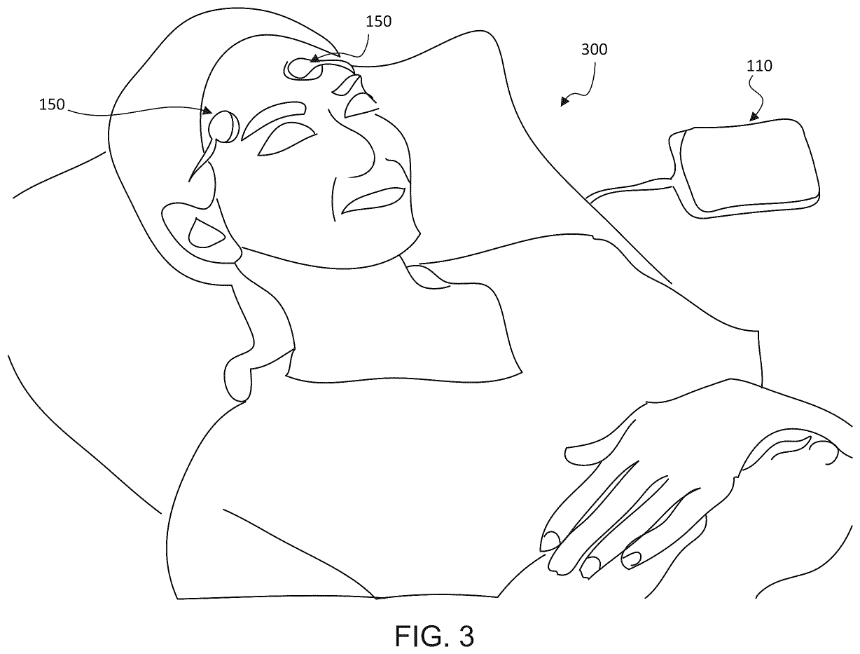

The ultrasound transducer 150, disclosed herein, enables novel use cases for medical ultrasound imaging systems 100. In a non-limiting example, FIG. 3 depicts one or more ultrasound transducers 150 secured to, or worn by, a patient 300. Because of their small size and light weight, the ultrasound transducer 150, may be worn for extended periods of time, thus enabling continuous patient 300 monitoring and eliminating the need for a trained sonographer. Alternatively, when paired with a portable imaging system 110, the ultrasound transducer 150 may be used in point-of-care applications, therefore increasing access to ultrasound imaging technology and improving patient outcomes. Finally, because of its reduced form factor, the ultrasound transducer 150 may be integrated into some other mechanical device, such as a helmet or other apparatus, clothing (e.g., a hat or a jacket), or wearable accessories for scanning of various body parts of the patient 300. The transducer's portability and ability to integrate with apparatuses, clothing, and/or accessories allow for monitoring of patients without requiring the patient to be in a healthcare facility (e.g., a clinic, hospital, doctor's office). In a non-limiting example, the patient may be at home, at work, or participating in various activities. In various embodiments, the transducer may comprise one or more fasteners configured to enable the transducer to be secured to a patient or other human or non-human subject, or elsewhere. Example fasteners include, without limitation, one or more straps (e.g., a strap sized to secure the transducer to a torso or abdomen with sufficient tightness to ensure consistent readings from the same region to be scanned), adhesive (e.g., glue that safe for the skin of the subject), suction cup, hook and loop fasteners, pins, hooks, etc., or any combination thereof.

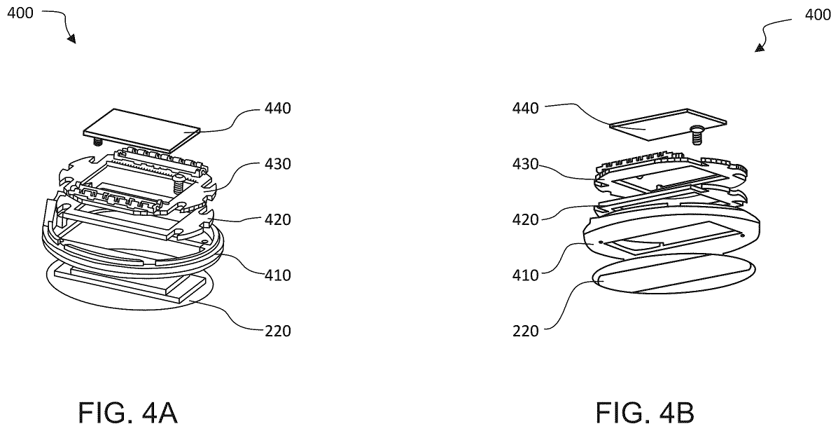

FIGS. 4A and 4B depict a subassembly 400 of an ultrasound transducer 150, in accordance with some of the embodiments of the disclosure. The subassembly 400 may include an acoustic lens 220, a front casing 410 of a housing 200, a conductive mounting pad 420, an interposer board 430, and/or a piezoelectric array 440. The subassembly 400 may contain additional or fewer components in different embodiments. Each of the acoustic lens 220, the front casing 410 of the housing 200, the conductive mounting pad 420, the interposer board 430, and the piezoelectric array 440 are discussed in greater detail below, in connection with other figures.

FIG. 5 depicts an example housing 200. The housing is configured to enclose one or more components of the ultrasound transducer 150. In some embodiments of the disclosure, the housing 200 can include a front casing 410 and a back casing 530. The front casing 410 may have an opening 520 for an acoustic lens 220. The front casing 410 and back casing 530 are configured to be joined together and form an enclosed cavity for containment of the one or more components of the ultrasound transducer 150. The front casing 410 and the back casing 530 may be joined together, in a non-limiting example, mechanically and/or chemically. In a non-limiting example, the front casing 410 and the back casing 530 may be mechanically joined by means of one or more fasteners, such as screws and/or clips. Alternatively or additionally, the front casing 410 and the back casing 530 may be joined together by an adhesive (e.g., one or more glues) and/or filler material (e.g., solder).

In other embodiments, the housing 200 may comprise a single casing with a closeable or sealable panel to access the cavity for containment of the one or more components of the ultrasound transducer 150. In other embodiments, the housing 200 may comprise a single casing with no means of accessing the cavity for containment of the one or more components of the ultrasound transducer 150. In such an embodiment, the housing 200 may be formed over the one or more components of the ultrasound transducer 150 at the time of manufacture.

The housing 200 may be made of metal, such as aluminum or titanium. Alternatively or additionally, the housing 200 may be made of synthetic material, such as any suitable polymer (e.g., one or more plastics). The housing 200 may be made by one or more process of molding, casting, and/or machining. In some embodiments, the housing 200 is made by overmolding the one or more components of the ultrasound transducer 150 to be contained by the housing 200.

In some embodiments, the housing includes a point of egress 540 for a cable assembly 240. The point of egress 540 may be an opening (e.g., a hole) in the front casing 410 and/or the back casing 530. The point of egress 540 may be a hole formed at the joint of the front casing 410 and the back casing 530. In other embodiments the housing requires no point of egress 240, because the ultrasound transducer 150 is in wireless communication with the imaging system 110, and no cable assembly 240 is needed to make electrical connection between the ultrasound transducer 150 and the imaging system 110.

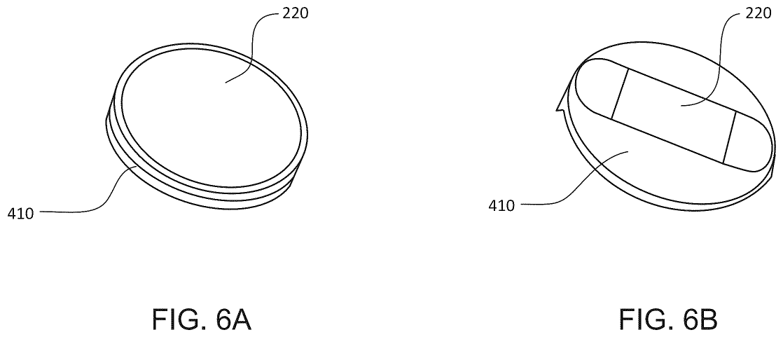

FIGS. 6A and 6B depict example acoustic lenses 220. The acoustic lens 220 directs and transmits sound waves between the piezoelectric array 440 to the surface of the patient's 300 body. In some embodiments of the disclosure, the acoustic lens is integral to the front casing 410 of the housing 200. This may be achieved, in a non-limiting example, by a casting process that involves first creating a mold with a cavity in the desired shape of the acoustic lens 220, filling the cavity with a liquid lens material, spraying the front casing 410 with a primer selected to bond to the lens material, securing the front casing 410 to the mold so that the front casing 410 is in contact with the liquid lens material, degassing the lens material in a vacuum chamber, and curing it at an elevated temperature. Once degassing and curing is complete, the front casing 410 is removed from the mold and an integrally secured acoustic lens 220 is attached. The mold employed in this process may be made of a polymer, such as Delrin, or a metal, such as steel or aluminum.

In other embodiments, the acoustic lens 220 may be molded, machined, or otherwise manufactured independent from the front casing 410. In such a case, the acoustic lens 220 may be secured to the front casing 410 by any means known in the art. In a non-limiting example, the acoustic lens 220 may be secured to the front housing 410 with an adhesive or mechanical fasteners, such as screws and/or clips. The acoustic lens 220 may encompass the entire surface of the front casing 410 as illustrated in FIG. 6A. In other embodiments, the acoustic lens 220 may occupy a smaller portion of the front surface of the front casing 410.

In some embodiments, one or more matching layers are located between the acoustic lens 220 and the piezoelectric array 440. The one or more matching layers help transfer ultrasound energy between the piezoelectric array 440 and the acoustic lens 220. The one or more matching layers may, in a non-limiting example, be cast using a process that includes creating a mold having two parts. The first part contains a cavity in the shape of the desired matching layer, the second part is essentially flat and configured to engage with or be clamped to the first part. Next, applying a mold release agent to the two mold parts, placing an amount of epoxy resin in the cavity of the first part of the mold, and securing the second part of the mold to the first part. Finally, once the epoxy is cured (e.g., by heating the epoxy), the matching layer can be removed from the mold. In some embodiments, the one or more matching layers can be produced or manufactured from any suitable material and process.

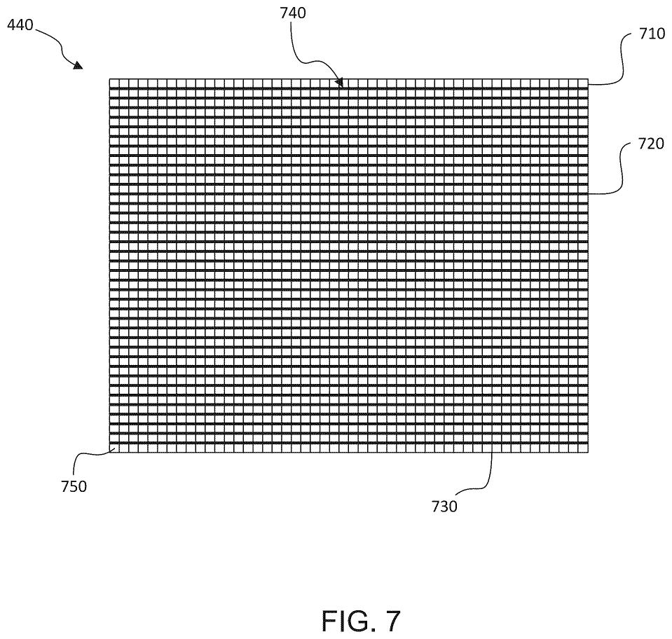

FIG. 7 depicts an example piezoelectric array 440. The piezoelectric array 440 generates ultrasound waves in response to electrical signals, receives the waves reflected off the body tissue being imaged, and converts the received ultrasound waves to electrical signals by means of the piezoelectric effect. In some embodiments of the disclosure, the piezoelectric array 440 is made of a three-dimensional piezoelectric composite material, a material having piezoelectric components 750 and/or non-piezoelectric components 740. The piezoelectric array 440 includes a series of elements 710, oriented parallel to one another, and extending in a first direction. Each element 710 of the plurality of elements 710 may emanate/extend from a bottom of the piezoelectric array 440. The elements 710 of the piezoelectric array 440 may be separated by a series of grooves 720 partially cut into the surface of the three-dimensional piezoelectric composite material. The grooves 720 may be cut to a depth that is less than 100% of a depth of the piezoelectric array 440. In a non-limiting example, the grooves 720 may be cut to a depth of about 70%, 80%, or 90% of the depth of the piezoelectric array 440. The grooves 720 may be cut into grooves formed from the non-piezoelectric components of the piezoelectric composite material. The non-piezoelectric component 740 may be an epoxy resin. Cutting of a material may be achieved via various machining (e.g., milling) techniques suitable for removal of portions of the material being cut. In some embodiments, a rotary cutter (e.g., a diamond saw blade) may be used with a milling machine (e.g., a water-cooled cutting machine).

Each element 710 of the plurality of elements may have an electrode affixed to one surface of the element 710. The bottom of the piezoelectric array 440 may also have an electrode affixed to a surface. One or more of the electrodes may be plated on the surface to which it is affixed. One or more of the electrodes may be/include a gold layer. The electrodes affixed to each element 710 may provide a signal electrode. The electrodes affixed to the bottom of the piezoelectric array 440 may provide a ground electrode.

The piezoelectric array 440 may be composed of a 1-3 piezoelectric composite material. A 1-3 piezoelectric composite material is a three-dimensional piezoelectric composite material whose piezoelectric components 750 have connectivity in one dimension and whose non-piezoelectric components 740 have connectivity in three dimensions. Connectivity, here, involves material continuity. In a non-limiting example, a 1-3 piezoelectric composite material may be a three-dimensional material including a plurality of columnar components of a piezoelectric material 750, such as lead zirconate titanate, and a mass of non-piezoelectric material 740, such as an epoxy resin. The plurality of columnar piezoelectric components 750 may be oriented such that they each extend in a same first direction. The plurality of columnar piezoelectric components 750 may be equally spaced apart from one another in a second direction and/or a third direction perpendicular to the second direction. The plurality of columnar piezoelectric components 750 may be oriented such that they form a series of rows and columns. The mass of non-piezoelectric material 740 may form a substrate around the plurality of columnar piezoelectric components 750. The nonpiezoelectric material 740 may form a first series of grooves 730 extending in the second direction and a second series of grooves 730 extending in the third direction perpendicular to the second direction.

A 1-3 piezo composite material may be manufactured, in a non-limiting example, by a method including one or more of the following steps (in any order, such as): (i) cutting (e.g., via a machining technique suited to cutting piezoelectric material) a first series of parallel grooves, extending in a first direction, into a surface of a piezoelectric material, such as lead zirconate titanate; (ii) cutting a second series of parallel grooves, extending in a second direction, into the surface of the piezoelectric material; each groove in the first series of grooves and each groove in the second series of grooves may be cut to a depth that is less than 100% (e.g., 70%, 80%, or 90%) of a depth of the piezoelectric material, so that a bottom body remains intact; (iii) filling the first series of parallel grooves and the second series of parallel grooves with a non-piezoelectric material, such as an epoxy resin; and/or (iv) removing the intact bottom body.

The piezoelectric array 440 may be composed of a 2-2 piezoelectric composite material. A 2-2 piezoelectric composite material is a three-dimensional piezoelectric composite material whose piezoelectric components 750 have connectivity in two dimensions and whose non-piezoelectric components 740 have connectivity in two dimensions. Connectivity, here, involves material continuity. In a non-limiting example, a 2-2 piezoelectric composite material may be a three-dimensional material including a plurality of parallel planar components of a piezoelectric material 750, such as lead zirconate titanate, separated from one another by one of a plurality of parallel planar components of a non-piezoelectric material 740, such as an epoxy resin. The nonpiezoelectric material 740 may form a first series of grooves 720 extending in a first direction.

A 2-2 piezo composite material may be manufactured, in a non-limiting example, by a method including one or more of the following steps (in any order, such as): (i) cutting a series of parallel grooves into a surface of a piezoelectric material, such as lead zirconate titanate; each groove in the series of grooves may be cut to a depth that is less than a depth of the piezoelectric material, so that a bottom body remains intact; (ii) filling the series of parallel grooves with a non-piezoelectric material, such as an epoxy resin; and/or (iii) removing the intact bottom body.

A piezoelectric array 440 may be manufactured, in a non-limiting example, from a piezoelectric composite material by a method including one or more of the following steps (in any order, such as): (i) attaching a first electrode to a top surface of the piezoelectric composite material and second electrode to the bottom surface of the piezoelectric composite material; the electrodes may be plated to the surfaces and may be made of gold; and/or (ii) partially cutting the piezoelectric composite material along a series of non-piezoelectric grooves in the material, to a depth less than 100% of a thickness of the piezoelectric composite material to form array elements. The grooves of non-piezoelectric material may be an epoxy resin. The depth to which the three-dimensional piezoelectric composite material is cut may be, in a non-limiting example, about 70% of the thickness of the piezoelectric composite material. The depth to which the three-dimensional piezoelectric composite material is cut may be, in a non-limiting example, about 80% of the thickness of the piezoelectric composite material. The depth to which the three-dimensional piezoelectric composite material is cut may be, in a non-limiting example, about 90% of the thickness of the piezoelectric composite material.

By cutting a piezoelectric composite material along its non-piezoelectric grooves to form elements 710 of a piezoelectric array 440, compositional variation between elements is minimized or otherwise reduced. The resulting piezoelectric array creates fewer unwanted oscillations than other piezoelectric arrays.

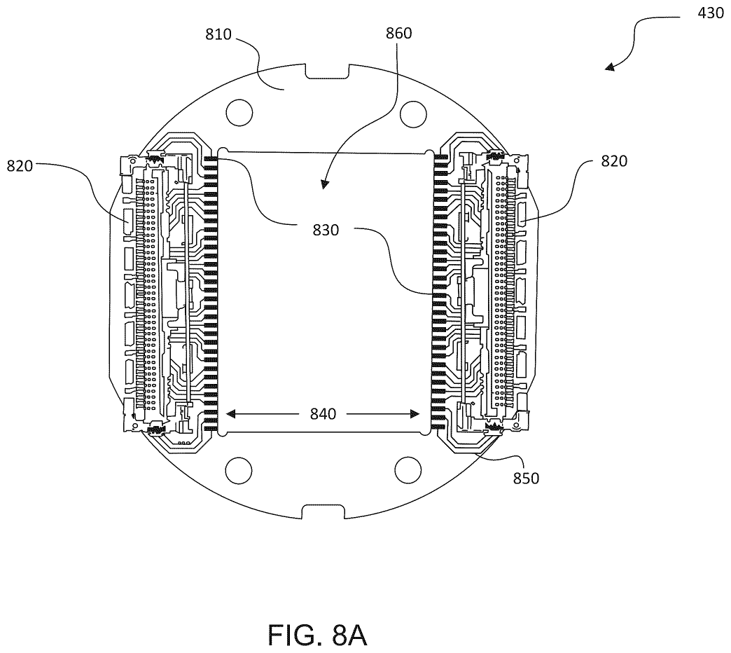

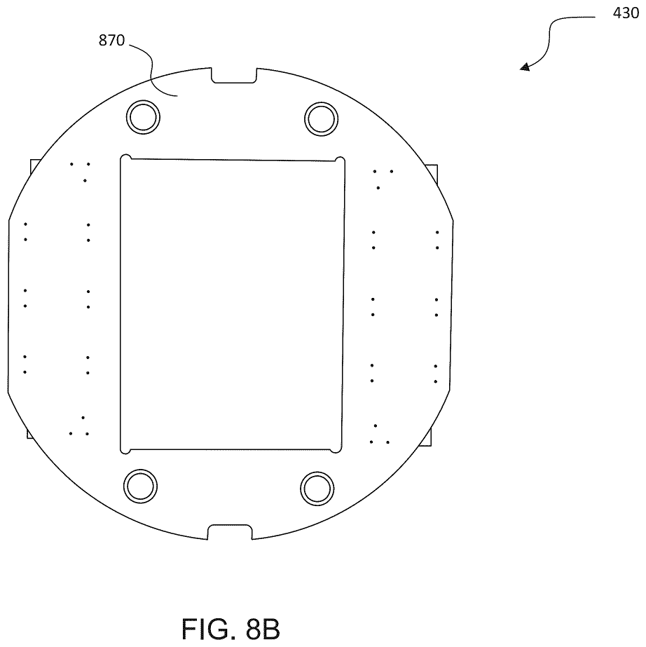

FIGS. 8A and 8B depict an example interposer board 430. The interposer board 430 provides electrical interface between the piezoelectric array 440 and the cable assembly 240. In some embodiments of the disclosure, the interposer board 430 includes a printed circuit board 810. The printed circuit board 810 may include one or more layers of conductive material laminated onto and/or between layers of nonconductive material. The interposer board 430 may include one or more signal electrodes 830, comprising an area of exposed conductive material, on a surface of the printed circuit board. In some embodiments, there is one signal electrode 830 for each array element 710 of the piezoelectric array 440. The interposer board 430 may also include one or more receptacle 820. The receptacle 820 may include one or more electrical connectors connected to one or more of the signal electrodes 830 by a conductive trace 850 on the printed circuit board 810. In some embodiments, each signal electrode 830 is connected to one connector of a receptacle 820 by a conductive trace 850.

The one or more receptacles 820 may be configured to join to one or more connectors 1530 (depicted in, e.g., FIGS. 15 and 16) of the cable assembly 240. The cable assembly 240 is discussed in greater detail below, in connection with FIG. 15. The one or more receptacle 820 may be an assembly configured to create electrical and mechanical connection between the interposer board 430 and the cable assembly 240. In other embodiments the receptacles may be pads or terminals on a surface of the printed circuit board 810 to which cables or wires of the cable assembly 240 can be electrically and mechanically joined.

In some embodiments, the interposer board 430 has a cutout 860 in the printed circuit board 810. The cutout 860 may be approximately the size and shape of the piezoelectric array 440, such that the piezoelectric array 440 can be positioned in the cutout 860. The cutout 860 has a measure 840 in at least one direction. In some embodiments, one or more signal electrodes 830 may be equally spaced along a first edge of the cutout 860 and one or more signal electrodes may be equally spaced along a second edge of the cutout 860 opposite the first edge of the cutout 860. The one or more signal electrodes 830 equally spaced along the first edge of the cutout 860 may be connected to one or more electrical connectors of a first receptacle 820, and the one or more signal electrodes 830 equally spaced along the second edge of the cutout 860 may be connected to one or more electrical connectors of the second receptacle 820. The signal electrodes 830 equally spaced along the first edge of the cutout 860 may be positioned to align with a first set of elements 710 of the piezoelectric array 440 and the signal electrodes 840 equally spaced along the second edge of the cutout 860 may be positioned to align with a second set of elements 710 of the piezoelectric array 440.

In some embodiments of the disclosure, the printed circuit board 810 of the interposer board 430 has a fully exposed conductive layer 870 on a surface of the printed circuit board 810, as depicted in FIG. 8B. The fully exposed conductive layer 870 is connected to one or more electrical connectors of one or more receptacle 820. In some embodiments, the fully exposed conductive layer 870 is a gold layer (e.g., comprising gold or an alloy thereof). In other embodiments, the fully exposed conductive layer 850 is made of some other conductive metal, in a non-limiting example, aluminum or copper. The fully exposed conductive layer 870 may be used to provide a ground electrode.

In some embodiments, the interposer board 430 has an impedance tuner. The impedance tuner may be one or more passive electrical components for electrical impedance tuning of the circuit or circuits formed between the ultrasound transducer 150 and the imaging system 110. In some embodiments, one or more, but not all, of the passive electrical components of the impedance tuner are part of the interposer board 430, while other passive electrical components of the impedance tuner are incorporated into the imaging system 110 or the cable assembly 240. In other embodiments of the disclosure, neither the interposer board 430 nor the ultrasound transducer 150 contains an impedance tuner. In such a case, the impedance tuner may be entirely incorporated into either the imaging system 110 or the cable assembly 240.

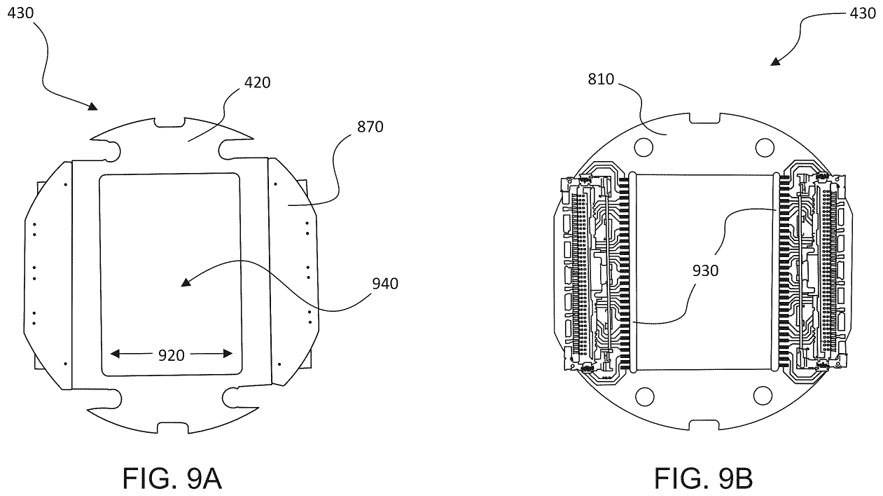

FIGS. 9A and 9B depict an example interposer board 430 with a conductive mounting pad 420 attached to it. The conductive mounting pad 420 provides mechanical and electrical connection between the exposed conductive layer 870 of the interposer board 430 and the bottom surface of the piezoelectric array 440. In some embodiments of the disclosure, the conductive mounting pad 420 may be a copper pad. The conductive mounting pad 420 may have a cutout 940 in it. The cutout 940 in the conductive mounting pad 420 is smaller in at least one dimension than the cutout 860 in the printed circuit board 810 of the interposer board 430. In a non-limiting example, the cutout 940 in the conductive mounting pad 420 may have a measure 920 in one direction that is smaller than a measure 840 of the cutout 860 in the printed circuit board 810 in the same direction.

In some embodiments, the conductive mounting pad 420 is attached to the exposed conductive layer 870 of the interposer board 430 in a manner that provides mechanical and electrical connection between the conductive mounting pad 420 and the exposed conductive layer 870. The conductive mounting pad 420 may be attached to the exposed conductive layer 870 of the interposer board 430 with a conductive epoxy. The two parts may alternatively be soldered to one another to achieve the same end. In other embodiments of the disclosure, mechanical and electrical connection between the conductive mounting pad 420 and the exposed conductive layer 870 of the interposer board 430 may be achieved by separate means. In some embodiments, the conductive mounting pad 420 may be integral to the printed circuit board 810 of the interposer board 430. In a non-limiting example, the conductive mounting pad 420 may be one or more conductive and/or nonconductive layers of the printed circuit board 810. In such a case, electrical connection between the conductive mounting 420 and one or more electrical connectors of the one or more receptacles 820 of the interposer board 430 may be achieved via structures or conductive traces in the printed circuit board 810 of the interposer board 430.

The conductive mounting pad 420 may be located relative to the printed circuit board 810 of the interposer board 430 so that the cutout 860 in the printed circuit board 810 and the cutout 940 in the conductive mounting pad 420 are concentrically located relative to one another. Because the cutout 940 in the conductive mounting pad 420 is smaller in at least one dimension than the cutout 860 in the printed circuit board 810, the relative position of the conductive mounting pad 420 and the printed circuit board 810 create one or more overhang regions 930 where the conductive mounting pad 420 overhangs the cutout 860 in the printed circuit board 810. The overhang regions 930 can provide a location on which the piezoelectric array 440 can be placed.

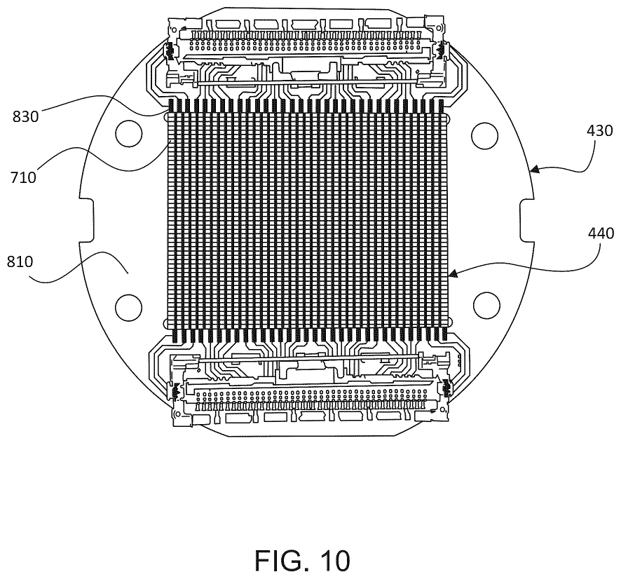

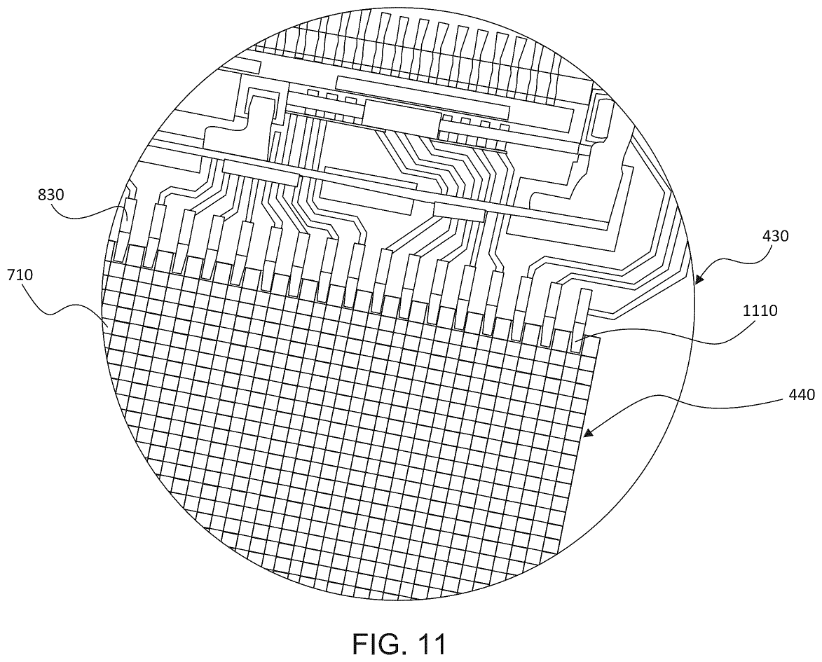

FIG. 10 depicts an example piezoelectric array 440 attached to an interposer board 430. In some embodiments of the disclosure, the piezoelectric array 440 is positioned in the cutout 860 of the printed circuit board 810 of the interposer board 430 such that the ground plane of the piezoelectric array 440 is on the one or more overhang region 930 that is formed by the mounting pad 420 and the cutout 860 in the printed circuit board 810. The piezoelectric array 440 may be positioned so that each element 710 of the piezoelectric array 440 is aligned with a signal electrode 830 on the printed circuit board 810 of the interposer board 430. In some embodiments, the ground plane of the piezoelectric array 440 is mechanically and electrically bonded to the conductive mounting pad 420. This mechanical and electrical bond may be achieved with a conductive epoxy applied to the ground plane of the piezoelectric array 440 and the conductive mounting pad 420. In other embodiments, the two components may be soldered together. In other embodiments, electrical and mechanical connection may be achieved by separate means.

FIG. 11 depicts electrical connections 1110 between elements 710 of the piezoelectric array 440 and signal electrodes 830 on the interposer board 430. In some embodiments of the disclosure, each of the one or more elements 710 of the piezoelectric array 440 is connected to one of one or more signal electrodes 830 on the interposer board 430. In some embodiments, each of the connections 1110 is formed by applying a conductive epoxy between an element 710 of the piezoelectric array 440 and a signal electrode 830 of the interposer board 430. A viscous epoxy may be chosen to ensure easy and accurate application to the desired locations. In some embodiments, each connection 1110 is formed by first soldering a wire to the signal electrode 830 of the interposer board so that one end of the wire extends over an element 710 of the piezoelectric array 440. The wire may be trimmed to an appropriate length. Once soldered in place, a conductive epoxy may be applied to the wire and a part of the element 830 of the piezoelectric array 440 to bond the wire to the element 830.

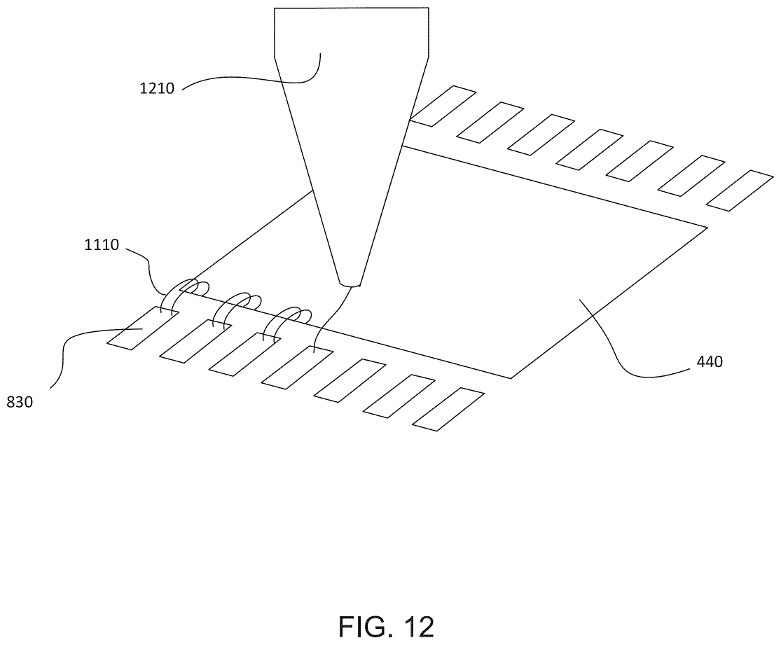

In other embodiments, a wire bonding process may be employed to create an electrical connection 1110 between elements 710 of the piezoelectric array 440 and signal electrodes 830 of the interposer board 430. FIG. 12 depicts such a wire bonding process. The wire bonding process may include: plasma cleaning the elements 710 of the piezoelectric array 440 and the signal electrodes 830 of the interposer board 430; bonding each one of the one or more elements 710 to a signal electrode 830 by a traditional wire bonding technique; and/or covering the electrical connection 1110 with an encapsulating material. The encapsulating material may be chosen to promote the mechanical stability of the connection 1110. The encapsulation material may be chosen to provide electromagnetic interference shielding.

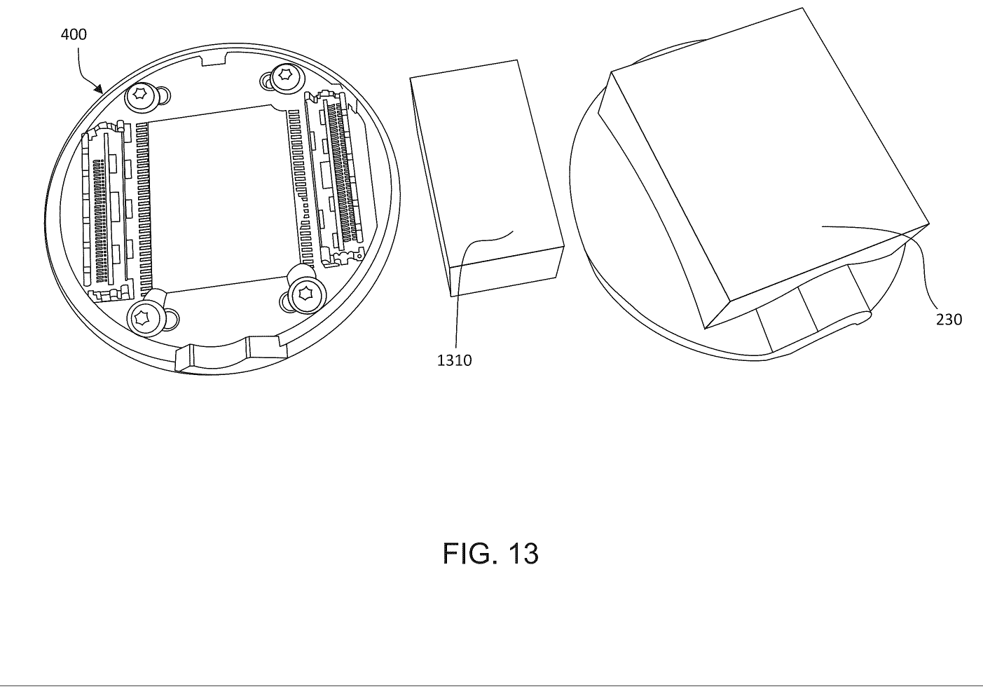

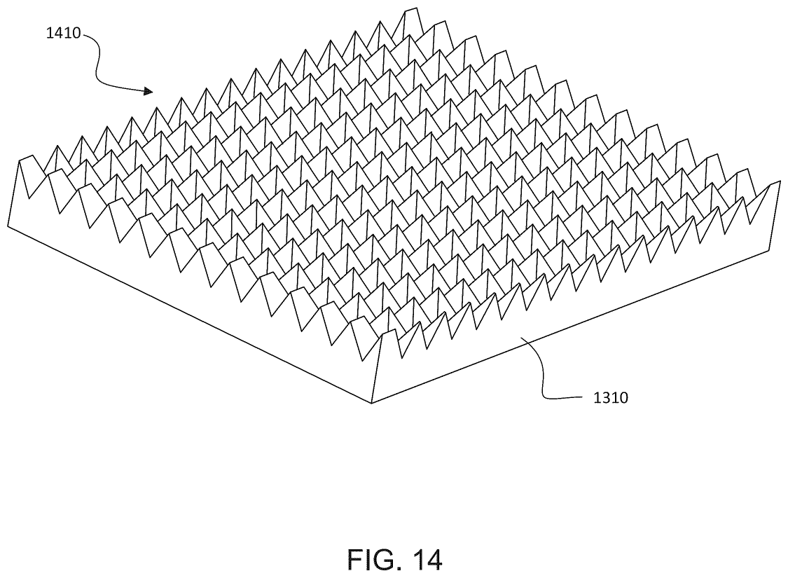

FIG. 13 depicts a subassembly 400 of an ultrasound transducer 150, a backing layer 1310, and the back casing 530. The subassembly 400 may be the subassembly described in connection with FIG. 4. The backing layer 1310 is located between the piezoelectric array 440 and the back 230 of the ultrasound transducer 150. In some embodiments of the disclosure, the backing layer 1310 is positioned between the subassembly 400 and the back casing 530. The backing layer 1310 may be held in place by the back casing 530. The function and composition of the backing layer 1310 is discussed in greater detail below, in connection with FIG. 14.

FIG. 14 depicts an example backing layer 1310. A backing layer 1310 is a component that attenuates backward emitted sound waves, and/or their echoes. Backward emitted sound waves are sound waves emitted by the piezoelectric array 440 in a direction opposite the patient 300. In some embodiments of the disclosure, the backing layer 1310 may be composed of an epoxy resin. The epoxy resin may serve as a substrate for other materials selected to change the acoustical properties of the backing layer 1310. In some embodiments, Tungsten powder may be added to the epoxy resin to increase the backing layer's 1310 weight per unit volume. In some embodiments, beads may be added to the epoxy to produce a backing layer 1310 with improved sound attenuating properties. The beads may be made of glass. The beads may also be hollow. The beads may be micro balloons. The beads may have a diameter, in a non-limiting example, of approximately five micrometers (μm).

The backing layer 1310 may also include a phase disruptive component 1410. A phase disruptive component 1410 is a component that helps ensure backward emitted waves are not reflected to the piezoelectric array 440 in phase. In some embodiments of the disclosure, the phase disruptive component 1410 may be, or may comprise, grooves in a surface of the backing layer 1310. The surface may be a surface facing away from the piezoelectric array. The grooves may be spaced apart from each other and extend in multiple different directions. In a non-limiting example, a first series of grooves may extend in a first direction and a second series of grooves may extend in a second direction perpendicular to the first direction. The grooves in each series of grooves may be equally spaced along the surface of the backing layer 1310. In some embodiments, the grooves are V-shaped grooves that create a series of pyramidal structures on the surface of the backing layer 1310. In certain embodiments, these or other structures that decrease in width until a pointed tip, or otherwise comprise pointed tips, may be used. In other embodiments, the grooves are U-shaped grooves that produce a series of cubic structures on the surface of the backing layer 1310.

By modifying the composition of the backing layer 1310 to improve its sound attenuating qualities, as described above, and/or by incorporating a phase disruptive component 1410, the backing layer 1310 can be made shorter than would otherwise be necessary to achieve the same performance. This enables a reduction in size of the ultrasound transducer 150, described herein.

FIG. 15 depicts an example cable assembly 240. The cable assembly 240 provides electrical connection between the ultrasound transducer 150 and the imaging system 110. The cable assembly 240 has a transducer end 1510 and a system end 1540. The cable assembly 240 comprises one or more cables or wires extending between the transducer end 1510 and system end 1540. In some embodiments of the disclosure, the transducer end 1510 may include one or more connectors 1530 configured to attach to the receptacles 820 on the interposer board 430. The system end 1520 also may include one or more connectors 1540 configured to attach to one or more receptacles associated with the imaging system 110. In other embodiments, the cable assembly 240 may not include connectors 1530, 1540 at one, or both, of the transducer end 1510 and the system end 1540. In such a case, the wires or cables comprising the cable assembly 240 may be joined to the ultrasound transducer and/or the imaging system by, in a non-limiting example, solder joints or other means connection.

In some embodiments, an impedance tuner, passive electrical components for electrical impedance tuning of the circuit or circuits formed between the ultrasound transducer 150 and the imaging system 110, may integrated into the cable assembly 240. The impedance tuner may be located at the system end 1520 of the cable assembly 240 or at the transducer end 1510 of the cable assembly 240. In some embodiments, no passive electrical components of the impedance tuner are placed at the transducer end 1510 of the cable assembly 240. In some embodiments, the passive electrical components of the impedance tuner may be integrated into the imaging system 110 so that no passive electrical components of the impedance tuner are incorporated into either the ultrasound transducer 150 or its cable assembly 240.

The cable assembly 240 may include one or more layers of insulating, nonconductive material formed over one or more of the wires or cables extending between the transducer end 1510 and the system end 1520. The cable assembly 240 may include one or more shields, a common conductive layer for electromagnetic shielding, over one or more of the wires or cables extending between the transducer end 1510 and the system end 1520. In some embodiments, the cable assembly includes strain reliefs at one, or both, of the transducer end 1510 and the system end 1540.

FIG. 16 depicts the cable assembly 240 connected to an interposer board 430 of a subassembly 400 of an ultrasound transducer 150. In some embodiments of the disclosure, one or more of the connectors 1530 of the cable assembly 240 is connected to one or more receptacles 820 on the interposer board 430. In other embodiments, connection between the cable assembly 240 and the interposer board 430 may be achieved by soldering, or otherwise joining, cables or wires of the cable assembly 240 to pads or terminals on the interposer board 430. Any type of suitable electrical connection may be used to achieve the same result.

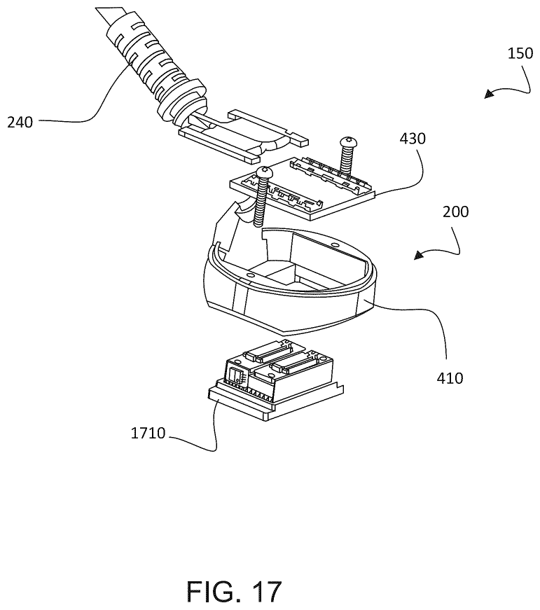

In some embodiments of the disclosure, various components of the ultrasound transducer 150 may be integrated into one or more subassemblies 1710. FIG. 17 depicts an ultrasound transducer comprising an acoustic lens, one or more matching layers, a piezoelectric array, a backing layer, an interposer board 430, a cable assembly 240, and a housing 200, which can comprise a front casing 410 and back casing. The acoustic lens, the one or more matching layers, the piezoelectric array, and the backing layer are integrated into a subassembly 3210. The subassembly 3210 may further comprise a flexible printed circuit board to make electrical connections between the piezoelectric array and the interposer board 430.

In other embodiments, the interposer board 430 may be integrated into the subassembly 3210. In some embodiments, the subassembly 3210 may include additional or fewer components than are illustrated in FIG. 17. In some embodiments of the disclosure, multiple subassemblies may be utilized in the construction of the ultrasound transducer 1710. In a non-limiting example, a first subassembly 1710 may comprise the acoustic lens and the one or more backing layer, while a second subassembly 1710 may comprise the piezoelectric array and the backing layer.

Example embodiments of the disclosed transducer have a small form factor, allowing it to be wearable. The transducer may use composite piezoelectric materials (e.g., 1-3 or 2-2 composites) that create fewer unwanted oscillations than material in conventional (bulkier/heavier) transducers. Tungsten powder and/or micro balloons may help attenuate backward-emitted waves. V-grooves may be used in a backing layer so that backward emitted waves are not reflected back to array elements in phase. Array elements may be diced along epoxy resin grooves of the piezoelectric components to reduce variation among elements.

Various non-limiting example embodiments include the following combinable embodiments/features:

Embodiment AA: An ultrasound transducer comprising at least one of: a housing; an acoustic lens secured to the housing; a piezoelectric array; a backing layer comprising a phase disruptive component; an interposer board coupled to the piezoelectric array; or a cable assembly coupled to the interposer board.

Embodiment AB: The ultrasound transducer of Embodiment AA, wherein the piezoelectric array comprises array elements at least partially cut along epoxy resin grooves.

Embodiment AC: The ultrasound transducer of either Embodiment AA or AB, wherein the housing comprises a front casing and a back casing, and wherein the acoustic lens is secured to the front casing.

Embodiment AD: The ultrasound transducer of any of Embodiments AA-AC, wherein the phase disruptive component comprises grooves.

Embodiment AE: The ultrasound transducer of Embodiment AD, wherein the grooves are V-shaped grooves.

Embodiment AF: The ultrasound transducer of any of Embodiments AA-AE, wherein the backing layer further comprises beads.

Embodiment AG: The ultrasound transducer of Embodiment AF, wherein the beads have a hollow interior.

Embodiment AH: The ultrasound transducer of Embodiment AG, wherein the backing layer further comprises tungsten powder.

Embodiment AI: The ultrasound transducer of any of Embodiments AA-AH, further comprising one or more matching layers, wherein each of the one or more matching layers comprises an epoxy resin.

Embodiment AJ: The ultrasound transducer of any of Embodiments AA-AI, wherein the interposer board comprises one or more receptacles for one or more cable assembly connectors.

Embodiment AK: The ultrasound transducer of any of Embodiments AA-AJ, wherein the interposer board comprises a cutout sized to fit the piezoelectric array.

Embodiment AL: The ultrasound transducer of any of Embodiments AA-AK, further comprising a copper pad having a cutout smaller than the piezoelectric array, wherein the piezoelectric array comprises a ground electrode, and wherein the ground electrode is bonded, via a conductive epoxy, to an exposed part of the copper pad.

Embodiment AM: The ultrasound transducer of any of Embodiments AA-AL, wherein the transducer does not comprise an impedance tuner.

Embodiment AN: The ultrasound transducer of any of Embodiments AA-AM, wherein the cable assembly comprises a cable extending from a transducer end to a system end, and wherein the system end of the cable comprises one or more electrical components configured for electrical impedance tuning.

Embodiment AO: The ultrasound transducer of any of Embodiments AA-AN, wherein the piezoelectric array comprises a 1-3 composite material.

Embodiment AP: The ultrasound transducer of any of Embodiments AA-AO, wherein the piezoelectric array comprises a 2-2 composite material.

Embodiment BA: A method of using any of the ultrasound transducers of Embodiments AA-AP.

Embodiment CA: A method of manufacturing any of the ultrasound transducers of Embodiments AA-AP.

Embodiment DA: A method of manufacturing an ultrasound transducer, comprising: connecting an element of a composite piezoelectric array to a signal electrode on an interposer board by at least one of: placing conductive epoxy between the element of the piezoelectric array and the signal electrode on the interposer board; soldering an aluminum wire between the element of the composite piezoelectric array and the signal electrode on the interposer board, trimming the aluminum wire, and applying conductive epoxy to the aluminum wire, the element of the composite piezoelectric array, and the signal electrode on the interposer board; or plasma cleaning the element of the composite piezoelectric array, bonding the element of the composite piezoelectric array to the signal electrode on the interposer board with a wire, and covering the element of the composite piezoelectric array, the signal electrode on the interposer board, and the wire with encapsulation material.

Embodiment DB: The method of Embodiment DA, further comprising at least partially cutting a 1-3 or 2-2 composite piezoelectric material along epoxy resin grooves of the 1-3 or 2-2 composite piezoelectric material.

Embodiment DC: The method of either Embodiment DA or DB, wherein the 1-3 or 2-2 composite piezoelectric material is at least partially cut to a depth of less than 100%.

Embodiment DD: The method of any of Embodiments DA-DB, wherein the 1-3 or 2-2 composite piezoelectric material is at least partially cut to a depth of about 80% to leave a ground electrode intact.

Embodiment EA: A method of manufacturing an ultrasound transducer, comprising connecting an element of a composite piezoelectric array to a signal electrode on an interposer board, wherein connecting the element to the signal electrode comprises placing conductive epoxy between the element of the piezoelectric array and the signal electrode on the interposer board.

Embodiment FA: A method of manufacturing an ultrasound transducer, comprising connecting an element of a composite piezoelectric array to a signal electrode on an interposer board, wherein connecting the element to the signal electrode comprises soldering an aluminum wire between the element of the composite piezoelectric array and the signal electrode on the interposer board, trimming the aluminum wire, and applying conductive epoxy to the aluminum wire, the element of the composite piezoelectric array, and the signal electrode on the interposer board.

Embodiment GA: A method of manufacturing an ultrasound transducer, comprising connecting an element of a composite piezoelectric array to a signal electrode on an interposer board, wherein connecting the element to the signal electrode comprises plasma cleaning the element of the composite piezoelectric array, bonding the element of the composite piezoelectric array to the signal electrode on the interposer board with a wire, and covering the element of the composite piezoelectric array, the signal electrode on the interposer board, and the wire with encapsulation material.

Embodiment HA: An ultrasound transducer manufactured according to any of the methods of Embodiments DA-GA.

Embodiment IA: An ultrasound transducer comprising piezoelectric array elements and a backing layer with a phase disruptive component so that backward-emitted waves are not reflected, in phase, back to the piezoelectric array elements.

Embodiment IB: The transducer of Embodiment IA, wherein the phase disruptive component comprises grooves.

Embodiment IC: The transducer of either Embodiment IA or IB, further comprising a wireless communication element configured to enable the ultrasound transducer to communicate with at least one of an imaging system and/or a computing device.

Embodiment ID: The transducer of any of Embodiments IA-IC, wherein the transducer is a medical ultrasound imaging transducer.

Embodiment IE: The transducer of any of Embodiments IA-ID, wherein the transducer is wearable.

Embodiment IF: The transducer of any of Embodiments IA-IE, further comprising a fastener configured to secure the transducer to a body part of a subject.

Embodiment JA: An ultrasound transducer comprising: a piezoelectric array; an interposer board coupled to the piezoelectric array; a cable assembly coupled to the interposer board; and a backing layer comprising a phase disruptive component.

Embodiment JB: The ultrasound transducer of Embodiment JA, wherein the piezoelectric array comprises array elements at least partially cut along epoxy resin grooves.

Embodiment JC: The ultrasound transducer of either Embodiment JA or JB, further comprising a housing with a front casing and a back casing.

Embodiment JD: The ultrasound transducer of any of Embodiments JA-JC, further comprising an acoustic lens secured to housing, and/or to a front casing of a housing.

Embodiment JE: The ultrasound transducer of any of Embodiments JA-JD, wherein the phase disruptive component comprises grooves.

Embodiment JF: The ultrasound transducer of any of Embodiments JA-JE, wherein phase-disruptive grooves are V-shaped grooves.

Embodiment JG: The ultrasound transducer of any of Embodiments JA-JF, wherein the backing layer comprises beads.

Embodiment JH: The ultrasound transducer of any of Embodiments JA-JG, wherein the backing layer comprises beads with a hollow interior.

Embodiment JI: The ultrasound transducer of any of Embodiments JA-JH, wherein the backing layer comprises tungsten powder.

Embodiment JJ: The ultrasound transducer of any of Embodiments JA-JI, further comprising one or more matching layers.

Embodiment JK: The ultrasound transducer of any of Embodiments JA-JJ, further comprising one or more matching layers, each layer comprising an epoxy resin.

Embodiment JL: The ultrasound transducer of any of Embodiments JA-JK, wherein the interposer board comprises one or more receptacles for one or more cable assembly connectors.

Embodiment JM: The ultrasound transducer of any of Embodiments JA-JL, wherein the interposer board comprises a cutout sized to fit the piezoelectric array.

Embodiment JN: The ultrasound transducer of any of Embodiments JA-JM, further comprising a copper pad having a cutout smaller than the piezoelectric array.

Embodiment JO: The ultrasound transducer of any of Embodiments JA-JN, wherein the piezoelectric array comprises a ground electrode.

Embodiment JP: The ultrasound transducer of any of Embodiments JA-JO, wherein the ground electrode is bonded, via a conductive epoxy, to an exposed part of the copper pad.

Embodiment JQ: The ultrasound transducer of any of Embodiments JA-JP, wherein the transducer does not comprise an impedance tuner.

Embodiment JR: The ultrasound transducer of any of Embodiments JA-JQ, wherein the cable assembly comprises a cable extending from a transducer end to a system end.

Embodiment JS: The ultrasound transducer of any of Embodiments JA-JT, wherein the system end of the cable comprises one or more electrical components configured for electrical impedance tuning.

Embodiment JT: The ultrasound transducer of any of Embodiments JA-JS, wherein the piezoelectric array comprises a 1-3 composite material and/or a 2-2 composite material.

Embodiment KA: An ultrasound imaging system comprising a transducer of, or corresponding to, any of Embodiments AA-JT.

Embodiment KB: The ultrasound imaging system of Embodiment KA, configured to interface with a smart device and/or other computing device to transmit, receive, and/or exchange data.

Embodiment KC: The ultrasound imaging system of either Embodiment KA or KB, wherein the data comprises, or consists of, instructions.

Embodiment KD: The ultrasound imaging system of any of Embodiment KA-KC, wherein the data comprises, or consists of, imaging data and/or images.

Embodiment KE: The ultrasound imaging system of any of Embodiments KA-KD, further comprising a smart device and/or other computing device configured to wirelessly communicate with at least one of the ultrasound imaging system and/or the transducer.

### Example Ultrasound Image Processing Embodiments

Below are detailed descriptions of various concepts related to and embodiments of techniques, approaches, methods, apparatuses, and systems for processing and analysis of anatomical structures using an ultrasound system. The various concepts introduced above and discussed in detail below may be embodied in any of numerous ways, as the described concepts are not limited to any particular manner of embodiment. Examples of specific embodiments and applications are provided primarily for illustrative purposes.

Medical ultrasound imaging systems may be used to generate images for health evaluation. Ultrasound imaging is a non-invasive method used to visualize internal body structures. Imaging performed using ultrasound is conducted via a transducer probe, which is a transducer device capable of both sending and receiving sound waves at various frequencies. During ultrasound imaging, the transducer dispatches high-frequency sound waves into a patient's body. The high-frequency waves propagating through the patient's body encounter different tissues and structures. Depending on the density and composition of these tissues, some waves are absorbed, while others are reflected back as “echoes” to the transducer. The echoes produced are received and processed into images that may then be analyzed or reviewed to better evaluate a patient's health.

Echoes captured by the transducer are converted into electrical signals, which are then processed to determine attributes like depth, intensity, and location based on the time taken for the echo's return and its strength. This processed information is then used to generate an image of the internal structures from which the echoes reflected, which may then be subsequently processed using the machine-learning techniques described herein. Various types of images may be constructed via the ultrasound devices, including two-dimensional (2D) or three-dimensional (3D) images.

The machine-learning techniques described herein may be utilized to process B-mode images or colorflow images, in some implementations. B-mode images (sometimes referred to as “brightness mode” images) may include 2D cross-sectional images of the anatomical structures within the body captured via reflection of ultrasound waves. In B-mode images, tissues that produce strong reflections, such as bone or dense tissues, may appear bright white, while those that produce weaker reflections, like fluid-filled cavities, may appear darker. This grayscale differentiation may be utilized to detect or classify various structures, conditions, and potential pathologies within the patient.

Colorflow imaging (sometimes referred to as “color doppler imaging”) is used to produce colorflow images, which indicate visual information about blood flow within anatomical structures of a patient. Colorflow images are generated based on the frequency of sound waves changes as they reflect off moving objects, such as blood cells. Colorflow imaging may include superimposing blood flow information (which may be indicated via different colors, hues, or shades to indicate flow direction or other flow properties) on one or more B-mode images. The colorflow images may be indicated in the form of a color map. In some implementations, a red color may indicate flow towards the transducer, and a blue color may indicate flow away from the transducer. Varied shades or intensities of these colors can also provide insights into the speed of the flow. Both B-mode images and colorflow images may be provided as input to the machine-learning models described herein to perform various detection, labeling, classification, and segmentation techniques.

One processing technique that may be performed using the machine-learning models described herein includes the detection of cerebral peduncles in a single B-mode image. In particular, these techniques can be utilized to train a machine-learning model, such as a deep convolutional neural network (CNN) model, to regress bounding boxes and apply labels to regions of B-mode images that correspond to cerebral peduncles. The machine-learning models described herein can be trained to generate, for a given B-mode image frame, an estimate of a presence score for a peduncle, which may be proportional to the likelihood that the B-mode image frame depicts a cerebral peduncle, and one or more bounding boxes, which may indicate a predicted location and size of a detected peduncle within the B-mode frame. In some implementations, a first machine-learning model can be trained to generate the presence score for the B-mode image, and a second machine-learning model can be trained to generate the one or more bounding boxes.

Additionally, in some implementations, an additional machine-learning model may be trained to receive a sequence of B-mode image frames as input. The sequence of B-mode images can be provided to improve the accuracy of frame-wise predictions by taking the anatomy of the neighboring regions of the patient into account. Processing sequences of B-mode images may mitigate the effects of the potential noise in image acquisition. In a non-limiting example, this mitigation may be implemented by averaging the frames in the sequence. The machine-learning models may be optimized using a sequence of B-mode frames and bounding boxes indicating the peduncle location in every frame.

The machine-learning models described herein can be utilized to assist with the identification of the cerebral peduncle. The cerebral peduncle may be utilized as a landmark by sonographers to locate the Circle of Willis. The Circle of Willis corresponds to a region in the brain that includes the main cerebral arteries, which may be a target for intracranial blood flow measurements. Although these machine-learning models are described for the purpose of detecting and generating bounding boxes for the cerebral peduncle, it should be understood that similar techniques, and even the same models (e.g., when trained on or using different data), can also be used to locate different brain regions for diagnostic and reporting purposes.

Another aspect of the present disclosure is directed to the use of machine-learning models to detect and segment brain vessels in ultrasound images. In a non-limiting example, a machine-learning model, such as a deep CNN, can be trained to receive ultrasound images as input (e.g., colorflow images, etc.), and generate image-level labels that indicate whether a target brain vessel is present in the ultrasound image. The machine-learning model may be utilized, in a non-limiting example, to generate a single binary label that indicates the presence or absence of a target brain vessel. In some implementations, the machine-learning model may not use any other information during training. This model can be used to detect the presence of the vessel in real time in the image. Moreover, it provides an approximation of the vessel location in the image.

Additionally, a machine learning model is provided that is trained to receive a pair of B-mode and colorflow frames as input, and to generate brain vessel segmentations. The segmentation machine-learning model may be executed in real-time and may be trained using ground-truth brain vessel segmentations of training brain ultrasound images. This model can be used for frame-level brain vessel detection by deriving vessel volume. The segmentations can also be used to derive quantities related to blood flow velocity and to characterize the vessel shape. Another machine-learning model can be trained to smooth variations of frame-to-frame brain vessel segmentations (and volume estimates). The smoothing process may be executed in real-time, in a non-limiting example. The smoothing machine-learning model can utilize a buffer that stores previous segmentations and uses them to modify the segmentation at the current frame with one or more predefined filters. The combination of these machine-learning models provide a target cerebral artery detection and segmentation framework that can be used to enable operators to identify a vessel for blood flow measurement using ultrasound.

Another aspect of the present disclosure provides machine-learning models that may be trained to generate segmentations using a single B-mode image as input. The machine-learning model can be optimized using brain vessel segmentations derived from colorflow images, in some implementations. In some implementations, the machine-learning model may not utilize the colorflow once it has been trained, and may instead utilize only B-mode images as input to generate segmentations. The machine-learning model may be utilized to detect a variety of anatomical landmarks or structures that are visible in B-mode images. The segmentations output from the machine-learning model can indicate estimations of the position of landmarks/structure and its delineation. The naked eye of an operator cannot recognize the cerebral arteries from the B-mode images only. In contrast to colorflow images, B-mode images may have a higher sampling frequency and they can cover a larger region of the brain. This facilitates a faster time-to-target when navigating the operator to a target vessel. In addition, it can be more robust to the noise captured during colorflow imaging.

The machine-learning models described herein may further provide techniques for brain vessel parameterization and tracking during ultrasound. In some implementations, a machine-learning model may be trained to receive a clip of brain vessel segmentations as input and generate parameters of detected target brain vessels as output. In a non-limiting example, the vessel parameters may include coordinates of the centerline points, vessel curvature at each point, vessel diameter at each point, and colorflow signal to noise ratio at each point. The machine-learning model can be trained using a variety of training processes, including but not limited to techniques ranging from polynomial fitting to frequency analysis.

An additional machine-learning model may be trained to track the position of the brain vessels segments sequences of frames across time. The machine-learning model can utilize parameters relating to a target vessel (e.g., parameterizations of the vessel curve) and a spatiotemporal matching technique to generate a spatiotemporal graph for brain vessel data. Tracking can be implemented as a pass through the graph. The tracking techniques can be utilized to enable a beam steering component of an ultrasound system to lock on the target vessel and extract the parameters required for an accurate assessment of cerebral blood flow velocity, in a non-limiting example.

Additional techniques described herein include training and execution of an ensemble machine-learning for brain vessel detection. The machine-learning model may be trained to generate a presence score for a target brain vessel in the Circle of Willis. The machine-learning ensemble model may be trained to receive a sequence of B-mode and/or colorflow images as input. The machine-learning ensemble model may aggregate the predictions of multiple machine learning models having different design and optimization processes. Those machine-learning models may include any of the machine-learning models described herein, and in some implementations, may include a first machine-learning model for peduncle detection using a single B-mode image frame and a second machine-learning model for peduncle detection using a sequence of B-mode image frames. Additional machine-learning models in the ensemble machine-learning model may include a machine-learning model that is trained to generate segmentations of target brain vessel(s) segmentation with B-mode and colorflow images and temporal smoothing, and a machine-learning model for brain vessel segmentation with B-mode only with temporal smoothing. The ensemble machine-learning model may be more robust to outliers than any of these single machine-learning models used individually.

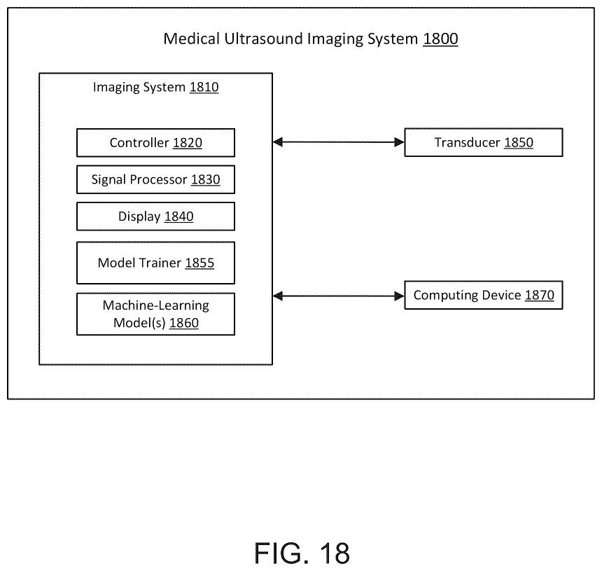

Prior to the discussion of the machine-learning techniques described herein, a brief overview of an ultrasound system that may be utilized to train, execute, or otherwise implement various machine-learning models is provided. FIG. 18 depicts an example medical ultrasound imaging system 1800. The medical ultrasound imaging system 1800 may include an imaging system 1810, one or more ultrasound transducers 1850, and a computing device 1870 external to the imaging system 1810. The ultrasound transducer 1850 produces sound waves that are transmitted to and bounce off body tissue being imaged. The echoes produced by this process can also be received by the ultrasound transducer 1850 and transmitted to the imaging system 1810. As used herein, an “echo” is distinguished from direct sound, and includes sound resulting from reflection and/or refraction once the direct sound has interfaced with (“hit” or “bounced off”) a surface. There may be a delay between emission of the direct sound and detection of an echo. The delay is proportional to a first distance between the source of the direct sound and the surface with which the direct sound interfaces, and a second distance between the surface and a sensor used to detect the echo.

The imaging system 1810 may include a controller 1820, a signal processor 1830, a display 1840, a model trainer 1855, and one or more machine-learning models 1860. The controller 1820 may control the amplitude, sequence, or direction of the sound waves that are produced by the ultrasound transducer 1850. The echoes received by the ultrasound transducer and transmitted to the imaging system 1810 may be processed by the signal processor 1830 to produce images. These images may be displayed to a patient or a medical professional for viewing and diagnostic purposes on the display 1840. The received images may be processed by the machine-learning models 1860 to produce the various output data described herein. Additionally, the model trainer 1855 may store one or more of the images produced by the signal processor 1830 as training data, which may be annotated with ground-truth data manually or automatically. The controller 1820, signal processor 1830, display 1840, model trainer 1855, and the machine-learning models 1860 may be implemented by a single device. In some embodiments, the functions performed by each of these components are performed by multiple devices in communication with one another.

In some embodiments, the medical ultrasound imaging system 1800 may include a computing device 1870 external to the imaging system 1810. The computing device may implement one or more functions of one or more components of the imaging system, such as the controller 1820, the signal processor 1830, the display 1840, the model trainer 1855, or the machine-learning models 1860. In a non-limiting example, the external computing device 1870 may be used to view, preview, and/or store produced images. The external computing device 1870 may also be used to coordinate training and/or execution of the machine-learning models 1860 (e.g., via the model trainer 1855). The computing device 1870 may allow a user to make selections regarding operation of the imaging system 1810, such as initiating or terminating functions of the medical ultrasound imaging system 1810, selecting imaging modalities, adjusting what is displayed, initiating or adjusting parameters for training the machine-learning models 1860, etc. In some embodiments, the computing device 1870 may be a general-purpose computer in communication with the imaging system 1810. The computing device 1870 may be, in a non-limiting example, a workstation, a desktop computer, a laptop, or any mobile device such as a tablet, a smartphone, or another smart device capable of running an application that provides interactivity.

Embodiments of the disclosure may include an ultrasound transducer 1850 with a small form factor. An ultrasound transducer 1850 with a small form factor may be suitable for use in many situations where traditional medical ultrasound imaging technology is not feasible or cost effective. However, it should be understood that the machine-learning techniques described herein may be implemented using images captured by any type of ultrasound transducer, including conventional ultrasound transducers. For example, the signal processor 1830 may receive and process data received from the ultrasound transducer 1850, and store corresponding ultrasound images, which may include B-mode images (sometimes referred to herein as “B-mode frames”) and/or colorflow images (sometimes referred to herein as “colorflow frames”) for training the machine-learning models 1860.

The model trainer 1855 may include hardware, software, or combinations of hardware and software that train one or more of the machine-learning models 1860. The model trainer 1855 may implement any type of machine-learning technique to train and/or update the machine-learning models 1860, including supervised learning, semi-supervised learning, self-supervised learning, or unsupervised learning techniques. In a non-limiting example of supervised learning, the model trainer 1855 may update trainable parameters (e.g., weights, biases, etc.) of a machine-learning model 1860 based on labeled training data. In supervised learning, both the input training data (e.g., B-mode images, colorflow images, etc.). The training data includes a corresponding label, which is indicative of the desired output of the model given a particular item of input data. In a non-limiting example, the output label may be a presence score for a brain vessel, or a pre-generated segmentation for a brain vessel, among other desired outputs described herein. In supervised learning, input data of the training data is provided to the machine-learning model 1860 being trained, and the machine-learning model 1860 is executed by the model trainer 1855 to produce an output.

The output of the machine-learning model 1860 is then compared to the corresponding label for the input data to determine a loss, and the trainable parameters of the machine-learning model 1860 are adjusted based on the difference. The adjustment is facilitated by algorithms that guide how the parameters of the machine-learning model 1860 are changed based on the error between its predictions produced by the machine-learning model 1860 and the labels associated with the input data. One non-limiting example algorithm used to optimize the trainable parameters of the machine-learning models 1860 is gradient descent, which involves iteratively adjusting the trainable parameters by modifying them in the direction that reduces the error. The adjustments are determined by the gradient of the loss function, which measures the difference between the output predictions of the machine-learning model 1860 and the labels corresponding to the input training data. By repeatedly adjusting the parameters in the direction of steepest descent, the loss function is minimized. Various optimization algorithms may be utilized in addition to or in the alternative to gradient descent, including but not limited to stochastic gradient descent, mini-batch gradient descent, and adaptive versions such as Adam and RMSprop.

In some implementations, the trainable parameters of one or more of the machine-learning models may be updated according to supervised learning, or combinations of supervised learning and other machine-learning techniques described herein. Some non-limiting example tasks for which the machine-learning models 1860 may be trained using supervised learning include classification, regression, segmentation, and/or regression. In a non-limiting example, one or more machine-learning models 1860 described herein may include models trained to generate output presence scores that are proportional to, and therefore indicative of, one or more structures (e.g., brain vessels, the Circle of Willis, etc.) of the brain depicted in input ultrasound image(s).

In another non-limiting example, one or more of the machine-learning models 1860 may include models trained to generate segmentations indicative of regions of interest (e.g., brain vessels, the Circle of Willis, etc.) in ultrasound images of the brain of a patient. A segmentation of an image, such as a B-mode image and/or a colorflow ultrasound image, may refer to a region or segment of the image that is identified as corresponding to a distinct label. One non-limiting example of segmentations include semantic segmentation, in which each pixel of an image (or a subset of pixels of the image) are classified into a particular category, e.g., as corresponding to a structure of the brain of the patient. Another non-limiting example of segmentations include instance segmentation, in which distinct objects of the same category are classified as separate entities or instances of the same category, e.g., multiple different distinct blood vessels in the brain. In some implementations, segmentations for an input image may include a segmentation map, which includes a respective segmentation label for each pixel in the input image.

The machine-learning models 1860 may include trained or untrained models that can receive ultrasound images as input. Such models may include, in a non-limiting example, deep convolutional neural network (CNN) models. Deep CNNs may include several layers of varying types, including but not limited to input layer(s), convolutional layers, activation functions, pooling layers, and fully connected layers, among others. Input layers include data structures that receive input images, and provide image data to the next layer in the machine-learning model 1860. Input layers may include tensor data structures, in which images may be represented as width by height by depth tensors. For a color image (e.g., a colorflow image), the depth may be three, corresponding to the red-green-blue (RGB) color channels of the image. For a B-mode image, the depth may be one, corresponding to the grayscale intensity of the pixel. In some implementations, both a colorflow image and a B-mode image may be received by an input layer, which may have a depth of four to accommodate all color channels.

Convolutional layers may include trainable parameters that are used to perform convolution operations on the data provided from the previous layer in a machine-learning model 1860. The trainable parameters may include one or more sets of learnable filters or kernels. These filters may be trained to extract features like edges, corners, and textures from the input data. The depth of the output (number of feature maps) depends on the number of filters used, which may be defined as a hyperparameter of the model prior to training. Activation functions may be applied after convolution operations to introduce non-linearity into the machine-learning model 1860. One non-limiting example of an activation function includes a Rectified Linear Unit (ReLU) activation function. Pooling layers include layers that are used to reduce the spatial dimensions of the data produced by the previous layer, and reduce the number of subsequent computations to execute the machine-learning model while providing a form of translational invariance. Non-limiting examples of pooling layers include max pooling and average pooling.

Fully connected layers of the machine-learning model(s) 1860 include one or more layers of neurons that connect to every neuron in the previous layer. In a non-limiting example, fully layers may be positioned near the output layer(s) of the machine-learning models and may be trained to produce outputs such as classification outputs and/or regression outputs. The output layer(s) of the machine-learning model(s) 1860 may be the final layers of the machine-learning model(s) 1860 that produce the final outputs of the model (e.g., classifications, segmentations, scores, etc.). In a non-limiting example for classification, various output operations such as soft-max operations may be performed to produce the final output.

In a non-limiting example, at least one of the machine-learning models 1860 may include a variant of a You Only Look Once (YOLO) model, which is a model trained to detect the presence of objects or structures in input images. In this non-limiting example, the YOLO model is trained to detect one or more structures in ultrasound images of the brain of a patient. In some implementations, the machine-learning models 1860 may be trained to generate bounding boxes, which are indicative of a location and size of a detected feature (e.g., a structure such as a brain vessel, etc.) in an ultrasound image. Training a machine-learning model 1860 to generate bounding boxes may include using pre-generated bounding boxes as label data for input training images. The machine-learning models 1860 may be trained according to loss functions that incorporate both classification loss and detection (e.g., bounding box) loss, improving the overall detection accuracy of the machine-learning models 1860.

The imaging system 1810 may execute one or more of the machine-learning models 1860 in response to corresponding request(s) from an operator of the imaging system 1810 or from an external computing system, such as the computing device 1870. In some implementations, the requests may include or may otherwise specify one or more input images to provide to the machine-learning models 1860 as input. The request may specify one or more structures or operations (e.g., segmentation, etc.) to perform on the input images, and the imaging system 1810 may select and execute (using the specified images as input) machine-learning models 1860 that have been trained to produce the requested output. In some implementations, the request may specify the particular machine-learning model 1860 to execute to produce a requested output. Further details of specific machine-learning models, training processes, input data, and particular outputs with regard to ultrasound images are described in connection with FIGS. 9-28.

Although shown in FIGS. 2A-17 as a portable or reduced-size ultrasound transducer device, it should be understood that the machine-learning techniques described herein may be implemented using any type of ultrasound device, including transducers of any size, shape, or form factor. In a non-limiting example, the ultrasound transducer 1850 may include traditional or conventional non-portable ultrasound transducer(s), which may produce signals that may be processed into ultrasound images utilized in inference and/or training of the various machine-learning models 1860 described herein.

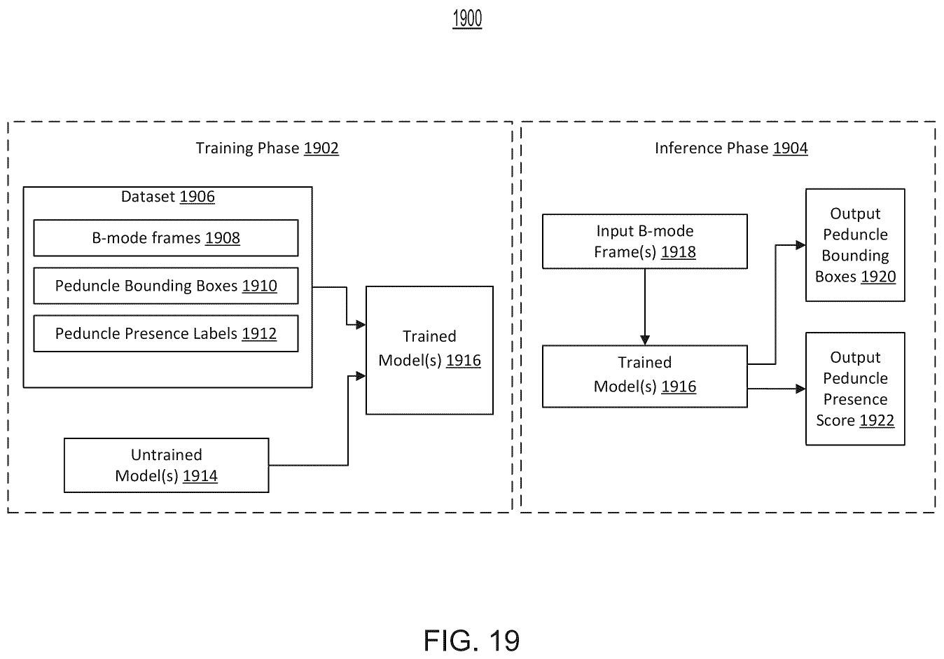

Referring to FIG. 19, depicted is a non-limiting example dataflow diagram 1900 showing a process for training and executing a machine-learning model for detecting cerebral peduncles with single, or a sequence of, B-mode image frames, in accordance with one or more embodiments of the disclosure. The process shown in the dataflow diagram 1900 may be performed, in a non-limiting example, by the imaging system 110 (or any components thereof) described herein. As shown, the process may include at least two phases: a training phase 1902 and an inference phase 1904. During the training phase 1902, the untrained model 1914 may be trained using information stored as part of the dataset 1906, using machine-learning techniques such as supervised learning, semi-supervised learning, self-supervised learning, and/or unsupervised learning.

In some implementations, the training phase 1902 and the inference phase 1904 may be performed by different computing systems. In a non-limiting example, the training phase 1902 may be performed using a computing environment separate from a system that processes ultrasound images in the inference phase 1904. In some implementations, because training machine-learning models may utilize additional computing resources that may not necessarily utilized during the inference phase 1904, a distributed or high-performance computing environment may be utilized to execute the training phase 1902. In such implementations, the inference phase 1904 may be performed “in the field,” enabling real-time or near real-time processing of ultrasound images as they are captured via an ultrasound transducer. In a non-limiting example, a cloud-computing platform or a distributed computing environment may perform the training phase 1902 to train the untrained model(s) 1914 to produce the trained model(s) 1916, which may then be transmitted or otherwise distributed to one or more computing devices that perform imaging with or otherwise operate in connection with an ultrasound device. The one or more computing devices may perform the operations of the inference phase 1904 using the trained machine-learning model(s) 1916, as described herein.

In the training phase 1902, the untrained machine-learning model(s) 1914 may be trained using a suitable machine-learning technique and based upon the information stored in the dataset 1906. In some implementations, the untrained model(s) 1914 may include any type of machine-learning model that has been untrained for a particular machine-learning task, and may include untrained neural network models (e.g., CNNs, deep CNNs, fully connected networks, recurrent neural networks (RNNs), etc.), linear regression models, sparse vector machine models, random forest models, combinations thereof, or any other type of machine-learning model. The untrained models 1914 may be stored as one or more data structures defined according to the hyperparameters of the model. The data structures may be stored the trainable parameters of the model, which may be initialized to initial (e.g., untrained) values. In some implementations, the architecture of one or more of the untrained machine-learning model(s) 1914 may include a variant of the you-only-look-once (YOLO) object detection model architecture or the CenterNet object detection model architecture, among others.

In some implementations, the trainable parameters of the untrained model(s) 1914) may include randomly initialized parameters. In a non-limiting example of a neural network, the weights and/or biases of the neural network model may be initialized using distributions such as Gaussian or uniform distributions. In some implementations, depending on the activation function used within the neural network, specialized initialization techniques like Xavier or He initialization may be utilizing to improve the efficiency of the training phase 1904. In some implementations, once initialized, the untrained model(s) 1914 may not encapsulate any learned features or patterns from any data, and therefore any predictions or output generated by the untrained model 1914 may be based on these random initializations, leading to a high error rate when evaluated against the labels (e.g., the peduncle bounding boxes 1910, the peduncle labels 1912) in the dataset 1906.

One advantage of using an untrained model 1914 and optimizing it using selected training data (e.g., the B-mode frames 1908) is their lack of data-specific bias. Once the training phase 1902 is complete, the trainable parameters (e.g., the weights, biases, etc.) may be trained to produce accurate outputs, and the untrained model(s) 1914 become the trained model(s) 1916. The trained model(s) 1916 are then capable of making accurate predictions based on input B-mode frames 1918 during the inference phase 1904.

In some implementations, the untrained model 1914 may include trainable parameters that are pre-trained, e.g., trained on a prior (and potentially unrelated or tangentially related) dataset. Previously trained (sometimes referred to as pre-trained) models may be utilized to improve overall computational efficiency during the training phase 1902, when compared to training the same untrained model(s) 1914 from scratch. Training machine-learning models from scratch may demand substantial computational resources. Because pre-trained models may have already undergone training on other datasets, the amount of training required to specialize the models for a particular task is reduced, improving computational efficiency and reducing the time required to reach a threshold level of accuracy.

The training process 1902 can utilize information stored in the dataset 1906 to iteratively train and/or update the untrained model(s) 1914 (or to retrain or update the trained model(s) 1916). In this example implementation, the dataset 1906 is shown as including B-mode images 1908, which are stored in association with corresponding peduncle bounding boxes 1910 and corresponding peduncle presence labels 1912. In this example implementation, the untrained model(s) 1914 are trained to receive B-mode ultrasound images as input (e.g., the input B-mode image(s) 1918), and identify, locate, and/or detect the presence of a cerebral peduncle in the input B-mode image. In a non-limiting example, at least one of the untrained model(s) 1914 may be trained and/or updated to produce bounding box coordinates of at least one bounding box identifying a location and size of a cerebral peduncle depicted in the B-mode image.

Furthering this non-limiting example, at least one of the untrained model(s) 1914 may be trained and/or updated as a detection model. In some implementations, the models may be trained such that the cerebral peduncle may be detected and located from a single B-mode image. To train at least one untrained model 1914 to do so, training data including single B-mode images and corresponding label data including pre-generated bounding boxes (e.g., the peduncle bounding boxes 1910) and pre-generated presence labels (e.g., the peduncle presence labels 1912) can be utilized.

To train the untrained model(s) 1914 using supervised learning, the untrained model(s) 1914 may be trained at least partially using supervised learning, such that the labels (e.g., the peduncle bounding boxes 1910, the peduncle presence labels 1912, etc.) are compared to the output of the untrained model 1914 produced using a single training B-mode frame 1908 as input to calculate a loss. The loss is then utilized to update the trainable parameters of the untrained model 1914 iteratively. In some implementations, the loss may be calculated based on several input images and several labels, to produce average error over several input samples (e.g., a “batch” of B-mode frames).

The B-mode frames 1908 may be frames previously captured using any type of ultrasound transducer and may include images from multiple patients or regions of the brain. In some implementations, the computing system (e.g., the imaging system 12310, the computing device 1870, etc.) executing the training phase 1902 may receive the B-mode frames from an ultrasound device (e.g., the ultrasound transducer 1850) or imaging system (e.g., the imaging system 1810). In some implementations, the dataset 1906 (and therefore the B-mode frames 1908) may be accessed via one or more application programming interfaces (APIs) of a storage system, such as a distributed computing system (e.g., a cloud system) that stores training data for the machine-learning models described herein. In a non-limiting example, items of training data (e.g., a B-mode frame 1908 and its corresponding peduncle bounding box(es) 1910 and peduncle presence label(s) 1912) may be retrieved from the storage system as a response to a request transmitted using the API of the storage system.

The B-mode images 1908 may include images depicting one or more cerebral peduncles and images that do not depict one or more cerebral peduncles in order to expose the untrained model(s) 1914 to images of both types for accurate training. The cerebral peduncles are the two stalks that attach the cerebrum to the brainstem. The cerebral peduncle(s) may be utilized as a landmark by operators to locate the Circle of Willis in the brain. The Circle of Willis may include all the main cerebral arteries that are the main target for intracranial blood flow measurements.

B-mode images 1908 that depict one or more cerebral peduncles may be stored in association with corresponding peduncle bounding box(es) 1910 that indicate a size and location of the one or more cerebral peduncles in the B-mode images 1908. Each B-mode image 1908 that depicts at least one cerebral peduncle may be stored in association with at least one peduncle bounding box 1910. Each B-mode image 1908 that depicts at least one cerebral peduncle may also be stored in association with a corresponding peduncle presence label 1912 that indicates a presence of the peduncle in the B-mode image 1908. The peduncle presence labels 1912 may be a binary value (e.g., zero indicating no presence of the peduncle in the corresponding B-mode image 1908, one indicating presence of the peduncle in the corresponding B-mode image 1908), or a scalar value (e.g., a value between zero and one that is proportional to the visibility of the peduncle in the corresponding B-mode image 1908). B-mode images 1908 that do not depict the cerebral peduncle may be stored in association with peduncle bounding box 1910 data that stores default values (e.g., a lack of bounding box, or a bounding box with invalid dimensions) that can indicate the B-mode image 1908 does not depict the cerebral peduncle.

In some implementations the peduncle bounding boxes 1910 and the peduncle presence labels 1912 may be generated using at least partially manual processes prior to the training phase 1902. For example, bounding box labeling software may be utilized by operators to generate bounding boxes and presence labels for each B-mode image 1908, which are then utilized to train the untrained model(s) 1914 using the training techniques described herein. In some implementations, manual operator feedback (e.g., adjustments to bounding box(es) and/or presence scores) may be provided to the output of the trained model(s) 1916, for example, to generate additional peduncle bounding boxes 1910 and/or peduncle presence labels 1912 for additional B-mode images captured via an ultrasound transducer, to produce additional training data that may be stored as part of the dataset 1906. In such implementations, the trained model(s) 1916 may be periodically or continuously retrained and/or updated based on the manually-produced or manually adjusted label information to improve the overall accuracy of the trained model(s) 1916.

To train the untrained model(s) 1914, training data from the dataset 1906, shown here as the B-mode frames 1908, are provided as input to the untrained model(s) 1914. In a non-limiting example where the untrained model(s) 1914 include neural networks, the untrained model(s) 1914 are then executed by performing mathematical computations of each layer (e.g., convolutions, activation functions, multiplications by weight values, etc.) and propagating the resulting data to the next layer in the network. This process is repeated for each layer in the untrained model(s) 1914 until corresponding outputs are generated. The outputs can then be compared to the pre-generated labels (e.g., the peduncle bounding boxes 1910, the peduncle presence labels 1912) associated with the input data to determine the loss. An optimization algorithm (e.g., gradient descent, Adam, etc.) is then performed using the loss as input to optimize the trainable parameters (e.g., weights, biases, etc.) of the untrained model(s) 1914 to minimize the loss. This training process may be repeated for multiple input training data images until a training termination condition is satisfied.

In some implementations, a first of the untrained models 1914 may be trained to generate bounding boxes that identify a size and location of a cerebral peduncle, if detected within an input ultrasound B-mode image, and a second of the untrained models 1914 may be trained to generate a presence score that indicates a likelihood that the input ultrasound B-mode image depicts a cerebral peduncle. The untrained model 1914 can be trained to output the presence score such that the presence score is proportional to the visibility of the cerebral peduncle within the input B-mode image (e.g., the degree of certainty that a cerebral peduncle has been detected within the image).

In some implementations, at least one of the untrained models 1914 can be trained to receive a sequence of B-mode images as input. In such implementations, at least a portion of the B-mode frames 1908 provided as input to train the model may be sequential B-mode frames 1908 of the same patient. The untrained model 1914 that is trained to receive and process a sequence of B-mode frames may receive the sequence in parallel (e.g., by using a larger input layer), or may include recurrent neural network elements to receive the frames sequentially, one after another. Using sequence B-mode images trains the untrained models 1914 to improve frame-wise predictions by taking the anatomy of neighboring regions into account. Using sequences of B-mode frames 1908 can mitigate the effects of potential noise resulting from image acquisition. In a non-limiting example, the noise is mitigated by averaging the frames in the sequence. Training an untrained model 1914 to receive a sequence of B-mode frames 1908 as input may be performed using techniques similar to those described herein, except that the input training data for the untrained model 1914 includes a sequence of B-mode frames 1908, and the label data used to calculate the loss includes corresponding sequences of peduncle bounding boxes 1910 indicating the peduncle location in each B-mode frame 1908, along with corresponding sequences of peduncle presence labels 1912 for each B-mode frame 1908.

The untrained model(s) 1914 may be trained and/or updated iteratively, using a number of batches or epochs, until a training termination condition has been reached. In a non-limiting example, the untrained model(s) 1914 may be trained using multiple batches of training data (e.g., B-mode images 1908 and corresponding peduncle bounding box(es) 1910 and peduncle presence labels 1912) to produce the trained model(s) 1916. A batch of training data may include a subset of the training dataset 1906, which is provided as input to the untrained model(s) 1914 in an iterative process. Rather than feeding the entire dataset into the untrained model(s) 1914 at once, the data may divided into multiple smaller sets or batches. Each batch is propagated through the untrained model(s) 1914. The trainable parameters of the untrained model(s) 1914 may be performed either at the end of each batch (e.g., when implementing mini-batch gradient descent) or after each individual data point (e.g., when implementing stochastic gradient descent). The size of each batch, which can denote the number of training data images (and corresponding label data) in each batch, is a hyperparameter of the training phase 1902 that may be predetermined.

The untrained models 1914 may be iteratively updated for one or more epochs, which are may include a complete forward and backward pass of all training samples (e.g., B-mode images 1908 and corresponding peduncle bounding boxes 1910 and peduncle presence labels 1912) in the dataset 1906. In other words, an epoch may include one forward and backward pass of all batches generated from the dataset 1906. After one epoch, the untrained model(s) 1914 may be exposed to every training example at least once. In some implementations, multiple epochs may be iteratively performed to assist with model convergence to an optimal set of trainable parameters (e.g., to achieve a training termination condition). The number of epochs may be a hyperparameter of the training phase 1902, which may be predetermined.

The training phase 1902 can be executed such that the untrained model(s) 1914 are trained and/or updated until a training termination condition has been satisfied. A training termination condition can dictate when the iterative training process of the untrained model(s) 1914 is to be stopped, and the now-trained untrained model(s) 1914 are to be stored as the trained model(s) 1916. In some implementations, the termination condition may be satisfied when a maximum number of epochs have been utilized to train the untrained model(s) 1914. In a non-limiting example of such a training condition, the iterative training phase 1902 for the untrained model(s) 1914 can be stopped when a predetermined number of epochs have been performed, irrespective of other factors.

Another example of a training termination condition is a target accuracy condition, in which iterative training of the untrained model(s) 1914 can be stopped when the accuracy (or other relevant metric) on a validation set reaches a predefined threshold. In such implementations, the validation set may be a set of training data that is set aside, relative to other training data stored in the dataset 406, and utilized solely to test the accuracy of the untrained model(s) 1914. In a non-limiting example, the accuracy of the models may be tested periodically (e.g., after each batch, after a predetermined number of batches, after each epoch, after a predetermined number of epochs, etc.). Using a termination condition that is at least a function of the accuracy of the models being trained can ensure that the trained model(s) 1916 meet a predetermined performance criteria.

Yet another example training termination condition includes a minimal improvement threshold. A minimal improvement threshold is satisfied when the performance improvement from one epoch to another on a validation set falls below a predetermined value. In a non-limiting example, if the improvement in model performance (e.g., reduction in validation loss, reduction in error rate, etc.) is below a predefined threshold for a predetermined number of consecutive epochs, training is terminated. One other training termination condition that may be utilized to stop the training phase 1902 is early stopping, in which the training phase 1902 is terminated once the performance on a validation set begins to deteriorate (e.g., indicating potential overfitting). In some implementations, a combination of different training termination criteria may be implemented to determine when to terminate the training phase 1902.

Once the training termination condition has been satisfied, the now-updated untrained model(s) 1914 can be stored (e.g., in one or more data structures or model files) as the trained model(s) 1916. The trained model(s) 1916 may be stored, in some implementations, as part of the machine-learning models 1860 of FIG. 18. The trained model(s) 1916 can then be accessed and utilized during the inference phase 1904 to generate predictions (e.g., the output peduncle bounding box(es) 1920, the output peduncle presence score(s) 1922, etc.) relating to cerebral peduncles potentially depicted in input B-mode images. In some implementations, after training, the trained model(s) 1916 can be transmitted to one or more computing systems that utilize the trained model(s) 1916 during the inference phase 1904. Although described in connection with detection of the cerebral peduncle, it should be understood that the trained models 1916 may be trained to detect any type of anatomical structure of a patient from a single B-mode frame or a sequence of B-mode frames using corresponding label data.

The inference phase 1904 may include a process for utilizing the trained model(s) 1916 generated in the training phase 1902 to detect the presence and location of the cerebral peduncle(s) in an input B-mode frame 1918. The input B-mode frame 1918 may be a B-mode image that is captured using an ultrasound transducer such as the ultrasound transducer 150. The input B-mode frame 1918 may be a frame that was not included in the dataset 1906, and therefore the trained models 1916 have not been exposed to the input B-mode frame 1918 during the training phase 1902.

The inference phase 1904 may be utilized to detect the presence and location of the cerebral peduncle in real-time or near real-time, and in a non-limiting example, during an ultrasound procedure on a patient's brain. During the inference phase 1904, input B-mode frames 1918, which may be captured during an ultrasound procedure, provided in a request to process the input B-mode frames 1918 (e.g., from an external computing device), or retrieved from a data repository or storage system, may be provided as input to the one or more trained models 1916. In an implementation where the trained models 1916 include a model that processes a sequence of B-mode images, the input B-mode images 1918 may be provided as input as a sequence to the trained model 1916 (e.g., as a single input in parallel or one after another in sequence).

In some implementations, the input B-mode images 1918 may be processed prior to being provided as input to the trained models 1916. Processing the input B-mode images 1918 may include cropping, down-sampling, sharpening, adjusting brightness, or other pre-processing tasks that may be utilized to improve detection accuracy or compatibility with the trained models 1916. In some implementations, a single input B-mode frame 1918 may be provided as input to one or more of the trained model(s) 1916, which can generate one or more output peduncle bounding boxes 1920 and one or more output peduncle presence scores 1922. To execute the trained model(s) 1916, data of the input B-mode image 1918 can be propagated through and utilized in the mathematical computations of each layer (e.g., convolutions, activation functions, multiplications by weight values, etc.). The resulting data of each layer is then propagated to the next layer in the network until corresponding outputs (e.g., the output peduncle bounding boxes 1920, the output peduncle presence scores 1922) are generated.

An output peduncle bounding box 1920 can be a bounding region generated by the trained model(s) 1916 that is indicative of a location and/or size of one or more cerebral peduncles depicted in the input B-mode image. The output peduncle presence score 1922 may be generated by the same trained model 1916 that generated the one or more output peduncle bounding boxes 1920, or in some implementations, by using a second trained model 1916. The output peduncle presence score 1922 may be indicative of a confidence of the corresponding predicted output peduncle bounding box 1920 generated for the input B-mode frame 1918. In some implementations, a sequence of input B-mode frames 1918 may be provided as input to the trained model(s) 1916 to generate the output peduncle bounding boxes 1920 and the output peduncle presence scores 1922 for each B-mode frame of the sequence.

In some implementations, the output of a trained model 1916 that receives the sequence of input B-mode frames as input may be utilized to retrain or update a trained model 1916 (or an untrained model 1914) that receives a single B-mode image as input. In a non-limiting example, the output of the trained model 1916 that processes a sequence of input B-mode frames 1918 may be utilized as label data for training an untrained model 1914 that generates peduncle bounding boxes and/or peduncle presence labels using single B-mode frames. Said data may be stored as part of the dataset 1906, such that the output peduncle bounding boxes 1920 and the output peduncle presence labels 1922 are stored as part of the peduncle bounding boxes 1910 and the peduncle presence labels 1912 for training an untrained model 1914 to detect the cerebral peduncle in a single B-mode image. Each image in the sequence of input B-mode frames 1918 may be stored as a respective B-mode frame 1908 to train, retrain, or update said model.

The output peduncle bounding boxes 1920 may be utilized to generate an output image, in which each output peduncle bounding boxes 1920 is superimposed over the input B-mode frame 1918, thereby indicating the location and/or size of the detected cerebral peduncle. The output image(s) may be displayed at a display device of the computing device executing the interference phase 1904. The output peduncle presence scores 1922 may be shown or otherwise indicated in association with the respective B-mode image on the display of the computing device.

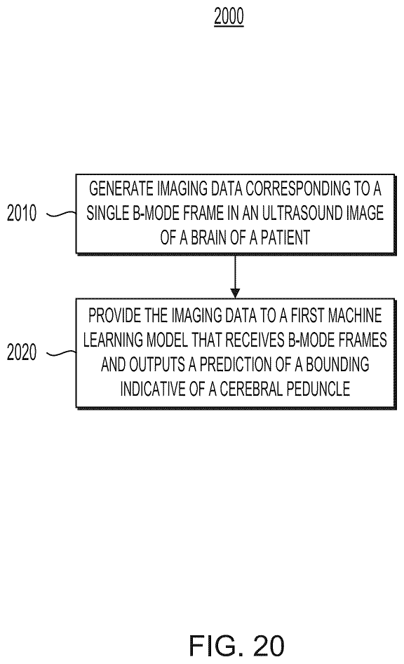

FIG. 20 depicts a flowchart of an example method 2000 of training and executing a machine-learning model for detecting cerebral peduncles with single, or a sequence, of B-mode image frames, in accordance with one or more embodiments of the disclosure. The method 2000 may be executed using any suitable computing system (e.g., the imaging system 1810, the computing device 1870 of FIG. 18, the computing system 3200 of FIG. 32, etc.) of an ultrasound system (e.g., the ultrasound system 12300). The ultrasound system used to perform the method 2000 may include a portable ultrasound transducer. It may be appreciated that certain steps of the method 2000 may be executed in parallel (e.g., concurrently) or sequentially, while still achieving useful results.

The method 2000 may include act 2010, in which the ultrasound system generates imaging data corresponding to a single B-mode frame in an ultrasound image of a brain of a patient. The B-mode frame of the ultrasound image may be generated by processing signals representative of ultrasound echoes received via an ultrasound transducer (e.g., the ultrasound transducer 1850). The imaging data may be or may include a B-mode image. The imaging data may include one or more data structures that are suitable for provision to an input of a machine-learning model (e.g., the trained model(s) 1916, the machine-learning models 1860, etc.). In a non-limiting example, the data structures may include one or more tensors that store the pixel-intensity values for each pixel in the B-mode frame. In some implementations, the ultrasound system may generate imaging data for a sequence of B-mode frames. The sequence may be a sequential data structure storing imaging data for each B-mode frame of the sequence, in a non-limiting example.

In some implementations, the ultrasound system may utilize the B-mode frame data to generate one or more training datasets (e.g., the dataset 1906) for use during a training process (e.g., the training phase 1904) of a first machine-learning model. The training dataset may include imaging data for a set of B-mode frames 1908, each of which may corresponding to the same or different patients. The training dataset may include, for each B-mode frame in the set of B-mode frames, one or more bounding regions (e.g., the one or more peduncle bounding boxes 1910, etc.) that indicate the location and/or size of one or more cerebral peduncle(s) depicted within the B-mode frame. The training dataset may include, for each B-mode frame in the set of B-mode frames, one or more bounding regions (e.g., the one or more peduncle presence scores 1912, etc.) that indicate the location and/or size of one or more cerebral peduncle(s) depicted within the B-mode frame.

The ultrasound system can train the first machine learning model using the training dataset, which as described herein may include B-mode frames (e.g., the B-mode frames 1908), at least one cerebral peduncle bounding region (e.g., the peduncle bounding boxes 1910) for each B-mode frame, and a cerebral peduncle presence label (e.g., the peduncle presence labels 1912) for each B-mode frame, as described herein. The training process may include training an untrained model to produce a trained model, using machine-learning techniques such as supervised learning, semi-supervised learning, self-supervised learning, or unsupervised learning, among others.

In some implementations, the ultrasound system may train a second machine learning model to generate bounding regions that identify the location of one or more cerebral peduncles based on predict based at least on regions neighboring the cerebral peduncle depicted in a sequence of B-mode images. To do so, the ultrasound system may generate a second training dataset that includes imaging data for sequences of B-mode frames. The second training dataset may include, for each B-mode frame in each of the sequences, a bounding region and data corresponding to data corresponding to neighboring regions proximate to the bounding region. The data corresponding to neighboring regions proximate to the bounding region may be pixels within the sequence of B-mode images that reflect structures proximate to the cerebral peduncle, and may provide context for the location, size, and/or orientation of the cerebral peduncle within the sequence of B-mode images. Each sequence of B-mode frames in the second training set may be captured from the same patient during the same ultrasound imaging session and may be stored and utilized to train the second machine learning model as described herein. Once trained, the first machine learning model and/or the second machine learning model can be executed to produce output data for B-mode frames of a brain of a patient.

The method 2000 may include act 2020, in which the ultrasound system provides the imaging data generated at act 2020 to the first machine learning model. As described herein, the first machine learning model may be trained to receive B-mode frames as input and, for each of the B-mode frames, output a prediction comprising one or more bounding regions (e.g., the output peduncle bounding boxes 1920) indicative of a location of a cerebral peduncle in the respective B-mode frame. Providing the imaging data as input to the first machine learning model may include formatting or otherwise adapting the imaging data for the input layer of the first machine learning model. The first machine learning model may then be executed by performing the mathematical computations of each layer (e.g., convolutions, activation functions, multiplications by weight values, etc.) in the first machine learning model, and propagating the resulting data to each next layer until corresponding outputs are generated. In some implementations, the first machine learning model may output one or more presence scores (e.g., the output peduncle presence scores 1922), the value of which is indicative of a confidence of the first machine learning model in the prediction of the output bounding region.

The outputs of the first machine learning model may be modified by a user, and the modified outputs may be utilized to retrain or otherwise update the first machine learning model. In a non-limiting example, the ultrasound system may receive user input (e.g., an interaction, etc.) that specifies a corrected bounding region identifying a location of the cerebral peduncle in an input B-mode frame. In such implementations, the ultrasound system may retrain or update the first machine learning model using the corrected bounding region as label data according to the techniques described herein.

In implementations where a sequence of B-mode frames have been generated in act 2010, the ultrasound system may provide the sequence of B-mode frames as input to the trained second machine learning model, and execute the second machine learning model as described herein to generate predictions of the location of the cerebral peduncle. As described herein, utilizing the sequence of B-mode frames can expose the second machine learning model to regions neighboring the cerebral peduncle, which may increase the overall accuracy of the second machine learning model. In some implementations, the second machine learning model may also output one or more presence scores (e.g., the output peduncle presence scores 1922) for each B-mode frame in each sequence, the value of which is indicative of a confidence of the second machine learning model in the prediction of the output bounding region corresponding to the B-mode frame.

In some implementations, the outputs of the first machine learning model may be utilized to update the second machine learning model, or vice versa. In a non-limiting example, the first machine learning model may generate peduncle bounding regions and/or presence score labels for each B-mode image in a sequence of images, which may be utilized to generate one or more B-mode frame sequences for the second training dataset described herein. In some implementations, label data corresponding to sequences of B-mode images may be generated by executing the first machine learning model using the single B-mode images of each sequence as input. In such implementations, the second imaging data using to train and/or update the second machine learning model may include one or more sequences of B-mode frames that include single B-mode frames provided to the first machine learning model and data indicative of bounding regions that locate the cerebral peduncle predicted by the first machine learning model.

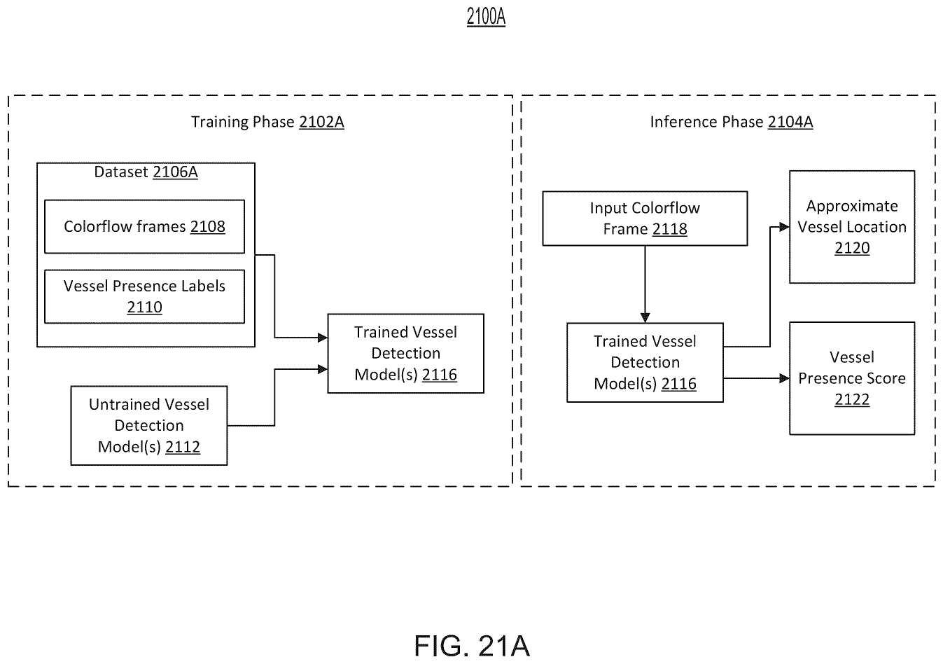

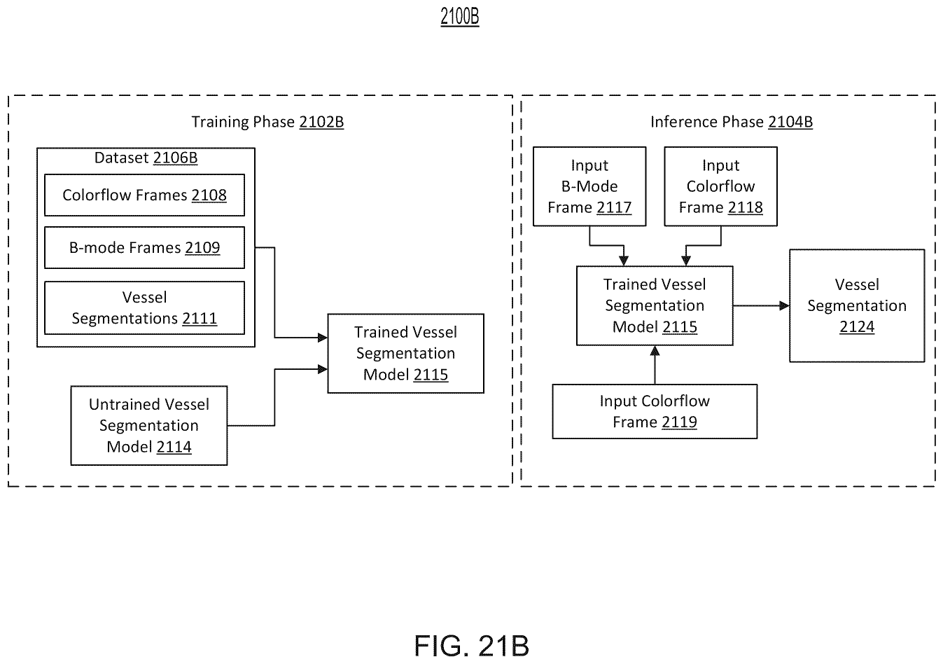

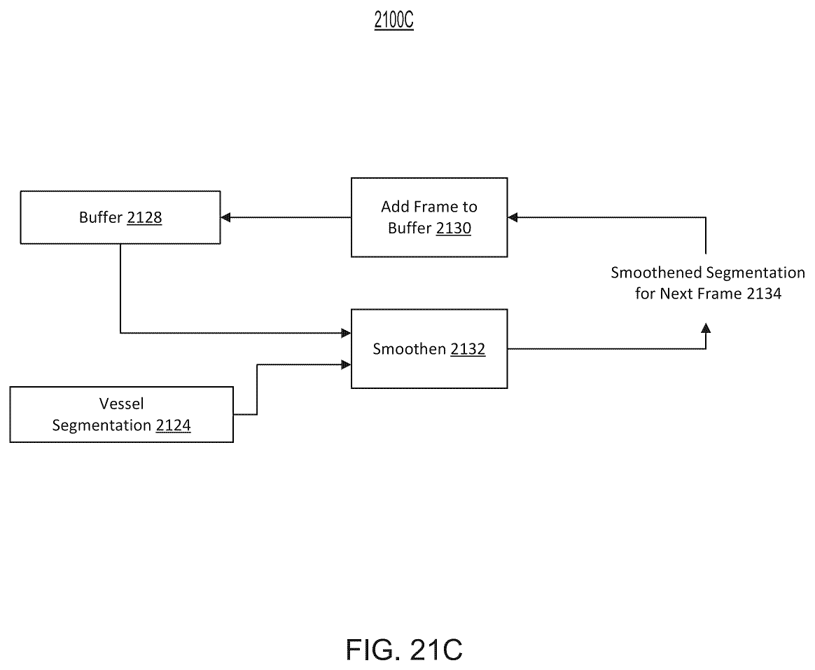

Referring to FIGS. 21A, 21B, and 21C, depicted non-limiting example dataflow diagrams 2100A, 2100B, and 2100C showing processes for training and executing machine-learning models for brain vessel detection and segmentation, in accordance with one or more embodiments of the disclosure. FIG. 21A shows the dataflow diagram 2100A, which provides techniques for training and executing machine-learning models for brain vessel detection in colorflow frames. FIG. 21B shows the dataflow diagram 2100B, which provides techniques for training and executing machine-learning models for brain vessel segmentation with B-mode and colorflow frames. FIG. 21C shows the dataflow diagram 2100C, which provides techniques for smoothing variations of frame-to-frame brain vessel segmentations and/or volume estimates.

Referring to FIG. 21A, illustrated is an example dataflow diagram 2100A, which provides techniques for training and executing machine-learning models for brain vessel detection in colorflow frames. The process shown in the dataflow diagram 2100A may be performed, in a non-limiting example, by the imaging system 1810 (or any components thereof) described herein. As shown, the process may include at least two phases: a training phase 2102A and an inference phase 2104A. During the training phase 2102A, the untrained vessel detection model 2112 may be trained using information stored as part of the dataset 2106A, using machine-learning techniques such as supervised learning, semi-supervised learning, self-supervised learning, and/or unsupervised learning.

In some implementations, the training phase 2102A and the inference phase 2104A may be performed by different computing systems. In a non-limiting example, the training phase 2102A may be performed using a computing environment separate from a system that processes ultrasound images in the inference phase 2104A. In some implementations, because training machine-learning models may utilize additional computing resources that may not necessarily utilized during the inference phase 2104A, a distributed or high-performance computing environment may be utilized to execute the training phase 2102A. In such implementations, the inference phase 2104A may be executed in real-time or near real-time processing of ultrasound images as they are captured via an ultrasound transducer. In a non-limiting example, a cloud-computing platform or a distributed computing environment may perform the training phase 2102A to train the untrained vessel detection model(s) 2112 to produce the trained vessel detection model(s) 2116, which may then be transmitted or otherwise distributed to one or more computing devices that perform imaging with or otherwise operate in connection with an ultrasound device. The one or more computing devices may perform the operations of the inference phase 2104A using the trained vessel detection model(s) 2116, as described herein. The trained vessel detection model(s) 2116 may be stored, in a non-limiting example, as part of the machine-learning models 160 described herein.

In the training phase 2102A, the untrained vessel detection model(s) 2112 may be trained using a suitable machine-learning technique and based upon the information stored in the dataset 2106A. The untrained vessel detection model(s) 2112 may be similar to one or more of the untrained models 1914 described in connection with FIG. 19, and may include any type of machine-learning model that has been untrained for a particular machine-learning task, such as neural network models (e.g., CNNs, deep CNNs, fully connected networks, recurrent neural networks (RNNs), etc.), linear regression models, sparse vector machine models, random forest models, combinations thereof, or any other type of machine-learning model. The untrained vessel detection model(s) 2112 may be stored as one or more data structures defined according to the hyperparameters of the model. The data structures may be stored the trainable parameters of the model, which may be initialized to initial (e.g., untrained) values (e.g., randomly generated values, etc.), as described herein. In some implementations, one or more trainable parameters of the untrained vessel detection model(s) 2112 may be pretrained on trained on a prior (and potentially unrelated or tangentially related) dataset, as described herein.

The training phase 2102A may be executed to train the untrained vessel detection model(s) 2112 to detect the presence (and in some implementations, approximate location) of one or more brain vessels in the colorflow frames 2108. As described herein, the colorflow frames 2108 (sometimes referred to herein as “colorflow images”) may be generated based on the frequency of sound waves changes as they reflect off moving objects, such as blood cells of the patient. The colorflow frames 2108 may be include one or more images that comprise a color map showing the direction of flow of different fluids within an imaged region of the patient (e.g., the patient's brain). In some implementations, a red color may indicate flow towards the transducer performing the ultrasound scan, and a blue color may indicate flow away from the transducer. Varied shades or intensities of these colors may provide insights into the speed of fluid flow depicted in each colorflow frame 2108. The colorflow frames 2108 may be utilized in connection with the vessel presence labels 2110 to train the untrained vessel detection model(s) 2112.

The colorflow frames 2108 in the dataset 2106A may be utilized as one or more training datasets to train the untrained vessel detection model(s) 2112. As shown, the dataset 2106A includes multiple colorflow frames 2108, which may be previously captured using one or more ultrasound transducers. The colorflow frames 2108 may each be from the same or different patients, and may result from the same or different scans. The colorflow frames 2108 may be generated by processing signals received from one or more ultrasound transducers (e.g., the ultrasound transducer 1850, etc.), as described herein. The training dataset 2106A is shown as including, for each colorflow frame 2108, a corresponding vessel presence label 2110. Each vessel presence label 2110 can include an indication of whether the corresponding colorflow frame 2108 depicts a brain vessel or does not depict a brain vessel. Non-limiting examples of brain vessels include arteries, veins, or other vessels that supply blood to the brain. In some implementations, brain vessels may include other anatomical structures of the brain that may store, retain, and/or transport, fluid.

The indication of brain vessel presence may be a binary value (e.g., a value of one to indicate a brain vessel is present in the colorflow frame 2108, a value of zero to indicate a brain vessel is not present in the colorflow frame 2108, etc.). In some implementations, the vessel presence labels 2110 may include an indication of an approximate location that the brain vessel is depicted in the corresponding colorflow frame 2108. In a non-limiting example, the approximate location may be pixel coordinates (e.g., a bounding region, etc.), or a general location (e.g., upper left corner, upper right corner, bottom left corner, bottom right corner, another type of general delineation of the colorflow frame 2108, etc.) within the colorflow frame 2108 at which the depicted brain vessel (if any) is located.

The untrained vessel detection model(s) 2112 may be trained using techniques similar to those described herein, which may include, in a non-limiting example, supervised learning. To train the untrained vessel detection model(s) 2112 using supervised learning, training data from the dataset 2106A, which is shown as including the colorflow frames 2108 and the vessel presence labels 2110, are provided as input to the untrained vessel detection model(s) 2112. In a non-limiting example where the untrained vessel detection model(s) 2112 include neural networks, the untrained vessel detection model(s) 2112 are then executed by performing mathematical computations of each layer (e.g., convolutions, activation functions, multiplications by weight values, etc.) and propagating the resulting data to the next layer in the network. This process is repeated for each layer in the untrained vessel detection model(s) 2112 until corresponding outputs are generated.

The outputs can then be compared to the pre-generated labels (e.g., the vessel presence labels 2110) associated with each respective colorflow frame 2108 to determine the loss. An optimization algorithm (e.g., gradient descent, Adam, etc.) is then performed using the loss as input to optimize the trainable parameters (e.g., weights, biases, etc.) of the untrained vessel detection model(s) 2112 to minimize the loss. Similar approaches may be performed for other types of models, such as regression models, in which an optimization technique may be performed after providing the colorflow frame 2108 as input to the untrained vessel detection model(s) 2112 and executing the mathematical computations (involving the trainable parameters) of the model. This training process may be repeated for multiple input training colorflow frames 2108 until a training termination condition is satisfied. Training termination conditions may be similar to those described in connection with FIG. 19.

Once the training termination condition has been satisfied, the now-updated untrained vessel detection model(s) 2112 can be stored (e.g., in one or more data structures or model files) as the trained vessel detection model(s) 2116. The trained vessel detection model(s) 2116 may be stored, in some implementations, as part of the machine-learning models 1860 of FIG. 18. The trained vessel detection model(s) 2116 can then be accessed and utilized during the inference phase 2104 to generate predictions (e.g., the approximate vessel location(s) 2120, the vessel presence score(s) 2122, etc.) relating to brain vessels potentially depicted in input colorflow frames 2118. In some implementations, after training, the trained vessel detection model(s) 2116 can be transmitted to one or more computing systems that utilize the trained vessel detection model(s) 2116 during the inference phase 2104A. In some implementations, the inference phase 2104A may be executed by the same computing system that executed the training phase 2102A.

The inference phase 2104A may include a process for utilizing the trained model(s) 2116 generated in the training phase 2102A to detect the presence and location of the cerebral peduncle(s) in an input colorflow frame 2118. The input colorflow frame 2118 may be a colorflow image that is captured using an ultrasound transducer such as the ultrasound transducer 1850. The input colorflow frame 2118 may be a frame that was not included in the dataset 2106A, and therefore the trained models 2116 have not been exposed to the input colorflow frame 2118 during the training phase 2102.

The inference phase 2104A may be utilized to detect the presence and location of the cerebral peduncle in real-time or near real-time, and in a non-limiting example, during an ultrasound procedure on a patient's brain. During the inference phase 2104A, input colorflow frames 2118 are provided as input to the trained vessel detection model(s) 2116. The input colorflow frames 2118 may, in non-limiting examples, be captured during an ultrasound procedure, provided in a request to process the input colorflow frames 2118 (e.g., from an external computing device), retrieved from a data repository or storage system, or otherwise accessed by the computing system executing the inference phase 2104A.

In some implementations, the input colorflow frames 2118 may be processed prior to being provided as input to the trained vessel detection model(s) 2116. Processing the input colorflow frames 2118 may include cropping, down-sampling, sharpening, adjusting brightness, or other pre-processing tasks that may be utilized to improve brain vessel detection accuracy or compatibility with the trained vessel detection model(s) 2116. In some implementations, a single colorflow frame 2118 may be provided as input to the trained vessel detection model(s) 2116, which is then executed to generate at least one vessel presence score 2122. To execute the trained vessel detection model(s) 2116, data of the input colorflow frame 2118 can be propagated through and utilized in the mathematical computations of each layer (e.g., convolutions, activation functions, multiplications by weight values, etc.). The resulting data of each layer is then propagated to the next layer in the network until corresponding outputs (e.g., the approximate vessel location 2120, the vessel presence score 2122) are generated.

The vessel presence score 2122 may be a prediction of whether the input colorflow frame 2118 depicts at least one brain vessel, or a particular brain vessel that the trained vessel detection model(s) 2116 were trained to detect. The vessel presence score 2122 may be, in some implementations, a binary value (e.g., a zero indicating no brain vessel is present, a one indicating that a brain vessel has been detected in the input colorflow image 2118). In some implementations, one or more of the trained vessel detection model(s) 2116 may be trained to additionally or alternatively output an approximate vessel location 2120 of the detected brain vessel indicated by the vessel presence score 2122. In a non-limiting example, the approximate vessel location may be a pixel coordinate (e.g., of an estimated center of the vessel within the colorflow frame 2118), a bounding region (e.g., a bounding box), or a predetermined portion of the input colorflow frame 2118 at which the brain vessel is estimated to be depicted.

The approximate vessel location 2120 may be generated by the same trained vessel detection model 2116 that generated the vessel presence score 2122, or in some implementations, by using a second trained vessel detection model 2116 trained specifically to output the approximate vessel location 2120 within the input colorflow frame 2118. In some implementations, an output image that indicates the approximate vessel location 2120 of the detected vessel displayed within or superimposed on the input colorflow frame 2118 may be generated. The output image(s) may be displayed at a display device of the computing device executing the interference phase 2104A, or may be provided to another computing device for display. The vessel presence scores 2122 may be shown or otherwise indicated in association with the output image(s) or the input colorflow frame(s) 2118 on the display of the computing device.

Referring to FIG. 21B, illustrated is an example dataflow diagram 2100B, which provides techniques for training and executing machine-learning models for brain vessel segmentation with B-mode and colorflow frames. The process shown in the dataflow diagram 2100B may be performed, in a non-limiting example, by the imaging system 12310 (or any components thereof) described herein. As shown, the process may include at least two phases: a training phase 2102B and an inference phase 2104B. During the training phase 2102B, the untrained vessel segmentation model 2114 may be trained using information stored as part of the dataset 2106B, using machine-learning techniques such as supervised learning, semi-supervised learning, self-supervised learning, and/or unsupervised learning.

In some implementations, the training phase 2102B and the inference phase 2104B may be performed by different computing systems. In a non-limiting example, the training phase 2102B may be performed using a computing environment separate from a system that processes ultrasound images in the inference phase 2104B. In some implementations, because training machine-learning models may utilize additional computing resources that may not necessarily utilized during the inference phase 2104B, a distributed or high-performance computing environment may be utilized to execute the training phase 2102B. In such implementations, the inference phase 2104B may be executed in real-time or near real-time processing of ultrasound images as they are captured via an ultrasound transducer.

In a non-limiting example, a cloud-computing platform or a distributed computing environment may perform the training phase 2102B to train the untrained vessel segmentation model(s) 2114 to produce the trained vessel segmentation model(s) 2115, which may then be transmitted or otherwise distributed to one or more computing devices that perform imaging with or otherwise operate in connection with an ultrasound device. The one or more computing devices may perform the operations of the inference phase 2104B using the trained vessel segmentation model(s) 2115, as described herein. The trained vessel segmentation model(s) 2115 may be stored, in a non-limiting example, as part of the machine-learning models 160 described herein.

In the training phase 2102B, the untrained vessel segmentation model(s) 2114 may be trained using a suitable machine-learning technique and based upon the information stored in the dataset 2106B (sometimes referred to as a training dataset 2106B). The untrained vessel segmentation model(s) 2114 may be machine-learning models that include architectures for generating segmentations of input images (e.g., the colorflow frames 2108, the B-mode images 2109). The segmentations may be partitions of the input frame(s) into segments, where each segment represents a distinct category or class. In some implementations, segmentations may be generated on a per-pixel basis, such that each pixel of the input frame(s) are classified into a distinct category. In the examples shown here, the distinct categories may include classifications of one or more brain vessels. In some implementations, the classification may be the presence of any brain vessel. In some implementations, different classifications may be generated for multiple types of brain vessels. The segmentations may be output in the form of a segmentation map, which may have the same, or a multiple of, the dimensionality (e.g., width, height, etc.) of the input data.

The untrained vessel segmentation model(s) 2114 may include neural networks with one or more convolutional layers (e.g., a CNN). In some implementations, the untrained vessel segmentation model(s) 2114 may include any type or number of machine-learning layers that may be utilized in connection with neural networks. In a non-limiting example architecture, the untrained vessel segmentation model(s) 2114 may include one or more layers that define an encoder. The encoder may include a series of convolutional layers, which may be followed by further processing layers such as normalization layers and/or activation functions (e.g., ReLU, etc.). The encoder portion of the non-limiting example architecture may include one or more pooling layers. The encoder may reduce the spatial resolution of the input data, while retaining semantic data that is relevant to producing accurate segmentations.

In some implementations, the untrained vessel segmentation model(s) 2114 may include a bottleneck, which may serve as a transition layer between one or more encoder layers and one or more decoder layers. In a non-limiting example, the bottleneck layer(s) may include convolutional layers trained to extract complex features present in the input data from the data produced by the encoder. Furthering this non-limiting example, the untrained vessel segmentation model(s) 2114 may include one or more decoders. The decoder may include one or more layers that perform upsampling operations (e.g., transposed convolutions, up-convolutions, etc.) to increase the spatial resolution of the feature maps generated via the previous layers of the model. In some implementations, the untrained vessel segmentation model(s) 2114 may include one or more skip connections, which may be utilized to transfer spatial information and gradients between different layers (e.g., the encoder to the decoder, etc.), enhancing the spatial accuracy of the output segmentations relative to the input data.

The untrained vessel segmentation model(s) 2114 may include one or more output layers, which are trained to generate the segmentations as output. The output layer of the untrained vessel segmentation model(s) 2114 may produce a segmentation mask, which may include pixel-wise (or region-wise) classification probabilities spatially corresponding to respective portions of the input colorflow frame 2108 and/or B-mode frame 2109. In some implementations, the output layer may include at least one convolutional layer with a number of channels corresponding to the number of classes (e.g., the number of segments). An activation function (e.g., softmax) may be utilized used here to provide pixel-wise class probabilities for each pixel in the segmentation mask.

The untrained vessel segmentation model(s) 2114 may be stored as one or more data structures defined according to the hyperparameters of the model. The data structures may store the trainable parameters of the model, which may be initialized to initial (e.g., untrained) values (e.g., randomly generated values, etc.), as described herein. In some implementations, one or more trainable parameters of the untrained vessel segmentation model(s) 2114 may be pretrained on trained on a prior (and potentially unrelated or tangentially related) dataset, as described herein.

The training phase 2102B may be executed to train the untrained vessel segmentation model(s) 2114 to generate brain vessel segmentations from pairs of corresponding colorflow frames 2108 and B-mode frames 2109. The B-mode frames 2109 may be similar to the B-mode frames 1908, as described herein. The B-mode frames 2109 may be captured at the same time as the respective colorflow frames 2108, for example, using duplex ultrasound techniques. Concurrent capture of B-mode frames 2109 and colorflow frames 2108 enables the input to the untrained vessel segmentation model 2114 to include both anatomical structures (e.g., via the B-mode images) and blood flow within those structures (e.g., via the colorflow images 2108).

The colorflow frames 2108 and the corresponding, respective B-mode frames 2109 in the dataset 2106B may be utilized as one or more training datasets to train the untrained vessel segmentation model(s) 2114. As shown, the dataset 2106B includes multiple colorflow frames 2108 and B-mode frames 2109, which may be previously captured using one or more ultrasound transducers, as described herein. The training dataset 2106B is shown as including, for each colorflow frame 2108, a corresponding B-mode frame 2109, and corresponding vessel segmentations 2111. Each vessel segmentation 2111 may include a pixel-wise (or region-wise) segmentation map that has the same dimensionality as the corresponding colorflow frames 2108 and/or the B-mode frames 2109. The segmentation map may indicate which pixels correspond to brain vessels, and in some implementations may indicate classifications of different types of brain vessels. As described herein, the vessel segmentations 2111 may be pre-generated and at least partially user-defined. In some implementations, the untrained vessel segmentation model 2114 may be trained to predict vessel volume of one or more brain vessels. In such implementations, the vessel segmentations 2111 may include corresponding vessel volume values, which may be utilized as label data as described herein.

The untrained vessel segmentation model(s) 2114 may be trained using techniques similar to those described herein, which may include, in a non-limiting example, supervised learning. To train the untrained vessel segmentation model(s) 2114 using supervised learning, training data from the dataset 2106B, which is shown as including the colorflow frames 2108 and the corresponding B-mode frames 2109, are provided as input to the untrained vessel segmentation model(s) 2114. In a non-limiting example where the untrained vessel segmentation model(s) 2114 include neural networks, the untrained vessel segmentation model(s) 2114 are then executed by performing mathematical computations of each layer (e.g., convolutions, activation functions, multiplications by weight values, etc.) and propagating the resulting data to the next layer in the network. This process is repeated for each layer in the untrained vessel segmentation model(s) 2114 until corresponding segmentations are generated are generated.

The output segmentations can then be compared to the pre-generated labels (e.g., the vessel segmentations 2111) associated with each respective colorflow frame 2108 and respective, corresponding B-mode frame 2109 to determine the loss. An optimization algorithm (e.g., gradient descent, Adam, etc.) is then performed using the loss as input to optimize the trainable parameters (e.g., weights, biases, etc.) of the untrained vessel segmentation model(s) 2114 to minimize the loss. This training process may be repeated for multiple input training colorflow frames 2108 until a training termination condition is satisfied. Training termination conditions may be similar to those described in connection with FIG. 19.

Once the training termination condition has been satisfied, the now-updated untrained vessel segmentation model(s) 2114 can be stored (e.g., in one or more data structures or model files) as the trained vessel segmentation model(s) 2115. The trained vessel segmentation model(s) 2115 may be stored, in some implementations, as part of the machine-learning models 1860 of FIG. 18. The trained vessel segmentation model(s) 2115 can then be accessed and utilized during the inference phase 2104 to generate predicted segmentations of brain vessels potentially depicted in input B-mode frames 2117 and input colorflow frames 2118. In some implementations, after training, the trained vessel segmentation model(s) 2115 can be transmitted to one or more computing systems that utilize the trained vessel segmentation model(s) 2115 during the inference phase 2104B. In some implementations, the inference phase 2104B may be executed by the same computing system that executed the training phase 2102B.

The inference phase 2104B may include a process for utilizing the trained model(s) 2116 generated in the training phase 2102B to generate vessel segmentations 2124 from corresponding input B-mode frames 2117 and colorflow frames 2118. The input B-mode frames 2117 and corresponding input colorflow frames 2118 may be captured using an ultrasound transducer such as the ultrasound transducer 1850 and may be produced concurrently. The input B-mode frames 2117 and corresponding input colorflow frames 2118 may therefore depict the same anatomical area of the patient. The input B-mode frames 2117 and corresponding input colorflow frames 2118 may be frames that were not included in the dataset 2106B, and therefore the trained vessel segmentation model(s) 2115 have not been exposed to input B-mode frames 2117 and corresponding input colorflow frames 2118 during the training phase 2102.

The inference phase 2104B may be utilized to generate segmentations of brain vessels real-time or near real-time, and in a non-limiting example, during an ultrasound procedure on a patient's brain. The segmentations may be displayed to an operator in real-time or near real-time. The vessel segmentations 2124 produced by the trained vessel segmentation model 2115 may provide frame-level brain vessel detection by deriving vessel volume. The vessel segmentations 2124 may also be used to derive quantities related to blood flow velocity and to characterize the vessel shape. During the inference phase 2104B, an input B-mode frame 2117 and a corresponding input colorflow frame 2118 are provided as input to the trained vessel segmentation model(s) 2115. The input B-mode frame 2117 and the corresponding input colorflow frame 2118 may, in non-limiting examples, be captured during an ultrasound procedure, provided in a request to process the input frames (e.g., from an external computing device), retrieved from a data repository or storage system, or otherwise accessed by the computing system executing the inference phase 2104B.

In some implementations, the input B-mode frames 2117 and the corresponding input colorflow frames 2118 may be processed prior to being provided as input to the trained vessel segmentation model(s) 2115. In one example, the input B-mode frame 2117 and the corresponding input colorflow frame 2118 may be individually upscaled and/or downscaled to match in dimensionality (e.g., width and height). Processing the input colorflow frames 2118 may include cropping, down-sampling, sharpening, adjusting brightness, or other pre-processing tasks that may be utilized to improve brain vessel segmentation accuracy or compatibility with the trained vessel segmentation model(s) 2115. In some implementations, a single B-mode frame 2117 and a single colorflow frame 2118 may be provided as input to the trained vessel segmentation model(s) 2115, which is then executed to generate at least one vessel segmentation 2124. To execute the trained vessel segmentation model(s) 2115, data of the input B-mode frame 2117 and the input colorflow frame 2118 can be propagated through and utilized in the mathematical computations of each layer (e.g., convolutions, activation functions, multiplications by weight values, etc.). The resulting data of each layer is then propagated to the next layer in the network until corresponding outputs (e.g., vessel segmentations 2124) are generated.

As described herein, the vessel segmentation 2124 may include a segmentation map indicating corresponding classifications of each pixel within the input frames as corresponding to a respective brain vessel. The classifications may be an indication that the pixel corresponds to any brain vessel. The classifications may be an indication that the pixel corresponds to one or more specific brain vessels. The trained vessel segmentation models 2115 may be trained to detect and distinguish between any number of brain vessel segmentations, as defined by the hyperparameters of the model and by the training dataset 2106B. In some implementations, an output image that indicates the vessel segmentations 2124 displayed within or superimposed on the input colorflow frame 2118 and/or the input B-mode image 2117 may be generated. The output image(s) may be displayed at a display device of the computing device executing the interference phase 2104B or may be provided to another computing device for display.

Referring to FIG. 21C, depicted is an example dataflow diagram 2100C, which provides techniques for smoothing variations of frame-to-frame brain vessel segmentations and/or volume estimates. The process shown in the dataflow diagram 2100C may be performed in connection with the inference phase 2104B described in connection with FIG. 21B. The example process shown in the diagram 2100C may be performed on frames as they are captured and processed in the inference phase 2104B to produce corresponding vessel segmentations 2124. As shown, the process may include an iterative process in which vessel segmentations 2124 generated in the inference phase 2104B are provided as input to a smoothening operation 2132 to produce a smoothened segmentation 2134 for the next vessel segmentation frame that is to be captured by an ultrasound transducer device.

The process shown in the dataflow diagram 2100C may begin by generating vessel segmentations of one or more ultrasound images (e.g., a B-mode image 2117 and a corresponding colorflow image 2118, et.) during an ultrasound procedure, as described in connection with the FIG. 21B. The captured vessel segmentations 2124 are then provided as input to a smoothening model 2132, which may include one or more algorithms or functions that smoothen segmentations between ultrasound frames. As shown, a second input to the smoothening process 2132 is an output of a buffer 2128, which may store a previously captured and/or processed vessel segmentation 2134. In some implementations, if the vessel segmentation 2124 is the first segmentation in the process (e.g., the buffer 2128 is empty), the smoothening process 2132 may receive the vessel segmentation 2124 as a first input and a default value (e.g., a predetermined value) as a second input. In some implementations, the default value is a duplicate of the vessel segmentation 2124 provided as the first input.

The smoothening process 2132 may be executed using the at least two inputs to generate the smoothened segmentation 2134, which is a processed version of the input vessel segmentation 2124. The smoothening process 2132 may be utilized to smooth variations of frame-to-frame brain vessel segmentations 2124. In some implementations, the vessel segmentations 2124 generated using the inference phase 2104B may include volume estimates of the brain vessels to which they correspond. In such implementations, the smoothing operation 2132 may smooth the volume estimates corresponding to the vessel segmentations 2124. The smoothing operation 2132 may include averaging the vessel segmentations 2124 over a set number of consecutive frames. Other non-limiting examples of smoothing operations may include optical flow algorithms, Kalman filtering algorithms, or temporal interpolation, among others. In a non-limiting example, the buffer 2128 may include one or more data structures that store a predetermined number of smoothened segmentations 2134 of a predetermined number of ultrasound frames. The smoothening operation 2132 may retrieve the predetermined number of smoothened segmentations 2134 from the buffer 2128 and perform the smoothing operation using the vessel segmentation 2124 for the current frame to produce a new smoothened segmentation 2134.

The new smoothened segmentation 2134 may be then be utilized added to the buffer 2128 at operation 2130. The operation 2130 may include discarding the oldest smoothened segmentation 2134 from the buffer 2128, and adding the new smoothened segmentation 2134 to the buffer 2128. In such implementations, the buffer 2128 may operate as a first-in first-out (FIFO) data structure (e.g., a queue). The smoothened segmentations 2134 may be displayed in real-time on one or more display devices of the computing device performing the process shown in the dataflow diagram 2100C, or may be provided for display at another computing device. In some implementations, volume estimates of corresponding brain vessels may be calculated from the smoothened segmentations 2134, and may be provided for display using similar techniques.

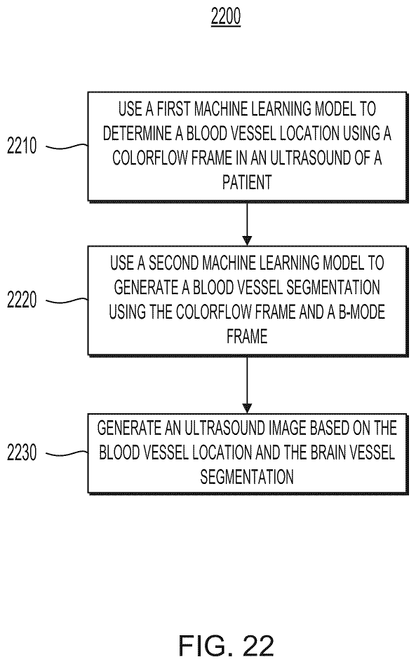

FIG. 22 depicts a flowchart of an example method 2200 of brain vessel detection and segmentation for ultrasound imaging, in accordance with one or more embodiments of the disclosure. The method 2200 may be executed using any suitable computing system (e.g., the imaging system 12310, the computing device 1870 of FIG. 18, the computing system 3200 of FIG. 32, etc.) of an ultrasound system (e.g., the ultrasound system 100). The ultrasound system used to perform the method 2200 may include a portable ultrasound transducer. It may be appreciated that certain steps of the method 2200 may be executed in parallel (e.g., concurrently) or sequentially, while still achieving useful results.

The method 2200 may include act 252210, in which the ultrasound system determines, using a first machine learning model (e.g., the trained vessel detection model 2116), a blood vessel location using a single colorflow frame (e.g., the input colorflow frame 2118) in an ultrasound of a patient. To do so, the ultrasound system may provide the single colorflow frame as input to the first machine learning model. The first machine learning model may then be executed to generate a prediction indicative of a brain blood vessel location (e.g., the approximate vessel location 2120, etc.) in the colorflow frame. In some implementations, the first machine learning model may be trained to output a presence score (e.g., the vessel presence score 2122, etc.) indicative of a confidence of the first machine learning model in the prediction. In some implementations, the presence score may be a binary value.

As described in connection with the training phase 2102A of FIG. 21A, the first machine learning model may be trained (e.g., by training the untrained vessel detection model(s) 2112) using one or more training datasets (e.g., the dataset 2106A). The training dataset may include one or more colorflow frames (e.g., the colorflow frames 2108) and corresponding vessel presence label(s) (e.g., the vessel presence labels 2110). The vessel presence label may be a binary indicator of whether a blood vessel is present in the corresponding colorflow frame.

The method 2200 may include act 2220, in which the ultrasound system generates, using a second machine learning model (e.g., the trained vessel segmentation model 2115), a brain vessel segmentation (e.g., the vessel segmentation 2124) using the single colorflow frame (e.g., the colorflow frame 2118) and a single B-mode frame (e.g., the input B-mode frame 2117). To do so, the ultrasound system may provide the single B-mode frame and the single colorflow frame as input to the second machine learning model. In some implementations, the second machine learning model may be trained (e.g., using the training process 2102B described herein) based at least on vessel volume values (e.g., included in the vessel segmentations 2111) in a training dataset (e.g., the dataset 2106B). The second machine learning model, when executed, can generate a single-frame blood vessel segmentation (e.g., a vessel segmentation 2124) as output.

The ultrasound system can derive one or more metrics related to blood flow velocity based at least on the blood vessel segmentation. In a non-limiting example, the metrics may include blood flow rate or blood pressure, among others. In some implementations, the ultrasound system may characterize blood vessel shape and/or volume based at least on the brain vessel segmentation. As described herein in connection with the dataflow diagram 2100C, the ultrasound system may smooth variations of frame-to-frame brain vessel segmentations in real-time using a buffer (e.g., the buffer 2128) that stores previous segmentations (e.g., the smoothened segmentations 2134).

The method 2200 may include act 2230, in which the ultrasound system generates, for display, an ultrasound image based at least on the blood vessel location and/or the brain vessel segmentation. In some implementations, the ultrasound system may generate an ultrasound image based at least on the prediction of the location of the brain vessel generated by the first machine learning model. In a non-limiting example, said ultrasound image may include an indication of the prediction of the location of the brain vessel within or superimposed on the input colorflow image. In some implementations, the ultrasound image may alternatively or additional include the blood vessel segmentation generated using the second machine learning model. The segmentation may be the smoothened segmentation generated according to the techniques described herein. The ultrasound image may be presented on a frame-by-frame basis, and in a non-limiting example, may be processed and displayed in real-time or near real-time.

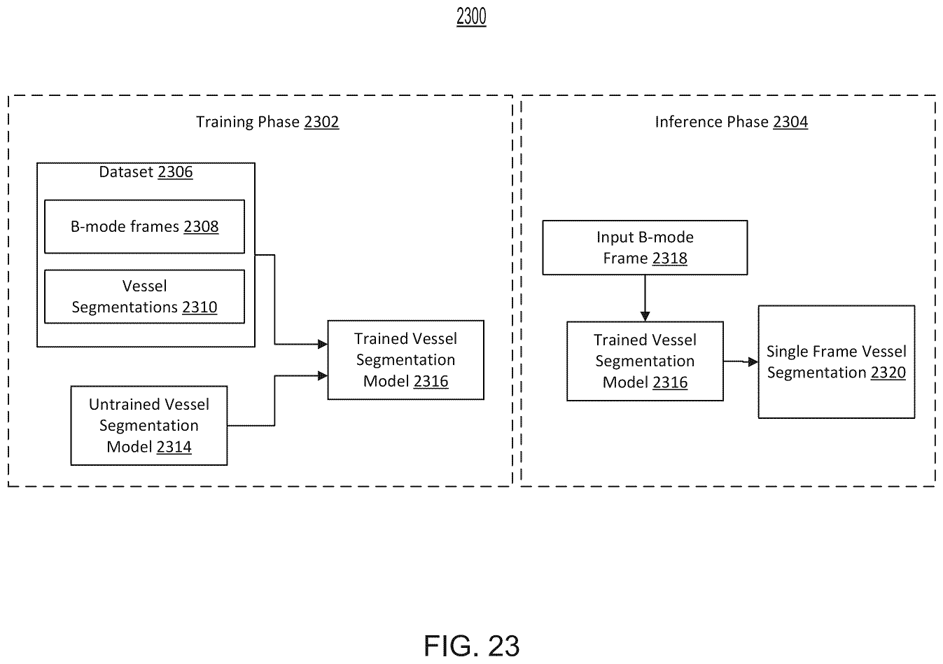

Referring to FIG. 23, depicted is a non-limiting example dataflow diagram 2300 showing a process for training and executing machine-learning models for brain vessel segmentation with B-mode frames, in accordance with one or more embodiments of the disclosure. The process shown in the dataflow diagram 2300 may be performed, in a non-limiting example, by the imaging system 12310 (or any components thereof) described herein. As shown, the process may include at least two phases: a training phase 2302 and an inference phase 2304. During the training phase 2302, the untrained vessel segmentation model 2314 may be trained using information stored as part of the dataset 2306, using machine-learning techniques such as supervised learning, semi-supervised learning, self-supervised learning, and/or unsupervised learning. The process shown in the dataflow diagram 2300 may be similar to the process described in connection with FIG. 21B, but may utilize only B-mode frames to generate segmentations.

In some implementations, the training phase 2302 and the inference phase 2304 may be performed by different computing systems. In a non-limiting example, the training phase 2302 may be performed using a computing environment separate from a system that processes ultrasound images in the inference phase 2304. In some implementations, because training machine-learning models may utilize additional computing resources that may not necessarily utilized during the inference phase 2304, a distributed or high-performance computing environment may be utilized to execute the training phase 2302. In such implementations, the inference phase 2304 may be executed in real-time or near real-time processing of ultrasound images as they are captured via an ultrasound transducer.

In a non-limiting example, a cloud-computing platform or a distributed computing environment may perform the training phase 2302 to train the untrained vessel segmentation model(s) 2314 to produce the trained vessel segmentation model(s) 2316, which may then be transmitted or otherwise distributed to one or more computing devices that perform imaging with or otherwise operate in connection with an ultrasound device. The one or more computing devices may perform the operations of the inference phase 2304 using the trained vessel segmentation model(s) 2316, as described herein. The trained vessel segmentation model(s) 2316 may be stored, in a non-limiting example, as part of the machine-learning models 1860 described herein.

In the training phase 2302, the untrained vessel segmentation model(s) 2314 may be trained using a suitable machine-learning technique and based upon the information stored in the dataset 2306 (sometimes referred to as a training dataset 2306). The untrained vessel segmentation model(s) 2314 may be similar in structure and function to the untrained vessel segmentation model(s) 2112 described in connection with FIG. 21A. In a non-limiting example, untrained vessel segmentation model(s) 2314 may have architectures for generating segmentations of input images (e.g., the B-mode images 2308). As described herein, the segmentations may be partitions of the input frame(s) into segments, and in some implementations may be generated on a per-pixel basis, such that each pixel of the input frame(s) are classified into a distinct category. The distinct categories may include classifications of one or more brain vessels. In some implementations, the classification may be the presence of any brain vessel. In some implementations, different classifications may be generated for multiple types of brain vessels. The segmentations may be output in the form of a segmentation map, which may have the same, or a multiple of, the dimensionality (e.g., width, height, etc.) of the input data.

The untrained vessel segmentation model(s) 2314 may be similar in structure and function to the untrained vessel segmentation model(s) 2112 described in connection with FIG. 21A. As described herein, the untrained vessel segmentation model(s) 2314 may include neural networks with one or more convolutional layers (e.g., a CNN). In some implementations, the untrained vessel segmentation model(s) 2314 may include any type or number of machine-learning layers that may be utilized in connection with neural networks. In a non-limiting example architecture, the untrained vessel segmentation model(s) 2314 may include one or more layers that define an encoder, one or more layers that define a bottleneck, and/or one or more layers that define a decoder. The untrained vessel segmentation model(s) 2314 may include one or more input layers configured to receive at least one B-mode frame 2308 (which may have the same dimensionality of at least one input B-mode frame 2318).

The untrained vessel segmentation model(s) 2314 may include one or more output layers, which are trained to generate the segmentations (e.g., the single frame vessel segmentation(s) 2320) as output. The output layer of the untrained vessel segmentation model(s) 2314 may produce a segmentation mask, which may include pixel-wise (or region-wise) classification probabilities spatially corresponding to respective portions of the input B-mode frame 2308. In some implementations, the output layer may include at least one convolutional layer with a number of channels corresponding to the number of classes (e.g., the number of segments). An activation function (e.g., softmax) may be utilized used here to provide pixel-wise class probabilities for each pixel in the segmentation mask.

The untrained vessel segmentation model(s) 2314 may be stored as one or more data structures defined according to the hyperparameters of the model, as described herein. The data structures may store the trainable parameters of the model, which may be initialized to initial (e.g., untrained) values (e.g., randomly generated values, etc.), as described herein. In some implementations, one or more trainable parameters of the untrained vessel segmentation model(s) 2314 may be pretrained on trained on a prior (and potentially unrelated or tangentially related) dataset, as described herein.

The training phase 2302 may be executed to train the untrained vessel segmentation model(s) 2314 to generate brain vessel segmentations from single B-mode frame 2308, each of which may be stored in association with respective label data (e.g., the vessel segmentations 2310). The B-mode frames 2309 may be similar to the B-mode frames 1908, as described herein. The dataset 2306, including the B-mode frames 2308, may be utilized as a training dataset to train the untrained vessel segmentation model(s) 2314. The training dataset 2306 is shown as including, for each B-mode frame 2308, corresponding vessel segmentations 2310. The vessel segmentations 2310 may be similar to the vessel segmentations 2111 described herein. In some implementations, the vessel segmentations 2310 may be derived at least from colorflow frames. In some implementations, the vessel segmentations 2310 may be produced as output from the trained segmentation model 2115 described herein. The untrained vessel segmentation model 2314 may be trained to detect multiple anatomical landmarks visible in B-mode frames 2308, and utilize those landmarks to estimate the position of brain vessel(s) and their delineations.

In a non-limiting example, a vessel segmentation 2310 may include a pixel-wise (or region-wise) segmentation map that has the same dimensionality as the corresponding B-mode frames 2308. The vessel segmentations 2310 may be pre-generated and at least partially user-defined. In some implementations, the untrained vessel segmentation model 2314 may be trained to predict vessel volume of one or more brain vessels. In such implementations, the vessel segmentations 2310 may include corresponding vessel volume values, which may be utilized as label data as described herein.

The untrained vessel segmentation model(s) 2314 may be trained using techniques similar to those described herein, which may include, in a non-limiting example, supervised learning. To train the untrained vessel segmentation model(s) 2314 using supervised learning, training data from the dataset 2306, which is shown as including the single B-mode frames 2308 are provided as input to the untrained vessel segmentation model(s) 2314. The untrained vessel segmentation model(s) 2314 are then executed by performing mathematical computations of each layer (e.g., convolutions, activation functions, multiplications by weight values, etc.) and propagating the resulting data to the next layer in the network. This process is repeated for each layer in the untrained vessel segmentation model(s) 2314 until corresponding segmentations are generated are generated.

The output segmentations can then be compared to the vessel segmentations 2310 associated with each respective B-mode frame 2308 to determine the loss. The comparison may include a pixel-wise difference, such that corresponding error values are calculated for each position in the segmentation map. An optimization algorithm (e.g., gradient descent, Adam, etc.) is then performed using the loss as input to optimize the trainable parameters (e.g., weights, biases, etc.) of the untrained vessel segmentation model(s) 2314 to minimize the loss. This training process may be repeated for multiple input training colorflow frames 2308 until a training termination condition is satisfied. Training termination conditions may be similar to those described in connection with FIG. 19.

Once the training termination condition has been satisfied, the now-updated untrained vessel segmentation model(s) 2314 can be stored (e.g., in one or more data structures or model files) as the trained vessel segmentation model(s) 2316. As described herein, the trained vessel segmentation model(s) 2316 may be stored, in some implementations, as part of the machine-learning models 160 of FIG. 1. The trained vessel segmentation model(s) 2316 can then be accessed and utilized during the inference phase 2304 to generate predicted segmentations of brain vessels potentially depicted in input B-mode frames 2318. In some implementations, the trained vessel segmentation model(s) 2316 can be transmitted to one or more computing systems that utilize the trained vessel segmentation model(s) 2316 during the inference phase 2304. In some implementations, the inference phase 2304 may be executed by the same computing system that executed the training phase 2302.

The inference phase 2304 may be similar to the inference phase 2104B described in connection with FIG. 21B, except that only single B-mode frames 2318 are provided as input to the trained vessel segmentation model(s) 2318 to generate corresponding single frame vessel segmentations 2320. In some implementations, the input B-mode frames 2318 may be captured by an ultrasound transducer, and the single frame vessel segmentations 2320 may be generated and displayed to an operator in real-time or near real-time. The vessel segmentations 2324 produced by the trained vessel segmentation model 2316 may provide frame-level brain vessel detection by deriving vessel volume. The vessel segmentations 2324 may also be used to derive quantities related to blood flow velocity and to characterize the vessel shape. During the inference phase 2304B, an input B-mode frame 2318 is provided as input to the trained vessel segmentation model(s) 2316. In some implementations, the input B-mode frame 2318 may, in non-limiting examples, be provided in a request to process the input frames (e.g., from an external computing device), retrieved from a data repository or storage system, or otherwise accessed by the computing system executing the inference phase 2304.

The trained vessel segmentation model(s) 2316 are executed to generate a vessel segmentation 2320 corresponding to the input B-mode frame 2318. To execute the trained vessel segmentation model(s) 2316, data of the input B-mode frame 2318 and the input colorflow frame 2118 can be propagated through and utilized in the mathematical computations of each layer (e.g., convolutions, activation functions, multiplications by weight values, etc.). The resulting data of each layer is then propagated to the next layer in the network until the correspond single frame vessel segmentation 2320 are generated.

The single frame vessel segmentation 2320 may be displayed in connection with, or superimposed on, the input single B-mode frame 2318 to generate an output image. The output image(s) may be displayed at a display device of the computing device executing the interference phase 2104B or may be provided to another computing device for display. In some implementations, the single frame vessel segmentations 2320 generated using the trained segmentation model 2316 may be utilized to facilitate faster time-to-target when navigating the operator of an ultrasound transducer to a target vessel. Moreover, due to the use of B-mode frames 2318, the single frame vessel segmentations 2320 may be more robust to noise that would otherwise be captured using colorflow imaging processes.

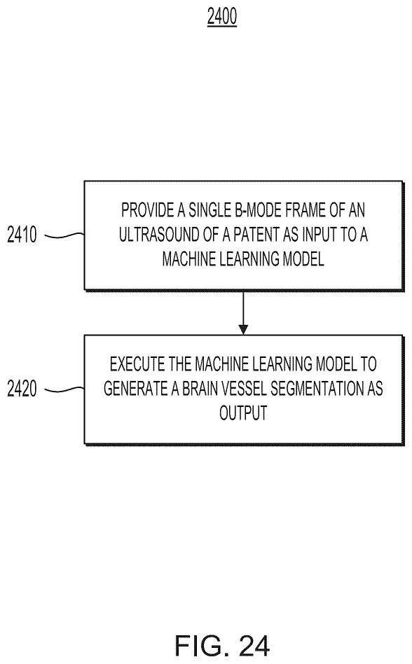

FIG. 24 depicts a flowchart of an example method 2400 of brain vessel segmentation with B-mode frames, in accordance with one or more embodiments of the disclosure. The method 2400 may be executed using any suitable computing system (e.g., the imaging system 1810, the computing device 1870 of FIG. 18, the computing system 3200 of FIG. 32, etc.) of an ultrasound system (e.g., the ultrasound system 1800). The ultrasound system used to perform the method 2400 may include a portable ultrasound transducer. It may be appreciated that certain steps of the method 2400 may be executed in parallel (e.g., concurrently) or sequentially, while still achieving useful results.

The method 2400 may include act 2410, in which the ultrasound system provides a single B-mode frame (e.g., the input B-mode frame 2318) of an ultrasound of a patient as input to a machine learning model (e.g., the trained vessel segmentation model 2316). As described herein, the machine learning model may be trained to receive a single B-mode frame as input and generate a corresponding vessel segmentation (e.g., the single frame vessel segmentation 2320) as output. Providing the B-mode frame as input to the machine learning model may include formatting or otherwise adapting the B-mode frame for the input layer of the machine learning model. In some implementations, the machine learning model does not receive any colorflow images as input to produce the vessel segmentation(s).

The method 2400 may include act 2420, in which the ultrasound system generates ultrasound images comprising brain vessel segmentations at least based on the outputs of the machine learning model. The machine learning model may be executed by performing the mathematical computations of each layer (e.g., convolutions, activation functions, multiplications by weight values, etc.) in the machine learning model, and propagating the resulting data to each next layer until corresponding outputs are generated. The output layer of the machine learning model may generate vessel segmentations (e.g., a segmentation map) indicating one or more segmentations of the input B-mode image. The segmentation map may then be superimposed on (or displayed in connection with the B-mode image) to produce an ultrasound image that includes both the segmentation map and the B-mode image.

In a non-limiting example, one or more colors may be assigned to the classifications represented in the segmentation map, and the colors may be superimposed on the input B-mode frame at positions encoded in the segmentation map. In some implementations, an operator of the ultrasound system may interact with the ultrasound system to toggle different segmentations on or off, to control which segmentations are hidden or displayed in connection with the input B-mode image. In some implementations, the output segmentations, and the output images may be presented in real-time or near real-time, and may be generated during an ultrasound procedure on a patient. As described herein, the machine learning model that generates the output segmentations of the brain vessel(s) may be trained to detect one or more anatomical landmarks in the input B-mode images, and utilize the anatomical landmarks to estimate a position and/or delineation of a brain vessel identified in the output vessel segmentations.

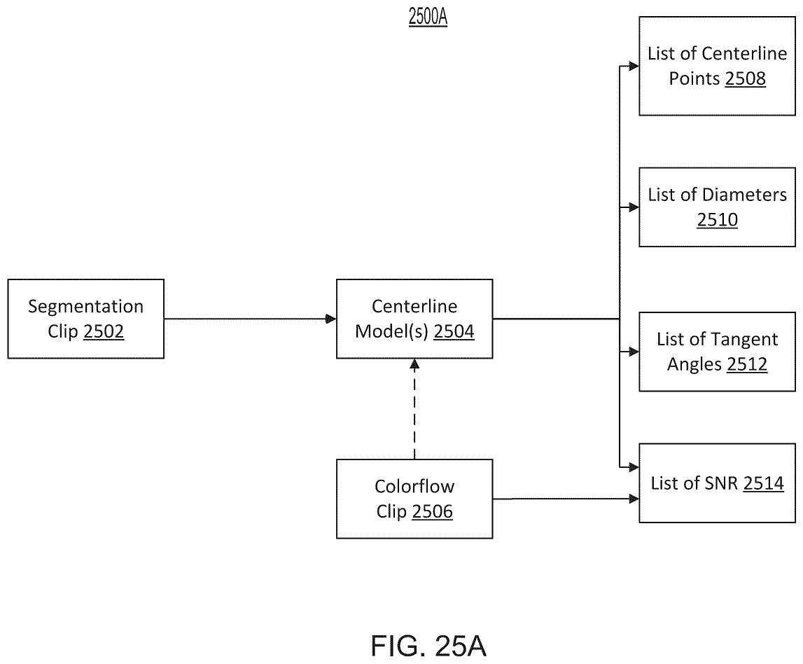

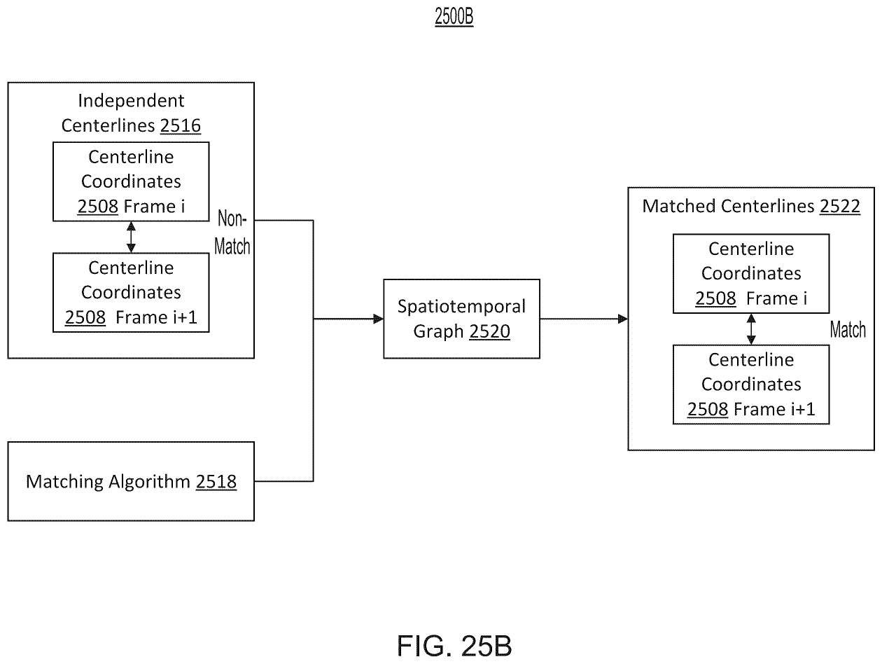

Referring to FIGS. 25A and 25B, depicted are non-limiting example dataflow diagrams 2500A and 2500B showing processes for training and executing machine-learning models for brain vessel parameterization and tracking, in accordance with one or more embodiments of the disclosure. FIG. 25A shows the dataflow diagram 2500A, which provides techniques for brain vessel parameterization. FIG. 25B shows the dataflow diagram 2500B, which provides techniques for brain vessel tracking based on the brain vessel parameterization described in connection with FIG. 25A.

Referring to FIG. 25A, illustrated is an example dataflow diagram 2500A, which provides techniques for brain vessel parameterization. The brain vessel parameters generated using the techniques described herein may be utilized in connection with the brain vessel tracking techniques described in connection with FIG. 25B. The process shown in the dataflow diagram 2500A may be performed, in a non-limiting example, by the imaging system 110 (or any components thereof) described herein.

The process shown in the dataflow diagram 2500A includes processing a segmentation clip 2502. A segmentation clip 2502 is a sequence of segmentations respectively corresponding to a sequence of ultrasound images captured during an ultrasound procedure of a patient. The segmentations in the segmentation clip 2502 may be generated, in a non-limiting example, from one or more colorflow images (e.g., of the colorflow clip 2506, etc.) and/or one or more B-mode images, using the trained vessel segmentation model 2115 and/or the trained vessel segmentation model 2316 described herein. Instead of a single set of segmentations for a single ultrasound image, the segmentation clip 2502 can include a series of segmentations generated over time. This enables increased accuracy with respect to the determination of blood vessel parameters and/or the tracking procedures described herein.

Another input of the processes described in connection with the process shown in the dataflow diagram 2500A may include the one or more colorflow clip(s) 2506. The colorflow clip 2506 may be a recorded sequence colorflow frames (e.g., the colorflow frames 2108, etc.) obtained during an ultrasound scan of a patient. In a non-limiting example, the colorflow frames of the colorflow flip 2506 may be captured during an ultrasound scan of a patient's brain. Rather than including just a single static colorflow frame, the colorflow clip 2506 may include a series of colorflow frames 2506 captured over time, providing a dynamic view of blood flow or movement of other fluids over time. In some implementations, the colorflow frames included in the colorflow clip 2506 may be stored in chronological order (e.g., the order they were captured during the ultrasound procedure, etc.). Each of the colorflow frames in the colorflow clip 2506 may correspond to the segmentations included in the segmentation clip 2502. Each of the colorflow frames in the colorflow clip 2506 may be utilized in connection with the machine learning model(s) described herein to generate the segmentations included in the segmentation clip 2502.

As shown, the segmentations in the segmentation clip 2502 may be provided as input to the centerline model(s) 2504 to generate brain vessel parameters, which are shown as including a list of centerline coordinates 2508, a list of brain vessel diameters 2510, a list of tangent angles 2512, and a list of signal-to-noise ratio (SNR) values relating to the colorflow frames in the colorflow clip 2506. The centerline model(s) 2504 may include multiple machine learning and/or mathematical models. Executing the centerline model(s) centerline model(s) 2504 may include, for example, executing one or more neural networks, linear regression models, sparse vector machine models, random forest models, hidden Markov models, polynomial fitting models, and/or frequency analysis model(s), among others. The centerline model(s) 2504 may be executed, in a non-limiting example, in real-time or near real-time, to parameterize brain vessels for the tracking techniques described herein.

One or more of the centerline model(s) 2504 may be trained using suitable machine-learning techniques, such as supervised learning, semi-supervised learning, self-supervised learning, and/or unsupervised learning, among others. In a non-limiting example of supervised learning, one o more of the centerline model(s) 2504 may be trained using a set of training data including training segmentation clips, training colorflow images, and corresponding label data. The label data may include any of the brain vessel parameters for which the centerline model(s) 2504 are to be trained to generate, including coordinates of centerlines, diameters of brain vessels and the coordinates, curvature of brain vessels (e.g., tangent angles) at the coordinates, and/or colorflow SNR data for each centerline point.

Furthering the non-limiting example above, one or more of the centerline model(s) 2504 may be trained by providing the segmentations of the training segmentation clip(s), and in some implementations the colorflow frames of the corresponding training colorflow clips as input to the centerline model(s) 2504. In a non-limiting example where the one or more centerline model(s) 2504 being trained include neural networks, the said model may be executed by performing mathematical computations of each layer (e.g., convolutions, activation functions, multiplications by weight values, etc.) and propagating the resulting data to the next layer in the network(s). This process is repeated for each layer until corresponding outputs are generated.

The outputs can then be compared to the pre-generated labels (e.g., coordinates of centerlines, diameters of brain vessels and the coordinates, the tangent angles at the coordinates, the colorflow SNR data, etc.) associated with input training data to determine the loss. An optimization algorithm (e.g., gradient descent, Adam, etc.) is then performed using the loss as input to optimize the trainable parameters (e.g., weights, biases, etc.) of the one or more centerline model(s) being trained. Similar approaches may be performed for other types of models, such as regression models.

In some implementations, execution of the centerline model(s) 2504 may include the execution of a polynomial fitting process to determine one or more of the brain vessel parameters (e.g., the list of coordinates 2508 of centerline points, the list of vessel diameters 2510, the list of tangent angles 2512, and/or the list of colorflow SNR data 2514, etc.) for each segmentation in the segmentation clip 2502. Polynomial fitting may be utilized, in a non-limiting example, to determine one or more centerline coordinates 2508 in the segmentations of the segmentation clip 2502. To do so, the boundaries of a segmentation of a brain vessel can be determined based on an edge detection technique or another type of boundary detection technique. The boundary points can be utilized as input data for polynomial fitting to determine the centerline points 2508 of one or more brain vessels to which the segmentation(s) correspond.

In some implementations, one or more detection algorithms can be executed to determine an approximation of the longitudinal axis of the segmentation, which may provide a set of initial points with which to perform polynomial fitting. In some implementations, the initial points may be determined based on the locations of the boundaries of a segmentation in the segmentation clip 2502. A polynomial curve may then be fit to the set of initial points by identifying a polynomial equation that closely matches to the initial points. The polynomial equation may be, in a non-limiting example, linear, quadratic, cubic, or higher-order polynomial equation. In some implementations, the polynomial equation may be selected at least based on the classification of the brain vessel to which the segmentation corresponds.

A polynomial fitting process, which may be performed based on the detected boundaries of the segmentation being analyzed, may be performed to generate an equation of a polynomial that best fits the center of the segmentation. Once fitted, the polynomial equation may be sampled at predetermined intervals to determine the list of centerline coordinates 2508. The number of points being sampled may be determined based on the classification of the brain vessel identified by the segmentation being analyzed. In some implementations, the polynomial curve generated using the fitting process may be utilized to determine the tangent angles 2512 at each centerline point 2508 on the curve (e.g., using a derivative of the polynomial, etc.). The tangent angles 2512 may be representative of a curvature of the brain vessel at the determined centerline points 2508, in a non-limiting example. Similar techniques may be utilized to determine the list of diameters 2510 at each centerline coordinate point 2508. In a non-limiting example, the diameter 2510 of a brain vessel to which a segmentation corresponds may be determined at each of the list of centerline points 2508 by determining the distance from each centerline point to the closest boundaries of the brain vessel. In some implementations, the diameter 2510 may be determined as a distance between the boundaries may be determined at a particular angle (e.g., the corresponding tangent angle 2512 of the centerline point 2508).

In some implementations, a frequency analysis process may be utilized to determine the colorflow SNR data 2514 at each centerline point coordinate 2508 in each segmentation in the segmentation clip 2502. To determine the SNR data 2514 for a centerline point coordinate 2508, a frequency analysis process such as a fast Fourier transform (FFT) may be utilized on the corresponding colorflow image in the colorflow clip 2506, as shown. To extract the SNR data 2514 for a particular centerline point 2508, the colorflow signal may be extracted and processed from a region of the corresponding colorflow image in the colorflow clip 2506 that includes the centerline point 2508. The frequency analysis process may then be performed using this region as input to produce a set of frequency values representative of the region in the frequency domain. Due to electromagnetic interference from the environment in which the ultrasound scan is performed, the resulting frequency values produced by the FFT process will include both frequencies corresponding to the flow signals (e.g., desired signals) and frequencies corresponding to noise signals (e.g., undesired signals).

Once the frequency values have been generated, the frequencies corresponding to noise can be differentiated from those corresponding to the colorflow signal. A variety of techniques can be utilized to do so, including filtering techniques, noise estimation and subtraction techniques, by using a reference/comparison signal, and/or amplitude discrimination techniques, among others. Once the colorflow signal is differentiated from the noise signal, the SNR data 2514 can be calculated for a centerline point 2508 by comparing the total power of the colorflow signal to the total power of the noise signal (e.g., as a ratio). This SNR value can be stored as part of the list of SNR data 2514, such that each entry in the list of SNR data 2514 corresponds to a respective centerline point 2508.

The foregoing processes may be performed for each segmentation in the segmentation clip 2502 to respective brain vessel parameters (e.g., the list of centerline points 2508, the list of vessel diameters 2510, the list of tangent angles 2512, and/or the list of SNR values 2514) for each segmentation in the segmentation clip 2502. In some implementations, an iterative smoothing algorithm, similar to the process described in connection with FIG. 21C, may be performed prior to determining the brain vessel parameters as described herein. The brain vessel parameters may be utilized in connection with the brain vessel tracking techniques described in connection with FIG. 25B.

Referring to FIG. 25B, depicted is the dataflow diagram 2500B, which provides techniques for brain vessel tracking based on the brain vessel parameters described in connection with FIG. 25A. The process shown in the dataflow diagram 2500B may be performed, in a non-limiting example, by the imaging system 1810 (or any components thereof) described herein. In a non-limiting example, the tracking techniques described in connection with the dataflow diagram 2500B may be performed iteratively (e.g., as brain vessel parameters are generated and/or extracted from segmentations).

The process shown in the dataflow diagram 2500B includes processing the independent centerlines 25162516 using the matching algorithm 2518 to generate a spatiotemporal graph 2520. The spatiotemporal graph 2520 can be generated to include the matched centerlines 2522, as shown. The unmatched centerlines 25162516 may include, for each frame in a sequence of frames (e.g., from a segmentation clip 2502 corresponding to a colorflow clip 2506), a set of centerline points (e.g., the centerline points 2508) generated from corresponding segmentations (e.g., segmentations in a segmentation clip 2502), as described in connection with FIG. 25A. Matching between points in sequential frames can be performed to generate the spatiotemporal graph 2520.

The spatiotemporal graph 2520 may include a data structure that represents spatial information (e.g., location or position) in connection with temporal information (e.g., in a frame-by-frame sequence). The spatiotemporal graph 2520 may include associations between different centerline points determined from segmentations of frames over time. The spatiotemporal graph 2520 may therefore include associations (e.g., tracking) of centerline points to track the location of segmentations and/or brain vessels over an ultrasound scan. Nodes of the spatiotemporal graph 2520 may be represent the spatial, centerline points 2508 extracted from the segmentation clip 2502 produced from the colorflow clip 2506. Each node may include the coordinates of each centerline point 2508, as well as attributes that might change over time, such as speed or direction.

The spatiotemporal graph 2520 may include one or more edges in the graph, each which may connect at least two nodes and may represent a spatial and/or temporal relationship. In a non-limiting example, the spatiotemporal graph 2520 may have multiple layers and/or slices, each of which corresponds to a respective frame. Each layer may include nodes representing the centerline points 2508 of the segmentation extracted from the corresponding frame. Edges may connect the nodes of sequential layers, showing how the coordinates of the centerline points 2508, and therefore the corresponding brain vessels, change over time. In some implementations, adjacent centerline points 2508 may be connected within each layer by spatial edges in the spatiotemporal graph 2520.

To generate the edges in the spatiotemporal graph 2520, a matching algorithm 2518 may be utilized. In some implementations, the matching algorithm 2518 may include the Hungarian matching algorithm (sometimes referred to as the Kuhn-Munkres algorithm). In a non-limiting example where the Hungarian matching algorithm is used, for each frame, the centerline coordinates 2508 of the independent centerlines 25162516 (e.g., of a sequence of frames, generated using the process shown in FIG. 25A, etc.) can be identified. Once the centerline coordinates 2508 are identified for each frame, a cost matrix can be generated that represents the “cost” between each centerline point 2508 in the earlier frame to each centerline point 2508 in the succeeding frame. The cost may be determined based on spatial distance between the centerline points 2508 in the frames. For each cost matrix, the Hungarian algorithm can then be applied to determine the optimal assignment of centerline points 2508 in the prior frame to the centerline points 2508 of the current frame. The output of the Hungarian algorithm includes matching associations that indicate which centerline point 2508 in the earlier frame corresponds to which centerline point 2508 in the succeeding frame, while minimizing the overall cost or distance. Temporal edges (e.g., edges that represent temporal relationships) can then be generated between the nodes representing the matching points in the spatiotemporal graph 2520. This process can be repeated iteratively for the centerlines 2508 generated for each frame in the independent centerlines 25162516.

In some implementations, one or more machine learning models may be utilized to determine matching coordinates in the spatiotemporal graph. In a non-limiting example, the one or more machine-learning models may include neural networks, linear regression models, sparse vector machine models, random forest models, or hidden Markov models, among others. The machine learning models may be executed, in a non-limiting example, in real-time or near real-time, to parameterize brain vessels for the tracking techniques described herein.

One or more of the machine learning model(s) of the matching algorithm 2518 may be trained using suitable machine-learning techniques, such as supervised learning, semi-supervised learning, self-supervised learning, and/or unsupervised learning, among others. In a non-limiting example of supervised learning, one or more of the machine learning model(s) of the matching algorithm 2518 may be trained using a set of training data including training centerline points, training tangent angle data (e.g., similar to the tangent angles 2512, etc.), and corresponding label data. The label data may indications of whether one or more coordinates match between frames, in a non-limiting example. The machine learning model(s) of the matching algorithm 2518 may be trained to generate, using input coordinates of centerlines and/or coordinates and/or tangent angle(s) of the centerline coordinates, an output indication of whether the centerline points match across time. The machine learning model(s) of the matching algorithm 2518 may therefore receive centerline points (and in some implementations, tangent angles corresponding thereto) for consecutive frames to generate the aforementioned output. In some implementations, the machine learning model(s) of the matching algorithm 2518 may be utilized in connection with the Hungarian matching algorithm described herein to generate the spatiotemporal graph 2520.

Once generated, the spatiotemporal graph 2520 can be traversed to track the position of one or more brain vessels over time. As each of the nodes in the graph, which include corresponding centerline coordinates 2508, have edges that point to a next node that represents the position of the centerline at a coordinate 2508 in the subsequent frame, the position of the centerline of the brain vessel can be tracked by traversing and accessing the centerline coordinates at each node in the spatiotemporal graph 2520. These are shown as the matched centerlines 2522, which includes the centerline coordinates 2508 matched between frames to track blood vessel position.

Tracking the brain vessel position may be performed, in a non-limiting example, in real time or near real-time (e.g., as frames are captured using an ultrasound device). In some implementations, the tracked position of the brain vessel may be utilized to control an ultrasound device performing the ultrasound scan. In a non-limiting example, the tracked position of one or more brain vessels may be utilized in to instruct a beam steering component of an ultrasound device, such that the device locks on a target brain vessel and accurately extract the parameters used an accurate assessment of cerebral blood flow velocity.

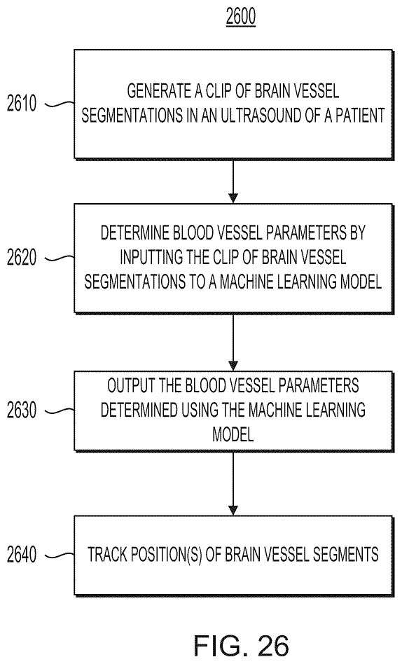

Referring to FIG. 26, depicted a flowchart of an example method 2600 of brain vessel parameterization and tracking, in accordance with one or more embodiments of the disclosure. The method 2600 may be executed using any suitable computing system (e.g., the imaging system 1810, the computing device 1870 of FIG. 18, the computing system 3200 of FIG. 32, etc.) of an ultrasound system (e.g., the ultrasound system 1800). The ultrasound system used to perform the method 2600 may include a portable ultrasound transducer. It may be appreciated that certain steps of the method 2600 may be executed in parallel (e.g., concurrently) or sequentially, while still achieving useful results.

The method 2600 may include act 2610, in which the ultrasound system generates a clip of brain vessel segmentations (e.g., the segmentation clip 2502) in an ultrasound of a patient. The clip of brain vessel segmentations may be generated, in a non-limiting example, using the techniques described in connection with FIG. 21B. The clip of segmentations may correspond to a clip of colorflow frames (e.g., the colorflow clip 2506). The clip of colorflow frames may be frames of an ultrasound scan that are stored sequentially, and in some implementations may be captured and processed into segmentations in real-time or near real-time.

The method 2600 may include act 2702620, in which the ultrasound system determines one or more blood vessel parameters at least by inputting the clip of brain vessel segmentations to a machine learning model (e.g., the centerline model(s) 2504) configured to output one or more blood vessel parameters based at least on the clip of the brain vessel segmentations. As described herein, the blood vessel parameters may include coordinates of a centerline location (e.g., the centerline points 2508). The blood vessel parameters may include a vessel curvature (e.g., the tangent angles 2512) at each centerline location. The blood vessel parameters may include a vessel diameter (e.g., the diameters 2510) at each centerline location. The blood vessel parameters may include a colorflow signal-to-noise ratio (e.g., the SNR data 2514) at each centerline location. In some implementations, the colorflow signal-to-noise ratio at each centerline location may be determined based at least on the colorflow images in the corresponding colorflow clip.

The method 2600 may include act 2630, in which the ultrasound system outputs the one or more blood vessel parameters determined using the machine learning model. Outputting the blood vessel parameters may include providing one or more of the blood vessel parameters for display in connection with the corresponding colorflow images and/or segmentations (e.g., displayed in connection with, or superimposed on, an ultrasound image, etc.). In some implementations, the blood vessel parameters may be provided as input to the tracking process described in connection with act 2640. To generate the blood vessel parameters, the machine learning model of act 2702620 may be executed using the segmentations of the blood vessels as input, as described herein.

The method 2600 may include act 2640, in which the ultrasound system tracks, in a sequence of ultrasound images (e.g., the colorflow clip 2506) a position of brain vessel segments (e.g., the segmentation clip 2502) across time using a machine learning model (e.g., the matching algorithm 2518). The machine learning model may be configured to use parametrization of a brain vessel curve (e.g., one or more tangent angles of centerline points 2508) and a spatiotemporal matching algorithm (e.g., the Hungarian algorithm, etc.) to generate a spatiotemporal graph (e.g., the spatiotemporal graph 2520). In some implementations, the spatiotemporal matching algorithm may include a Hungarian matching algorithm.

In some implementations, the tracking may be implemented as a scan through the spatiotemporal graph. As described herein, each node of the spatiotemporal graph may be connected to edges that point to a next node that represents the position of a centerline (e.g., of a segmentation) at a coordinate in the subsequent. The position of the brain vessel can be tracked by traversing and accessing the centerline coordinates at each node in the spatiotemporal graph. The position of the brain vessel in the ultrasound images can be utilized in to control an ultrasound device. In a non-limiting example, a beam steering component of an ultrasound system may utilize the tracking data to lock onto a target anatomical feature (e.g., a blood vessel). Locking onto the blood vessel may include extracting one or more parameters to perform an assessment of cerebral blood flow velocity.

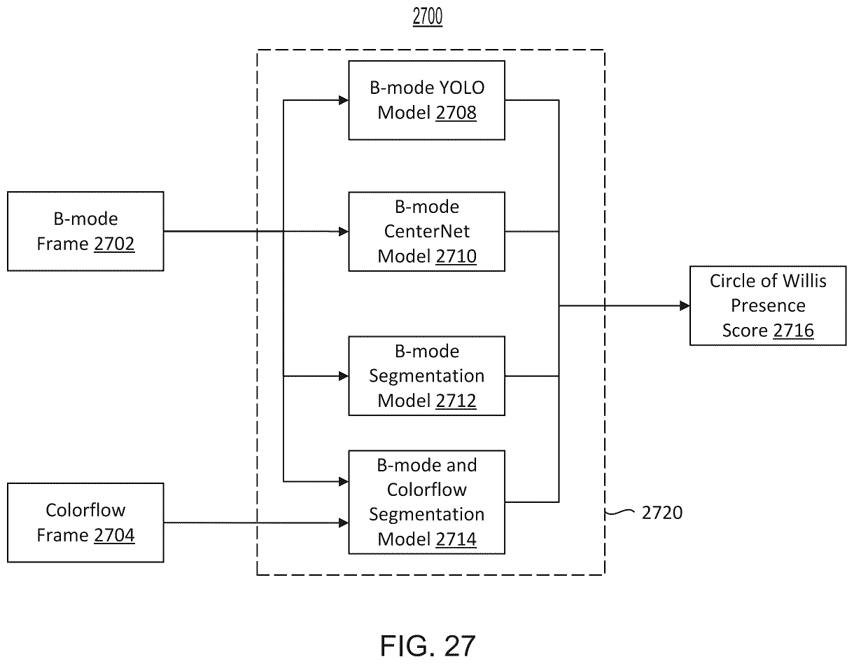

FIG. 27 depicts a non-limiting example dataflow diagram 2700 showing a process for training and executing a machine-learning model ensemble 2720 for brain vessel detection, in accordance with one or more embodiments of the disclosure. The process shown in the dataflow diagram 2700 may be executed to generate a Circle of Willis presence score 2716. As shown, the machine-learning model ensemble 2720 may include several models, the outputs of which may be aggregated to detect one or more target vessels in the Circle of Willis, the presence of which may be indicated by the Circle of Willis presence score 2716.

Each of the machine learning models included in the ensemble 2720 may be trained using different architectures and/or optimization processes. In a non-limiting example, the ensemble 2720 includes a B-mode YOLO model 2708, a B-mode CenterNet model 2710, a B-mode segmentation model 2712, and a B-mode and Colorflow segmentation model 2714. Each of these models may be executed using the same inputs (e.g., the B-mode frame 2702 for all models, the corresponding colorflow frame 2704 for the B-mode and colorflow segmentation model 2714, etc.). The B-mode frame 2702 and the colorflow frame 2704 may be captured at the same time (e.g., using duplex ultrasound), as described herein.

The B-mode YOLO model 2708 and the B-mode CenterNet model 2710 may each be one of the trained models 1916 described in connection with FIG. 19, while having different model architectures. The B-mode YOLO model 2708 may have a YOLO object detection model architecture, and the B-mode CenterNet model 2710 may have a CenterNet object detection model architecture. In some implementations, the B-mode YOLO model 2708 and the B-mode CenterNet model 2710 may be trained on the same training dataset, and in other implementations, the B-mode YOLO model 2708 and the B-mode CenterNet model 2710 may each be trained using different training datasets.

As described in connection with FIG. 19, the B-mode YOLO model 2708 and the B-mode CenterNet model 2710 may be trained to generate output bounding boxes that track an anatomical region of interest in an ultrasound scan. In the example shown in FIG. 27, the B-mode YOLO model 2708 and the B-mode CenterNet model 2710 may be trained to generate bounding boxes for cerebral peduncles (e.g., the output peduncle bounding boxes 1920) using a single B-mode image or a sequence of B-mode images as input. In some implementations, the B-mode YOLO model 2708 and the B-mode CenterNet model 2710 may each generate a corresponding peduncle presence score (e.g., a peduncle presence score 1922). Although the B-mode YOLO model 2708 and the B-mode CenterNet model 2710 may be trained using similar techniques, the outputs of each model may differ due to their differing architectures (and therefore sensitivities). The use of multiple models to detect the same feature using the same input, here the cerebral peduncle in a B-mode frame, may be more robust to outliers than single models used individually.

The B-mode segmentation model 2712 may be one of the trained vessel segmentation models 2316 described in connection with FIG. 23. As described in connection with FIG. 23, the mode segmentation model 2712 may be trained to receive a single B-mode frame 2702 as input, and produce corresponding segmentations (e.g., the single frame vessel segmentation 2320) as output. The B-mode segmentation model 2712 may be trained, in a non-limiting example, based on label data produced based at least on colorflow images. The segmentations produced by the B-mode segmentation model 2712 may be utilized in connection with the segmentations produced by the B-mode and colorflow segmentation model 2714 to generate the Circle of Willis Presence Score 2716.

The B-mode and colorflow segmentation model 2714 may be one of the trained vessel segmentation models 2115 described in connection with FIG. 21B. The B-mode and colorflow segmentation model 2714 may be trained to receive both a B-mode frame 2702 and a colorflow frame 2704 as input, and produce segmentations as output. The training dataset used to train the B-mode and colorflow segmentation model 2714 may include images included in the training dataset used to train the B-mode segmentation model 2712. In some implementations, the outputs of each of the B-mode segmentation model 2712 and the B-mode and colorflow segmentation model 2714 be provided as input to respective temporal smoothing processes, similar to those described in connection with FIG. 21C. The temporally smoothed outputs of both models may then be utilized by the ensemble 2720 to generate the Circle of Willis presence score 2716. The use of multiple models to produce segmentations of brain vessels may be more robust to outliers than single models used individually.

The each of the models of the ensemble may be executed to produce the Circle of Willis presence score 2716, which may proportional to a predicted confidence that the input B-mode frame 2702 and/or the input colorflow frame 2704 depicts the brain vessels of the Circle of Willis. To do so, the ensemble 2720 itself may include one or more machine learning models that are trained (e.g., using various supervised learning techniques described herein in connection with corresponding training data) to receive the outputs of each of the B-mode YOLO model 2708, the B-mode CenterNet model 2710, the B-mode segmentation model 2712, and the B-mode and colorflow segmentation model 2714, and generate the Circle of Willis Presence score 2716.

In some implementations, the inputs to the ensemble 2720 may include a sequence of B-mode frames 2702 and a sequence of colorflow frames 2704. In such implementations, each model of the ensemble may produce a corresponding sequence of outputs. The sequence of outputs may be provided as input to the further machine learning model of the ensemble 2720, which is executed to produce the Circle of Willis presence score 2716. In some implementations, each model may produce a single, respective output from the sequence of B-mode frames 2702 and th sequence of colorflow frames 2704, and the ensemble 2720 may be used to generate the Circle of Willis presence score 2716 using each of the single, respective outputs. In some implementations, the ensemble 2720 may utilize rule-based techniques to generate the Circle of Willis Presence score 2716. In a non-limiting example, the presence of one or more bounding boxes for the cerebral peduncle being proximate to segmentations of the target brain vessels may be indicative of a larger Circle of Willis presence score 2716.

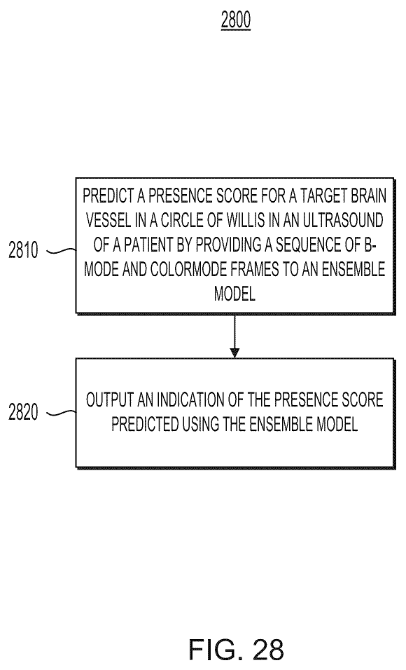

Referring to FIG. 28, depicted a flowchart of an example method 2800 of brain vessel detection using a machine-learning model ensemble, in accordance with one or more embodiments of the disclosure. The method 2800 may be executed using any suitable computing system (e.g., the imaging system 1830, the computing device 1870 of FIG. 18, the computing system 3200 of FIG. 32, etc.) of an ultrasound system (e.g., the ultrasound system 1800). The ultrasound system used to perform the method 2800 may include a portable ultrasound transducer. It may be appreciated that certain steps of the method 2800 may be executed in parallel (e.g., concurrently) or sequentially, while still achieving useful results.

The method 2800 may include act 2810, in which the ultrasound system predicts a presence score for a target brain vessel in a Circle of Willis in an ultrasound of a patient, by providing a sequence of B-mode and colorflow frames to an ensemble model (e.g., the machine learning model ensemble 2720, etc.). The ensemble model configured to aggregate predictions of a plurality of machine learning models with different designs. One or more of the machine learning models may be trained to detect a cerebral peduncle using a single B-mode frame. If multiple machine learning models (e.g., the B-mode YOLO model 2708, the B-mode CenterNet model 2710) are used to detect a cerebral peduncle using a single B-mode frame, each of the multiple models may have different designs/architectures (e.g., a YOLO model, a CenterNet model, etc.). In some implementations, the ensemble model may include one or more machine learning models trained to detect a cerebral peduncle using a sequence of B-mode frames.

In some implementations, the ensemble model may further include one or more machine learning models (e.g., the B-mode and colorflow segmentation model 2714) trained to generate brain vessel segmentations using colorflow frames and/or B-mode frames as input. Said machine learning models may be utilized to perform temporal smoothing (e.g., using a process similar to that described in connection with FIG. 21C). The ensemble model may include at least one machine learning model (e.g., the B-mode segmentation model 2712) that is trained to generate brain vessel segmentations using only B-mode frames. Each of the models may be executed using the corresponding input frames to produce the presence score (e.g., the Circle of Willis presence score 2716), as described herein.

In some implementations, the ensemble may include a first machine learning model (e.g., the B-mode YOLO model 2708) and a second machine learning model (e.g., the B-mode CenterNet model 2710) each a cerebral peduncle using a single B-mode frame. The ensemble may include a third machine learning model (e.g., the trained models 1916) configured to detect a cerebral peduncle using a sequence of B-mode frames. The ensemble may include a fourth machine learning model (e.g., the B-mode and colorflow segmentation model 2714) configured for brain vessel segmentation using B-mode and colorflow frames. The ensemble may include a fifth machine learning model (e.g., the B-mode segmentation model 2712) configured for brain vessel segmentation using only B-mode frames.

The method 2800 may include act 2812, in which the ultrasound system outputs an indication of the presence score predicted using the ensemble model. The output may be indicated in connection with an ultrasound image and may be displayed in real-time or near real-time as an ultrasound process is performed. In a non-limiting example, the presence score may be indicated on a display device accessible to an operator of the ultrasound system. As described herein, the use of an ensemble model may be more robust to outliers than any single models used individually. This is due to each model in the ensemble having a different model architecture, and therefore producing slightly different (and potentially inconsistent in the case of outliers) individual outputs.

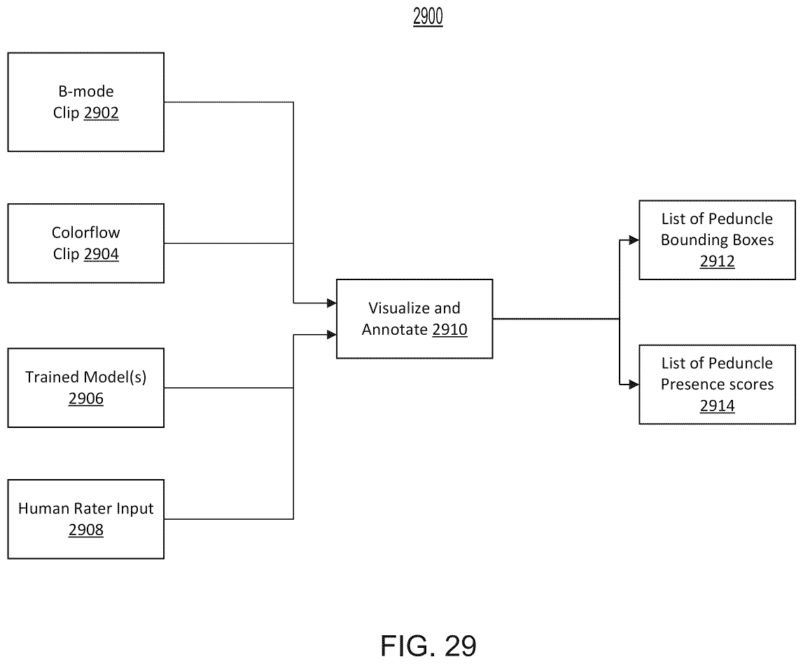

FIG. 29 depicts a non-limiting example dataflow diagram 2900 showing a process for labeling cerebral peduncles or other anatomical structures in ultrasound clips for training machine learning models, in accordance with one or more embodiments of the disclosure. The process shown in the dataflow diagram 2900 may be performed to generate training data to train the untrained models 1914 described in connection with the training phase 1902 of FIG. 19. The example process shown in the diagram 2900 may be performed, in a non-limiting example, to generate peduncle bounding boxes 2912 and peduncle presence scores 2914 for use in training datasets, such as the training dataset 1906 described in connection with FIG. 19.

The process shown in the dataflow diagram 2900 may be performed to facilitate labeling of the cerebral peduncle in video clips of B-mode frames (e.g., frames in the B-mode clip 2902) and/or colorflow frames (e.g., frames in the colorflow clip 2904). Labeling may be performed using the human rater input 2908, which may be provided via software that allows a user to draw a bounding box indicating the location of the cerebral peduncle on one or more B-mode frames 2902 and/or colorflow frames 2904. In some implementations, an initial bounding box may be estimated in other frames based at least on the bounding box location drawn by the user (e.g., as part of the human rater input 2908). To do so, a template matching algorithm may be utilized. and a template matching algorithm. In some implementations, the frames in the B-mode clip 2902 and/or the colorflow clip 2904 may be presented in one or more graphical user interfaces on a display device, and the user may navigate between the frames to accept or correct the bounding boxes generated by the template algorithm.

In some implementations, the template matching algorithm may compute and shows a score that shows the algorithm's confidence in its predictions (e.g., the peduncle presence scores 2914). In some implementations, the trained model(s) 2906, which may be trained using the techniques described herein to receive the frames in the B-mode clip 2902 and/or the frames in the colorflow clip 2904 and generate corresponding initial bounding boxes and corresponding presence scores. The presence scores may be stored in the list of peduncle presence scores 2914 in association with the corresponding frames. The bounding boxes, once accepted or corrected by the user, may be stored as in the list of peduncle bounding boxes 2912. The list of peduncle presence scores 2914 and the list of peduncle bounding boxes 2912 may be stored in a training dataset and utilized, in a non-limiting example, as the peduncle presence labels 1912 and the peduncle bounding boxes 1910 of FIG. 19, respectively.

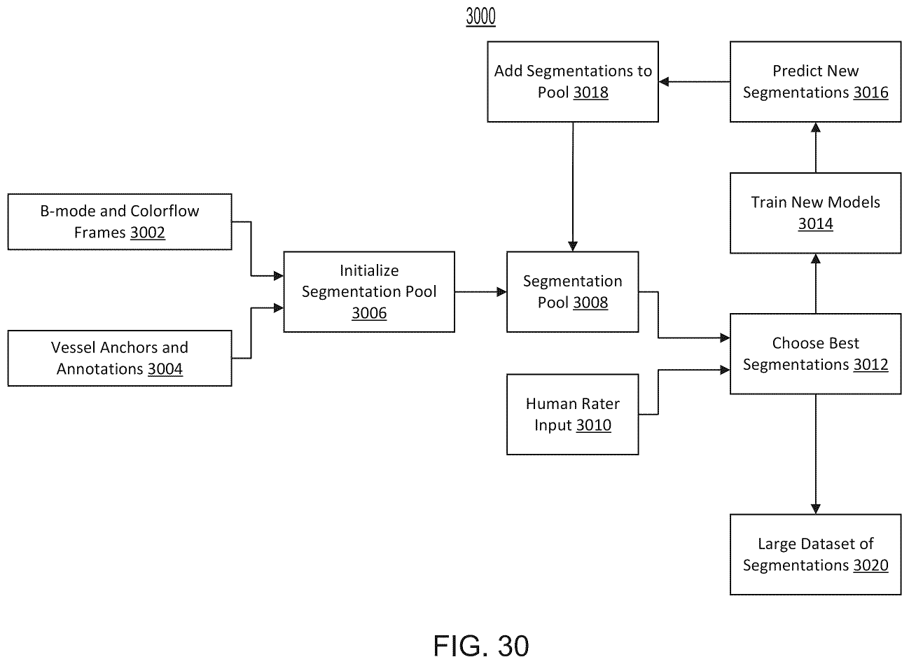

Referring to FIG. 30, depicted is a non-limiting example dataflow diagram 3000 showing a process for creating pixel annotations for brain vessels that may be used for training machine learning models, in accordance with one or more embodiments of the disclosure. The pixel annotations may be utilized as label data for training the various segmentation models described herein. The process shown in the dataflow diagram 3000 may be utilized to iteratively building a segmentation dataset using binary human input (e.g., accept or reject segmentations).

The segmentations may be generated for one or more B-mode and colorflow frames 3002, which may include any number of frames captured from any number of ultrasound scans, as described herein. The label process may be initialized using initial labels on a per-image basis. The initial labels, shown here as the vessel anchors and annotations 3004, indicate the approximate location of a target brain vessel, and may include a preliminary segmentation map. In some implementations, the vessel anchors and annotations 3004 may only need to be available a few images (e.g., a subset of the B-mode and colorflow frames 3002).

The vessel anchors and annotations 3004, in connection with the B-mode and colorflow frames 1852, are then utilized to initialize the segmentation pool 3006 to generate initial vessel segmentations in the segmentation pool 3008. Initializing the segmentation pool 3006 may include generating initial segmentations (e.g., from the vessel anchors and annotations 3004), which may include one or more segmentation maps or masks that correspond to brain vessels depicted in the B-mode and colorflow frames 3002. Standard image processing methods may be utilized to do so.

The segmentations in the segmentation pool 3008 may then be utilized to train one or more machine learning models. The machine learning models may be trained, in a non-limiting example, using any of the techniques described herein, including the training phase 2102B and the training phase 2302 described in connection with FIGS. 21B and 23, respectively. In a non-limiting example, the segmentations in the segmentation pool 3008 (at this stage, the initial segmentations) may be used as label data for supervised learning techniques to refine the trainable parameters of the machine learning models. The machine learning models may be trained until training termination conditions are met.

Then, additional images (e.g., not in the training set or the segmentation pool) may be provided as input to the machine learning models to produce additional segmentations. At step 3002, a user may provide human rater input 3010, which may include selections of the best and most correct segmentations for further training processes. To do so, a graphical user interface may be displayed showing the generated additional segmentations in connection with the additional input images (e.g., as an overlay, superimposed, etc.). The best or most correct segmentations may be segmentations that most closely correspond to the representation of the brain vessel in the corresponding image. The best segmentations (and the frames to which they correspond) are then stored as part of the large dataset of segmentations 3020, which may be utilized to train other machine learning models (e.g., via supervised learning, etc.).

At step 3014, the machine learning models are trained from scratch (or retrained) using the segmentations selected via the human rater input 3010. The images in the segmentation pool 2508 may then be provided as input to the trained models, and to generate new segmentations at step 213016. At step 3018, the new segmentations 3018 are then added to the segmentation pool 3008, and evaluated by users as described herein. This process is then repeated until a training termination condition is met for the machine learning models (e.g., a lack of improvement in model accuracy, etc.). The process shown in the dataflow diagram 3000 may be utilized to iteratively train any of the segmentation models described herein, while generating or updating the large dataset of segmentations 3020 for use in training other machine learning models.

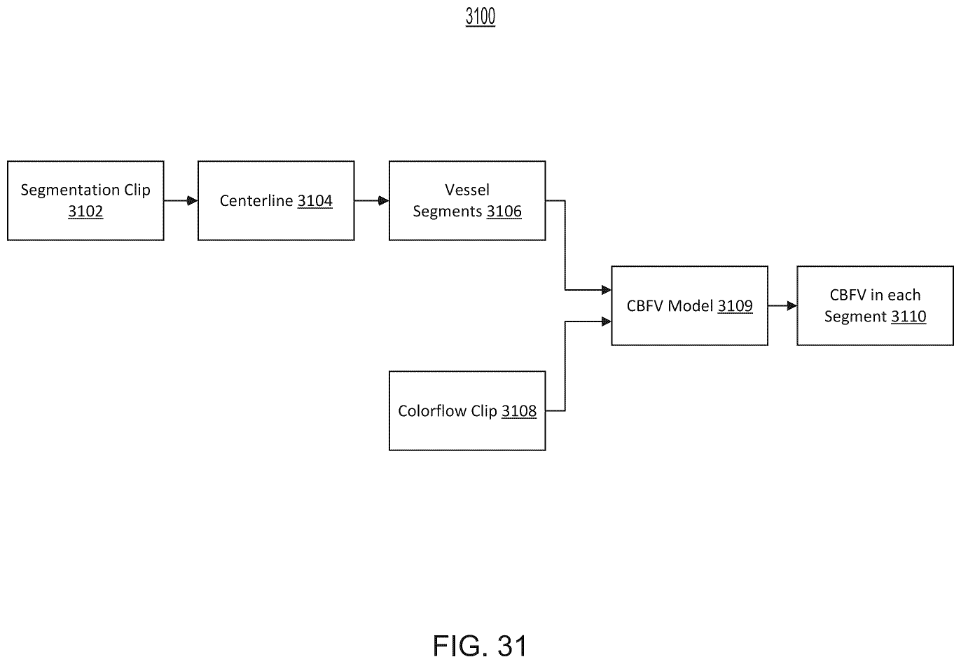

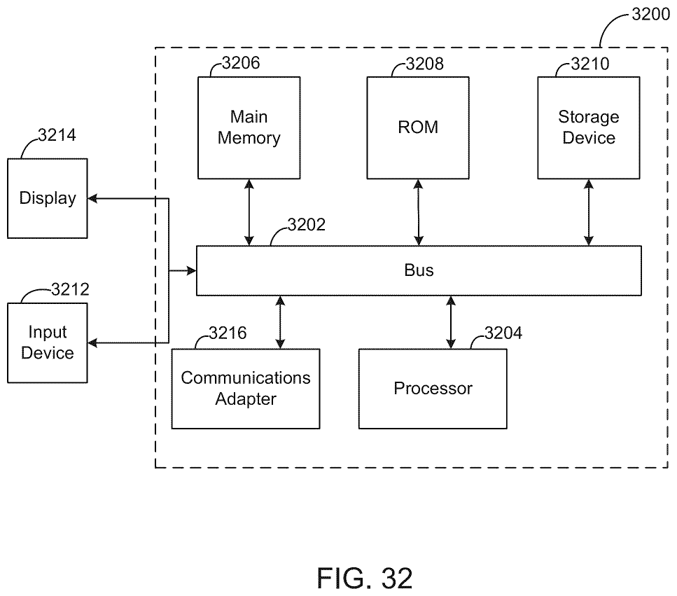

Referring to FIG. 31, depicted is a non-limiting example dataflow diagram 3100 showing a process for executing a machine-learning model to estimate cerebral blood flow using colorflow images, in accordance with one or more embodiments of the disclosure. The process shown in the dataflow diagram 3100 can be used to execute a machine learning model that receives colorflow frames as input to estimate the cerebral blood flow velocity (CBFV). The model may be utilized to estimate the CBFV in multiple segmentations of the vessel simultaneously with a single probe. In some implementations, the process shown in the diagram 3100 may be used to automatically track vessel segments across video clips and measure local changes in colorflow values to estimate the pulse.

As shown, one or more segmentation clips may 3102 may be utilized to generate segmentation parameters, such as the centerline parameters 3104. The centerline parameters 3104 may be estimated, in a non-limiting example, using the approaches described in connection with FIG. 25A. Tracking techniques may be performed to generate associations and track the segmentations across time. The tracking techniques may include the generation of associations between centerlines 3104 of each segmentation in the segmentation clip, which may be stored as the vessel segments 3106. The vessel segments 3106, along with the corresponding colorflow frames of a colorflow clip 3108 from which the vessel segments 3106 are derived, may be provided as input to the CBFV model 3109.

The CBFV model 3109 may be trained to receive sequences of vessel segments 3106 and corresponding sequences of colorflow frames (e.g., a colorflow clip 3108) and generate output CBFV for each segment 3110. In some implementations, the CBFV model 3109 may be a trained using supervised learning and a corresponding training dataset. In some implementations, execution of the CBFV model 3109 may include generating CFBV estimates for multiple segments depicted in a colorflow image 3110. In such implementations, the CBFV model 3109 may enable estimations CBFV of multiple segments simultaneously, which is an improvement over conventional techniques that utilize only pulsed wave signals. Such conventional techniques may only be able to estimate flow of a single physical coordinate in a given image.

FIG. 32 illustrates a component diagram of an example computing system suitable for use in the various implementations described herein, according to an example implementation. In a non-limiting example, the computing system 3200 may implement the imaging system 12310 or the computing device 1870 of FIG. 18, or various other example systems and devices described in the present disclosure.

The computing system 3200 includes a bus 3202 or other communication component for communicating information and a processor 3204 coupled to the bus 3202 for processing information. The computing system 3200 also includes main memory 3206, such as a RAM or other dynamic storage device, coupled to the bus 3202 for storing information, and instructions to be executed by the processor 3204. Main memory 3206 may also be used for storing position information, temporary variables, or other intermediate information during execution of instructions by the processor 3204. The computing system 3200 may further include a ROM 3208 or other static storage device coupled to the bus 3202 for storing static information and instructions for the processor 3204. A storage device 2522103210, such as a solid-state device, magnetic disk, or optical disk, is coupled to the bus 3202 for persistently storing information and instructions.

The computing system 3200 may be coupled via the bus 3202 to a display 3214, such as a liquid crystal display, or active matrix display, for displaying information to a user. An input device 3212, such as a keyboard including alphanumeric and other keys, may be coupled to the bus 3202 for communicating information, and command selections to the processor 3204. In another implementation, the input device 3212 has a touch screen display. The input device 3212 may include any type of biometric sensor, or a cursor control, such as a mouse, a trackball, or cursor direction keys, for communicating direction information and command selections to the processor 3204 and for controlling cursor movement on the display 3214.

In some implementations, the computing system 3200 may include a communications adapter 3216, such as a networking adapter. Communications adapter 3216 may be coupled to bus 3202 and may be configured to enable communications with a computing or communications network or other computing systems. In various illustrative implementations, any type of networking configuration may be achieved using communications adapter 3216, such as wired (e.g., via Ethernet), wireless (e.g., via Wi-Fi, Bluetooth), satellite (e.g., via GPS) pre-configured, ad-hoc, LAN, WAN, and the like.

According to various implementations, the processes of the illustrative implementations that are described herein may be achieved by the computing system 3200 in response to the processor 3204 executing an implementation of instructions contained in main memory 3206. Such instructions may be read into main memory 3206 from another computer-readable medium, such as the storage device 2522103210. Execution of the implementation of instructions contained in main memory 3206 causes the computing system 3200 to perform the illustrative processes described herein. One or more processors in a multi-processing implementation may also be employed to execute the instructions contained in main memory 3206. In alternative implementations, hard-wired circuitry may be used in place of or in combination with software instructions to implement illustrative implementations. Thus, implementations are not limited to any specific combination of hardware circuitry and software.

Various non-limiting example embodiments include the following combinable embodiments/features:

Embodiment AA: A method comprising: generating, by an ultrasound system, imaging data corresponding to a single B-mode frame in an ultrasound image of a brain of a patient; and providing, by the ultrasound system, the imaging data to a first machine learning model configured to receive B-mode frames and, for each of the B-mode frames, output a prediction comprising a bounding region indicative of a location of a cerebral peduncle in the respective B-mode frame.

Embodiment AB: The method of Embodiment AA, wherein the first machine learning model is further configured to output a presence score indicative of a confidence of the first machine learning model in the prediction.

Embodiment AC: The method of either Embodiment AA or AB, further comprising generating, by the ultrasound system on a display device, the ultrasound image comprising the respective B-mode frame with the bounding region superimposed thereon.

Embodiment AD: The method of any of Embodiments AA-AC, further comprising identifying a Circle of Willis in the respective B-mode frame based at least on the location of the cerebral peduncle.

Embodiment AE: The method of any of Embodiments AA-AD, further comprising training the first machine learning model, wherein training the first machine learning model comprises: generating a first training dataset comprising imaging data for a set of B-mode frames and, for each B-mode frame in the set of B-mode frames, a bounding region containing the cerebral peduncle.

Embodiment AF: The method of any of Embodiments AA-AE, wherein the bounding region for each B-mode frame in the set of B-mode frames in the first training dataset is user-defined.

Embodiment AG: The method of any of Embodiments AA-AF, further comprising training the first machine learning model using one or more training datasets comprising (i) B-mode frames, (ii) a cerebral peduncle bounding region for each B-mode frame, and (iii) a cerebral peduncle presence label for each B-mode frame.

Embodiment AH: The method of any of Embodiments AA-AG, further comprising: generating, by the ultrasound system, second imaging data corresponding to a sequence of B-mode frames in the ultrasound image of the patient; and inputting, by the ultrasound system, the second imaging data to a second machine learning model that is configured to predict the location of the cerebral peduncle based at least on regions neighboring the cerebral peduncle.

Embodiment AI: The method of any of Embodiments AA-AH, further comprising: generating, by the ultrasound system, second imaging data corresponding to a sequence of B-mode frames in the ultrasound image of the patient, the sequence comprising (i) the single B-mode frame and (ii) data indicative of the bounding region predicted by the first machine learning model; and inputting, by the ultrasound system, the second imaging data to a second machine learning model that is configured to predict the location of the cerebral peduncle based at least on regions neighboring the bounding region.

Embodiment AJ: The method of any of Embodiments AA-AI, further comprising training the second machine learning model, wherein training the second machine learning model comprises: generating a second training dataset comprising imaging data for sequences of B-mode frames and, for each B-mode frame in each of the sequences, (i) a bounding region produced by the first machine learning model and (ii) data corresponding to neighboring regions proximate to the bounding region.

Embodiment AK: The method of any of Embodiments AA-AJ, further comprising updating the first machine learning model based at least on outputs of the second machine learning model.

Embodiment AL: The method of any of Embodiments AA-AK, further comprising: receiving, for the single B-mode frame, a user input corresponding to the cerebral peduncle; and updating the first machine learning model based at least on the user input.

Embodiment BA: A method comprising: generating, by the ultrasound system, imaging data corresponding to a sequence of B-mode frames in an ultrasound of a patient and, in each of the B-mode frames, an indication of a first location of a cerebral peduncle; and providing, by the ultrasound system, the imaging data to a first machine learning model, the first machine learning model configured to output a prediction comprising a bounding region indicative of a second location of a neighboring anatomic feature proximate to the cerebral peduncle.

Embodiment BB: The method of Embodiment BA, further comprising training the first machine learning model using a training dataset comprising B-mode frames, peduncle bounding regions, and peduncle presence labels.

Embodiment BC: The method of Embodiment BA or BB, further comprising using a second machine learning model to locate the second anatomic feature in a single B-mode frame in the sequence of B-mode frames.

Embodiment CA, A method comprising: providing, by an ultrasound device, a single colorflow frame in an ultrasound of a patient to a first machine learning model configured to receive colorflow frames and, for each of the colorflow frames received, output a prediction indicative of a brain blood vessel location in the colorflow frame; and generating, by the ultrasound device, an ultrasound image based at least on the prediction.

Embodiment CB: The method of Embodiment CA, wherein the first machine learning model is further configured to output a presence score indicative of a confidence of the first machine learning model in the prediction.

Embodiment CC: The method of any of Embodiments CA or CB, wherein the first machine learning model is trained using one or more training datasets comprising colorflow frames, each of the colorflow frames comprising a vessel presence label.

Embodiment CD: The method of any of Embodiments CA-CC, wherein the vessel presence label is a binary indicator of whether a blood vessel is present.

Embodiment CE: The method of any of Embodiments CA-CD, wherein the first machine learning model is trained using one or more training datasets consisting of colorflow frames, each of the colorflow frames comprising a vessel presence label.

Embodiment CF: The method of any of Embodiments CA-CE, wherein the vessel presence label is a binary indicator of whether a blood vessel is present.

Embodiment CG: The method of any of Embodiments CA-CF, further comprising inputting, by the ultrasound device, the single colorflow frame and a single B-mode frame to a second machine learning model configured to output a single-frame blood vessel segmentation.

Embodiment CH: The method of any of Embodiments CA-CG, further comprising deriving, by the ultrasound device, a metric related to blood flow velocity based at least on the blood vessel segmentation.

Embodiment CI: The method of any of Embodiments CA-CH, further comprising smoothing, by the ultrasound device, variations of frame-to-frame brain vessel segmentations in real-time using a buffer that stores previous segmentations and uses the previous segmentations to modify current vessel segmentations.

Embodiment CJ: The method of any of Embodiments CA-CI, further comprising generating, in real-time, an ultrasound image based at least on the brain blood vessel location from the first machine learning model and the blood vessel segmentation of the second machine learning model.

Embodiment DA: A method comprising: generating, in real-time, a single-frame brain vessel segmentation in an ultrasound of a brain of a patient by inputting a single B-mode frame and a single colorflow frame to a machine learning model configured for brain vessel detection based at least on vessel volume.

Embodiment DB: The method of Embodiment DA, further comprising deriving a quantity related to blood flow velocity based at least on the brain vessel segmentation.

Embodiment DC: The method of any of Embodiments DA or DB, further comprising characterizing blood vessel shape based at least on the brain vessel segmentation.

Embodiment DD: The method of any of Embodiments DA-DC, further comprising smoothing variations of frame-to-frame vessel segmentations using a buffer that stores previous segmentations and uses the previous segmentations to modify brain vessel segmentation in the current frame.

Embodiment EA: A method comprising: using a first machine learning model to determine a blood vessel location using a single colorflow frame in an ultrasound of a patient; using a second machine learning model to generate a brain vessel segmentation using the single colorflow frame and a single B-mode frame; and generating, for display, an ultrasound image based at least on the blood vessel location and the brain vessel segmentation.

Embodiment FA: A method comprising: generating, by the ultrasound system, ultrasound images comprising brain vessel segmentations at least by inputting a single B-mode frame in an ultrasound of a patient to a machine learning model, wherein the machine learning model is configured to output a brain vessel segmentation based at least on the single B-mode frame.

Embodiment FB: The method of Embodiment FA, wherein the brain vessel segmentations are generated, by the ultrasound system, in real-time.

Embodiment FC: The method of any of Embodiments FA or FB, wherein the machine learning model is trained using brain vessel segmentations derived from colorflow images.

Embodiment FD: The method of any of Embodiments FA-FC, wherein the machine learning model does not receive a colorflow image as input once the machine learning model has been optimized using the colorflow images.

Embodiment FE: The method of any of Embodiments FA-FD, wherein the machine learning model detects multiple anatomical landmarks visible in B-mode images and uses the anatomical landmarks to estimate a position of a brain vessel corresponding to the brain vessel segmentation.

Embodiment FF: The method of any of Embodiments FA-FE, wherein the machine learning model detects multiple anatomical landmarks visible in B-mode images and uses the anatomical landmarks to estimate a delineation of a brain vessel corresponding to the brain vessel segmentation.

Embodiment FG: The method of any of Embodiments FA-FF, wherein the machine learning model detects multiple anatomical landmarks visible in B-mode images and uses the anatomical landmarks to estimate a position and delineation of a brain vessel corresponding to the brain vessel segmentation.

Embodiment FH: The method of any of Embodiments FA-FG, further comprising training the machine learning model using brain vessel segmentations derived from colorflow images.

Embodiment GA: An ultrasound system comprising one or more processors, the ultrasound system configured to generate ultrasound images comprising brain vessel segmentations at least by inputting a single B-mode frame in an ultrasound of a patient to a machine learning model, wherein the machine learning model is configured to output a brain vessel segmentation based at least on the single B-mode frame.

Embodiment GB: The ultrasound system of Embodiment GA, wherein the ultrasound system is configured to generate the brain vessel segmentations in real-time.

Embodiment GC: The ultrasound system of any of Embodiments GA or GB, wherein the machine learning model is trained using brain vessel segmentations derived from colorflow images.

Embodiment GD: The ultrasound system of any of Embodiments GA-GC, wherein the ultrasound system does not input colorflow images to the machine learning model once the machine learning model has been trained using the colorflow images.

Embodiment GE: The ultrasound system of any of Embodiments GA-GD, wherein the machine learning model detects multiple anatomical landmarks visible in B-mode images and uses the anatomical landmarks to estimate a position of a brain vessel corresponding to the brain vessel segmentation.

Embodiment GF: The ultrasound system of any of Embodiments GA-GE, wherein the machine learning model detects multiple anatomical landmarks visible in B-mode images and uses the anatomical landmarks to estimate a delineation of a brain vessel corresponding to the brain vessel segmentation.

Embodiment GG: The ultrasound system of any of Embodiments GA-GF, wherein the machine learning model detects multiple anatomical landmarks visible in B-mode images and uses the anatomical landmarks to estimate a position and a delineation of a brain vessel corresponding to the brain vessel segmentation.

Embodiment HA: A method comprising: generating, by an ultrasound system, a clip of brain vessel segmentations in an ultrasound of a patient; determining, by the ultrasound system, a plurality of blood vessel parameters at least by inputting the clip of brain vessel segmentations to a machine learning model configured to output the plurality of blood vessel parameters based at least on the clip of the brain vessel segmentations; and outputting, by the ultrasound system, the plurality of blood vessel parameters determined using the machine learning model.

Embodiment HB: The method of Embodiment HA, wherein the plurality of blood vessel parameters comprises coordinates of a centerline location.

Embodiment HC: The method of any of Embodiments HA or HB, wherein the plurality of blood vessel parameters comprises a vessel curvature at each centerline location.

Embodiment HD: The method of any of Embodiments HA-HC, wherein the plurality of blood vessel parameters comprises a vessel diameter at each centerline location.

Embodiment HE: The method of any of Embodiments HA-HD, wherein the plurality of blood vessel parameters comprises a colorflow signal-to-noise ratio at each centerline location.

Embodiment HF: The method of any of Embodiments HA-HE, wherein the plurality of blood vessel parameters comprises at least one of: a plurality of coordinates of a centerline location, a vessel curvature at the centerline location, a vessel diameter at the centerline location, or a colorflow signal-to-noise ratio at the centerline location.

Embodiment IA: A method comprising: tracking, in a sequence of ultrasound images, by an ultrasound system, a position of brain vessel segments across time using a machine learning model, wherein the machine learning model is configured to use parametrization of a brain vessel curve and a spatiotemporal matching algorithm to build a spatiotemporal graph.

Embodiment IB: The method of Embodiment IA, wherein the tracking is implemented as a scan through the spatiotemporal graph.

Embodiment IC: The method of any of Embodiments IA or IB, wherein the spatiotemporal matching algorithm comprises a Hungarian matching algorithm.

Embodiment ID: The method of any of Embodiments IA-IC, further comprising using the tracking in a beam steering component of an ultrasound system.

Embodiment IE: The method of any of Embodiments IA-ID, further comprising locking on a target and extracting one or more parameters to perform an assessment of cerebral blood flow velocity.

Embodiment JA: An ultrasound system comprising one or more processors, the ultrasound system configured to: generate a plurality of blood vessel parameters at least by inputting a clip of brain vessel segmentations in an ultrasound of a patient, to a first machine learning model configured to output the plurality of blood vessel parameters based at least on the clip of the brain vessel segmentations; and

track a position of brain vessel segments across time using a second machine learning model configured to use parametrization of a brain vessel curve and a spatiotemporal matching algorithm to build a spatiotemporal graph.

Embodiment JB: The ultrasound system of Embodiment JA, wherein the plurality of blood vessel parameters comprises at least one of: a plurality of coordinates of a centerline location, a vessel curvature at the centerline location, a vessel diameter at the centerline location, or a colorflow signal-to-noise ratio at the centerline location.

Embodiment JC: The ultrasound system of any of Embodiments JA or JB, wherein the ultrasound system is configured to track the position in a beam steering component of the ultrasound system.

Embodiment JD: The ultrasound system of any of Embodiments JA-JC, further configured to lock on a target and extract one or more parameters to perform an assessment of cerebral blood flow velocity.

Embodiment KA: A method comprising: predicting, by an ultrasound system, a presence score for a target brain vessel in a Circle of Willis in an ultrasound of a patient, by providing a sequence of B-mode and colorflow frames to an ensemble model, the ensemble model configured to aggregate predictions of a plurality of machine learning models with different designs; and outputting, by the ultrasound system, an indication of the presence score predicted using the ensemble model.

Embodiment KB: The method of Embodiment KA, wherein the plurality of machine learning models comprises either: (i) a first machine learning model, or (ii) both the first machine learning model and a second machine learning model, each of the first and second machine learning models configured to detect a cerebral peduncle using a single B-mode frame, the first and second machine learning models having different designs.

Embodiment KC: The method of any of Embodiments KA or KB, wherein the plurality of machine learning models comprises a third machine learning model configured to detect a cerebral peduncle using a sequence of B-mode frames.

Embodiment KD: The method of any of Embodiments KA-KC, wherein the plurality of machine learning models comprises a fourth machine learning model configured for brain vessel segmentation using B-mode and colorflow frames.

Embodiment KE: The method of any of Embodiments KA-KD, wherein the fourth machine learning model is further configured to perform temporal smoothing.

Embodiment KF: The method of any of Embodiments KA-KE, wherein the plurality of machine learning models comprises a fifth machine learning model configured for brain vessel segmentation using only B-mode frames.

Embodiment KG: The method of any of Embodiments KA-KF, wherein the plurality of machine learning models comprises: a first machine learning model and a second machine learning model, each of the first and second machine learning models configured to detect a cerebral peduncle using a single B-mode frame; a third machine learning model configured to detect a cerebral peduncle using a sequence of B-mode frames; a fourth machine learning model configured for brain vessel segmentation using B-mode and colorflow frames; and a fifth machine learning model configured for brain vessel segmentation using only B-mode frames; and

Embodiment KH: The method of any of Embodiments KA-KG, wherein the ensemble model comprises at least two of: a B-mode You Only Look Once (YOLO) model, a B-mode CenterNet model, a B-mode segmentation model, and a B-mode and colorflow segmentation model.

Embodiment LA: An ultrasound system comprising one or more processors, the ultrasound system configured to: predict, by at least one processor, a presence score for a target brain vessel in a Circle of Willis in an ultrasound of a patient, by providing a sequence of B-mode and colorflow frames to an ensemble model, the ensemble model configured to aggregate predictions of a plurality of machine learning models with different designs; and output, by the at least one processor, an indication of the presence score predicted using the ensemble model.

Embodiment LB: The ultrasound system of Embodiment LA, wherein the plurality of machine learning models comprises a first machine learning model and a second machine learning model, each of the first and second machine learning models configured to detect a cerebral peduncle using a single B-mode frame, the first and second machine learning models having different designs.

Embodiment LC: The ultrasound system of Embodiments LA or LB, wherein the plurality of machine learning models comprises a third machine learning model configured to detect a cerebral peduncle using a sequence of B-mode frames.

Embodiment LD: The ultrasound system of Embodiments LA-LC, wherein the plurality of machine learning models comprises a fourth machine learning model configured for brain vessel segmentation using B-mode and colorflow frames.

Embodiment LE: The ultrasound system of Embodiments LA-LD, wherein the plurality of machine learning models comprises a fifth machine learning model configured for brain vessel segmentation using only B-mode frames.

Embodiment MA: One or more computing systems and/or one or more computing devices comprising one or more processors and configured to perform any of the methods of the above Embodiments.

Embodiment NA: One or more computing systems and/or one or more computing devices comprising one or more processors and configured to perform any combination of steps from any combination of the methods of the above Embodiments.

It should be noted that although method steps may be described in a specific order, it is understood that the order of these steps may differ from what is described. In a non-limiting example, two or more steps may be performed concurrently or with partial concurrence. Also, some method steps that are performed as discrete steps may be combined, steps being performed as a combined step may be separated into discrete steps, the sequence of certain processes may be reversed or otherwise varied, and the nature or number of discrete processes may be altered or varied. The order or sequence of any element or apparatus may be varied or substituted according to alternative embodiments. Accordingly, all such modifications are intended to be included within the scope of the present disclosure as defined in the appended claims. It is understood that all such variations are within the scope of the disclosure.

While this specification contains many specific embodiment details, these should not be construed as limitations on the scope of any inventions or of what may be claimed, but rather as descriptions of features specific to particular embodiments of the systems and methods described herein. Certain features that are described in this specification in the context of separate embodiments may also be embodied in combination in a single embodiment. Conversely, various features that are described in the context of a single embodiment may also be embodied in multiple embodiments separately or in any suitable subcombination. Moreover, although features may be described above as acting in certain combinations and even initially claimed as such, one or more features from a claimed combination may in some cases be excised from the combination, and the claimed combination may be directed to a subcombination or variation of a subcombination.

Having now described some illustrative embodiments and embodiments, it is apparent that the foregoing is illustrative and not limiting, having been presented by way of example. In particular, although many of the examples presented herein involve specific combinations of method acts or system elements, those acts and those elements may be combined in other ways to accomplish the same objectives. Acts, elements, and features discussed only in connection with one embodiment are not intended to be excluded from a similar role in other embodiments.

The phraseology and terminology used herein is for the purpose of description and should not be regarded as limiting. The use of “including,” “comprising,” “having,” “containing,” “involving,” “characterized by,” “characterized in that,” and variations thereof herein, is meant to encompass the items listed thereafter, equivalents thereof, and additional items, as well as alternate embodiments consisting of the items listed thereafter exclusively. In one embodiment, the systems and methods described herein consist of one, each combination of more than one, or all of the described elements, acts, or components.

As utilized herein with respect to numerical ranges, the terms “approximately,” “about,” “substantially,” “essentially,” and similar terms generally mean +/−10% of the disclosed values. When the terms “approximately,” “about,” “substantially,” “essentially,” and similar terms are applied to a structural feature (e.g., to describe its shape, size, orientation, direction, etc.), these terms are meant to cover minor variations in structure that may result from, for example, the manufacturing or assembly process and are intended to have a broad meaning in harmony with the common and accepted usage by those of ordinary skill in the art to which the subject matter of this disclosure pertains. Accordingly, these terms should be interpreted as indicating that insubstantial or inconsequential modifications or alterations of the subject matter described and claimed are considered to be within the scope of the disclosure as recited in the appended claims.

Any references to embodiments or elements or acts of the systems and methods herein referred to in the singular may also embrace embodiments including a plurality of these elements, and any references in plural to any embodiment or element or act herein may also embrace embodiments including only a single element. References in the singular or plural form are not intended to limit the presently disclosed systems or methods, their components, acts, or elements to single or plural configurations. References to any act or element being based on any information, act, or element may include embodiments where the act or element is based at least in part on any information, act, or element.

Any embodiment disclosed herein may be combined with any other embodiment, and references to “an embodiment,” “some embodiments,” “an alternate embodiment,” “various embodiments,” “one embodiment,” or the like are not necessarily mutually exclusive and are intended to indicate that a particular feature, structure, or characteristic described in connection with the embodiment may be included in at least one embodiment. Such terms as used herein are not necessarily all referring to the same embodiment. Any embodiment may be combined with any other embodiment, inclusively or exclusively, in any manner consistent with the aspects and embodiment disclosed herein.

References to “or” may be construed as inclusive so that any terms described using “or” may indicate any of a single, more than one, and all of the described terms.

Where technical features in the drawings, detailed description or any claim are followed by reference signs, the reference signs have been included for the sole purpose of increasing the intelligibility of the drawings, detailed description, and claims. Accordingly, neither the reference signs nor their absence have any limiting effect on the scope of any claim elements.

The foregoing description of embodiments has been presented for purposes of illustration and description. It is not intended to be exhaustive or to limit the disclosure to the precise form disclosed, and modifications and variations are possible in light of the above teachings or may be acquired from this disclosure. The embodiments were chosen and described in order to explain the principals of the disclosure and its practical application to enable one skilled in the art to utilize the various embodiments and with various modifications as are suited to the particular use contemplated. Other substitutions, modifications, changes, and omissions may be made in the design, operating conditions and embodiment of the embodiments without departing from the scope of the present disclosure as expressed in the appended claims.

What is claimed is:

1. An ultrasound transducer comprising:
a piezoelectric array;
an interposer board coupled to the piezoelectric array;
a cable assembly coupled to the interposer board; and
a backing layer comprising a phase disruptive component.

2. The ultrasound transducer of claim 1, wherein the piezoelectric array comprises array elements at least partially cut along epoxy resin grooves.

3. The ultrasound transducer of claim 1, further comprising a housing with a front casing and a back casing, and an acoustic lens secured to the front casing.

4. The ultrasound transducer of claim 1, wherein the phase disruptive component comprises grooves.

5. The ultrasound transducer of claim 4, wherein the grooves are V-shaped grooves.

6. The ultrasound transducer of claim 1, wherein the backing layer further comprises beads.

7. The ultrasound transducer of claim 6, wherein the beads have a hollow interior.

8. The ultrasound transducer of claim 1, wherein the backing layer further comprises tungsten powder.

9. The ultrasound transducer of claim 1, further comprising one or more matching layers, wherein each of the one or more matching layers comprises an epoxy resin.

10. The ultrasound transducer of claim 1, wherein the interposer board comprises one or more receptacles for one or more cable assembly connectors.

11. The ultrasound transducer of claim 1, wherein the interposer board comprises a cutout sized to fit the piezoelectric array.

12. The ultrasound transducer of claim 1, further comprising a copper pad having a cutout smaller than the piezoelectric array, wherein the piezoelectric array comprises a ground electrode, and wherein the ground electrode is bonded, via a conductive epoxy, to an exposed part of the copper pad.

13. The ultrasound transducer of claim 1, wherein the transducer does not comprise an impedance tuner.

14. The ultrasound transducer of claim 1, wherein the cable assembly comprises a cable extending from a transducer end to a system end, and wherein the system end of the cable comprises one or more electrical components configured for electrical impedance tuning.

15. The ultrasound transducer of claim 1, wherein the piezoelectric array comprises a 1-3 composite material or a 2-2 composite material.
